(19) United States
(12) Patent Application Publication
(10) Pub. No.: US 2016/0013392 A1
(43) Pub. Date: Jan. 14, 2016

(54) METHOD OF PRODUCING THERMOELECTRIC CONVERSION ELEMENT AND METHOD OF PREPARATION DISPERSION FOR THERMOELECTRIC CONVERSION LAYER

(71) Applicant: FUJIFILM Corporation, Tokyo (JP)

(72) Inventors: Eri TAKAHASHI, Ashigarakami-gun (JP); Naoyuki HAYASHI, Ashigarakami-gun (JP); Yoichi MARUYAMA, Ashigarakami-gun (JP)

(73) Assignee: FUJIFILM CORPORATION, Tokyo (JP)

(21) Appl. No.: 14/862,220

(22) Filed: Sep. 23, 2015

Related U.S. Application Data
(63) Continuation of application No. PCT/JP2014/058388, filed on Mar. 25, 2014.

(30) Foreign Application Priority Data
Mar. 28, 2013 (JP) 2013-069028
Mar. 4, 2014 (JP) 2014-041690

(51) Int. Cl. H01L 35/34; H01L 35/24

(52) U.S. Cl. CPC H01L 35/34; H01L 35/24

(57) ABSTRACT

A method of producing a thermoelectric conversion element which has, on a substrate, a first electrode, a thermoelectric conversion layer, and a second electrode, which method comprising a step of preparing a dispersion for the thermoelectric conversion layer containing a nano conductive material by subjecting at least the material and a dispersion medium to a high-speed rotating thin film dispersion method; and a step of applying the prepared dispersion on or above the substrate and then drying the dispersion; and a method of preparing a dispersion for a thermoelectric conversion layer, which method comprises dispersing a nano conductive material into the dispersion medium by subjecting at least the material and the medium to a high-speed rotating thin film dispersion method.

### CROSS-REFERENCE TO RELATED APPLICATIONS

This application is a Continuation of PCT International Application No. PCT/JP2014/058388 filed on Mar. 25, 2014, which claims priority under 35 U.S.C. §119 (a) to Japanese Patent Application No. 2013-069028 filed in Japan on Mar. 28, 2013, and Patent Application No. 2014-041690 filed in Japan on Mar. 4, 2014. Each of the above applications is hereby expressly incorporated by reference, in its entirety, into the present application.

### TECHNICAL FIELD

The present invention relates to a method of producing a thermoelectric conversion element and a method of preparing a dispersion for a thermoelectric conversion layer.

### BACKGROUND ART

Recently, in the electronics field such as thermoelectric conversion elements, carbon nanotubes or the like having high electrical conductivity have attracted attention as a new conductive material for replacing a conventional inorganic material such as indium tin oxide (ITO).

However, such a nanometer-sized conductive material (hereinafter, referred to as “a nano conductive material”), particularly, a carbon nanotube is likely to be aggregated and thus shows poor dispersibility in a dispersion medium. Accordingly, when the nanometer-sized conductive material is used as a conductive material, the improvement of dispersibility is desired.

For example, as a method of improving the dispersibility of the carbon nanotube in a dispersion medium, a method of using a specific dispersant for carbon fibers (for example, see Patent Literature 1), a method of employing a jet mill or an ultrasonication as a dispersing means (for example, see Patent Literature 2), a method of sequentially performing a mechanical homogenizer method and an ultrasonic dispersion method as a preferred dispersion method (for example, see Patent Literature 3), or the like is exemplified.

### CITATION LIST

### Patent Literatures

Patent Literature 1: JP-A-2008-248412 (“JP-A” means unexamined published Japanese patent application)

### Patent Literature 2: JP-A-2010-97794

Patent Literature 3: WO 2012/133314 pamphlet

### SUMMARY OF INVENTION

### Technical Problem

Since the thermoelectric conversion element converts heat into electricity in a thermoelectric conversion layer thereof, when the thermoelectric conversion layer is formed to be thicker to some extent, excellent thermoelectric conversion performance is exerted. It is desirable that such a thermoelectric conversion layer be formed, by a printing method, using a coating liquid of a conductive material having a high solid content concentration and a high viscosity, for example, a paste of the conductive material as a dispersion for forming a thermoelectric conversion layer (referred to as “a dispersion for a thermoelectric conversion layer in the present invention”) from the standpoint of productivity, production cost, and the like.

However, as described above, a nano conductive material such as a carbon nanotube has a big technical problem in that the dispersibility is low, and the dispersibility of the carbon nanotube is not sufficient in any cases where the methods described in Patent Literature 1 and Patent Literature 2 are used. In addition, the film-forming property and the printing property of the dispersion for a thermoelectric conversion layer are also not sufficient yet. Therefore, to form a thermoelectric conversion layer that has high electrical conductivity and is excellent in the thermoelectric conversion performance, it is necessary to further improve the dispersibility of the nano conductive material, particularly, the dispersibility of the carbon nanotube as well as the film-forming property and the printing property of the dispersion for a thermoelectric conversion layer.

Further, according to the method described in Patent Literature 3, it is possible to prepare a dispersion for a thermoelectric conversion layer having a solid content concentration and a viscosity to some extent and thus a thermoelectric conversion layer that is excellent in the thermoelectric conversion performance can be formed.

However, every year, the thermoelectric conversion performance demanded for the thermoelectric conversion element has been raising, and to realize higher thermoelectric conversion performance that will be demanded in the future, there is a demand for developing a dispersion for a thermoelectric conversion layer in which the dispersibility of the carbon nanotube is much improved and which is excellent in the film-forming property and the printing property.

Therefore, the present invention is intended to provide a method of preparing a dispersion for a thermoelectric conversion layer which is excellent in the dispersibility of a nano conductive material and has high film-forming property and printing property, and a method of producing a thermoelectric conversion element which is excellent in electrical conductivity and thermoelectric conversion performance by using the dispersion for a thermoelectric conversion layer.

### Solution to Problem

The inventors of the present invention examined various methods of dispersing a carbon nanotube in the dispersion for a thermoelectric conversion layer in order to solve the above-described problems. As a result, they found that, when a carbon nanotube as a dispersion treatment target substance and a dispersion medium are subjected to a high-speed rotating thin film dispersion method in which the dispersion treatment target substance is rotated at high speed while being pressed in a cylindrical thin film shape onto the inner wall surface of an apparatus by centrifugal force, and the centrifugal force and shear stress generated by a speed difference with respect to the inner wall surface of the apparatus are allowed to act on the dispersion treatment target substance, the carbon nanotube can be dispersed highly in the dispersion medium and the film-forming property and the printing property can also be improved.

As described above, in the case where a thermoelectric conversion layer having high thermoelectric conversion performance is produced by a printing method, a dispersion for a thermoelectric conversion layer having a high solid content concentration and a high viscosity is required. According to the high-speed rotating thin film dispersion method, as the solid content concentration and the viscosity of the dispersion increase, shear stress to be applied increases, and thus the dispersibility of the carbon nanotube can be further increased. As a result, the inventors of the present invention also found that it is possible to prepare a dispersion for a thermoelectric conversion layer capable of forming a thermoelectric conversion layer having high thermoelectric conversion performance.

The present invention has been made based on those findings.

In the present invention, the term “film-forming property” means a property relating to a film quality of a thermoelectric conversion layer (film) formed by applying a dispersion for a thermoelectric conversion layer to a substrate. For the film-forming property, evaluation on whether the layer quality of the thermoelectric conversion layer is good, for example, whether the layer is uniform without any aggregate or whether the layer is broken or fragile is conducted, and evaluation on whether the thermoelectric conversion layer can be formed to have a thickness of, for example, 5 μm or more is conducted. Therefore, the expression “being excellent in the film-forming property” means that a uniform film can be produced and a thermoelectric conversion layer can be formed without dripping of a dispersion for a thermoelectric conversion layer.

In addition, the term “printing property” relates to a material characteristic when a dispersion for a thermoelectric conversion layer is printed on a substrate to form a thermoelectric conversion layer. The expression “being excellent in printing property” means, for example, a state where the thixotropic property of the dispersion for a thermoelectric conversion layer is appropriately high, printing can be performed uniformly, and formability is excellent.

According to the present invention, there is provided the following means:

<1> A method of producing a thermoelectric conversion element which has, on a substrate, a first electrode, a thermoelectric conversion layer, and a second electrode, which method comprises steps of:

preparing a dispersion for the thermoelectric conversion layer containing a nano conductive material by subjecting at least the nano conductive material and a dispersion medium to a high-speed rotating thin film dispersion method; and

applying the prepared dispersion for a thermoelectric conversion layer on or above the substrate and then drying the dispersion for a thermoelectric conversion layer.

<2> The method of producing a thermoelectric conversion element described in the above item <1>, wherein solid content concentration of the dispersion for a thermoelectric conversion layer is 0.5 to 20 w/v %.
<3> The method of producing a thermoelectric conversion element described in the above item <1> or <2>, wherein content of the nano conductive material in the solid contents of the dispersion for a thermoelectric conversion layer is 10% by mass or more.
<4> The method of producing a thermoelectric conversion element described in any one of the above items <1> to <3>, wherein a viscosity of the dispersion for a thermoelectric conversion layer is 10 mPa·s or more.
<5> The method of producing a thermoelectric conversion element described in any one of the above items <1> to <4>, wherein the high-speed rotating thin film dispersion method is performed at a circumferential velocity of 10 to 40 m/sec.
<6> The method of producing a thermoelectric conversion element described in any one of the above items <1> to <5>, wherein a dispersant is further subjected to the high-speed rotating thin film dispersion method.
<7> The method of producing a thermoelectric conversion element described in the above item <6>, wherein the dispersant is a conjugated polymer.
<8> The method of producing a thermoelectric conversion element described in any one of the above items <1> to <7>, wherein a non-conjugated polymer is further subjected to the high-speed rotating thin film dispersion method.
<9> The method of producing a thermoelectric conversion element described in any one of the above items <1> to <8>, wherein the nano conductive material is at least one kind of material selected from the group consisting of a carbon nanotube, a carbon nanofiber, fullerene, graphite, graphene, carbon nanoparticles and a metal nanowire.
<10> The method of producing a thermoelectric conversion element described in any one of the above items <1> to <9>, wherein the nano conductive material is a carbon nanotube.
<11> The method of producing a thermoelectric conversion element described in any one of the above items <1> to <10>, wherein the nano conductive material is a single-walled carbon nanotube, the diameter of the single-walled carbon nanotube is 1.5 to 2.0 nm, the length of the single-walled carbon nanotube is 1 μm or more, and the G/D ratio of the single-walled carbon nanotube is 30 or more.
<12> The method of producing a thermoelectric conversion element described in any one of the above items <1> to <11>, wherein the dispersion for a thermoelectric conversion layer is applied on or above the substrate by a printing method.
<13> The method of producing a thermoelectric conversion element described in any one of the above items <1> to <12>, wherein an average particle diameter D of the nano conductive material, which is measured by a dynamic light scattering method, in the dispersion for a thermoelectric conversion layer is 1,000 nm or less.
<14> The method of producing a thermoelectric conversion element described in any one of the above items <1> to <13>, wherein a ratio [dD/D] between a half-value width dD in the particle size distribution and an average particle diameter D, of the nano conductive material, which is measured by a dynamic light scattering method, in the dispersion for a thermoelectric conversion layer is 5 or less.
<15> A method of preparing a dispersion for a thermoelectric conversion layer, the dispersion being used for forming a thermoelectric conversion layer of a thermoelectric conversion element, which method comprises:

dispersing a nano conductive material into a dispersion medium by subjecting at least the nano conductive material and the dispersion medium to a high-speed rotating thin film dispersion method.

In the present invention, a numerical value range indicated using “to” means a range including the numerical values described before and after “to” as the lower limit and the upper limit.

In the present invention, when a substituent is described as an xxx group, the xxx group may have an arbitrary substituent. Also, when there are a number of groups represented by the same reference symbol, the groups may be identical with or different from each other.

A repeating structure (also referred to “as a repeating unit”) represented by each formula includes different repeating structures when they are within the range represented by the each formula, but they are not nonetheless completely identical repeating structures. For example, in the case that the repeating structure has an alkyl group, the repeating structure represented by the each formula may be composed only of a repeating structure having a methyl group, or may include a repeating structure having another alkyl group, e.g. an ethyl group, in addition to the repeating structure having a methyl group.

### Advantageous Effects of Invention

According to the method of preparing a dispersion for a thermoelectric conversion layer of the present invention, it is possible to produce a dispersion for a thermoelectric conversion layer which is excellent in the dispersibility of the nano conductive material and has high film-forming property and printing property. In addition, according to the method of producing a thermoelectric conversion element of the present invention, it is possible to produce a thermoelectric conversion element which is excellent in electrical conductivity and thermoelectric conversion performance.

Other and further features and advantages of the invention will appear more fully from the following description, appropriately referring to the accompanying drawings.

### BRIEF DESCRIPTION OF DRAWINGS

FIG. 1 is a diagram schematically showing one embodiment of the cross section of the thermoelectric conversion element produced by the method of producing a thermoelectric conversion element of the present invention.

FIG. 2 is a diagram schematically showing another embodiment of the cross section of the thermoelectric conversion element produced by the method of producing a thermoelectric conversion element of the present invention.

FIG. 3 is a cross-sectional view showing a substrate to be used in an ink jet method.

### DESCRIPTION OF EMBODIMENTS

A thermoelectric conversion element produced by a method of producing a thermoelectric conversion element of the present invention (referred to as “the thermoelectric conversion element of the present invention” in some cases) will be described.

The positional relationship among a first electrode, a second electrode, and a thermoelectric conversion layer, and other configurations of the thermoelectric conversion element of the present invention are not particularly limited as long as the thermoelectric conversion element has a configuration in which the first electrode, the thermoelectric conversion layer, and the second electrode are included on or above a substrate, and at least one surface of the thermoelectric conversion layer is disposed to come into contact with the first electrode and the second electrode. For example, the thermoelectric conversion element may have an aspect in which the thermoelectric conversion layer is interposed between the first electrode and the second electrode, that is, the thermoelectric conversion element of the present invention may have an aspect in which the first electrode, the thermoelectric conversion layer, and the second electrode are provided in this order on a substrate. Moreover, the thermoelectric conversion element may have an aspect in which one surface of the thermoelectric conversion layer is disposed to come into contact with both of the first electrode and the second electrode, that is, the thermoelectric conversion element of the present invention may have an aspect in which the thermoelectric conversion layers are formed on both electrodes to be separated from each other on the substrate.

The thermoelectric conversion layer is formed by using a dispersion for a thermoelectric conversion layer produced by the method of preparing a dispersion for a thermoelectric conversion layer of the present invention (hereinafter, in some cases, referred to as “the dispersion for a thermoelectric conversion layer to be used in the present invention” or simply referred to as “the dispersion for a thermoelectric conversion layer”).

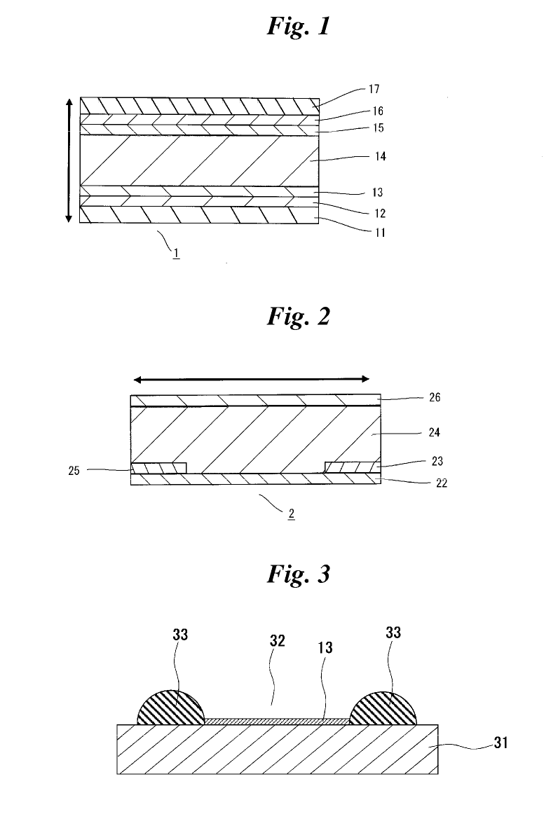

As an example of the structure of the thermoelectric conversion element of the present invention, the structures of the elements illustrated in FIG. 1 and FIG. 2 are exemplified. In FIG. 1 and FIG. 2, the arrows indicate a direction of temperature difference at the use of the thermoelectric conversion element.

A thermoelectric conversion element 1 illustrated in FIG. 1 includes, on a first substrate 12, a pair of electrodes of a first electrode 13 and a second electrode 15, and a thermoelectric conversion layer 14 provided between the electrodes 13 and 15. A second substrate 16 is disposed on the other surface of the second electrode 15, and metal plates 11 and 17 are disposed at the outsides of the first substrate 12 and the second substrate 16 to face each other. Materials of the metal plates 11 and 17 are not particularly limited, and the metal plates are formed by a metal material generally used for the thermoelectric conversion element.

For the thermoelectric conversion element 1, the substrate 12, the first electrode 13, the thermoelectric conversion layer 14, and the second electrode 15 are formed in this order. For thermoelectric conversion element 1, it is preferable that the first electrode 13 or the second electrode 15 be provided on each surface (surfaces having the thermoelectric conversion layer 14 formed thereon) of two substrates 12 and 16, and the thermoelectric conversion layer 14 be provided between these electrodes.

For a thermoelectric conversion element 2 illustrated in FIG. 2, a first electrode 23 and a second electrode 25 are disposed on a first substrate 22, and a thermoelectric conversion layer 24 is provided to cover both of the first electrode 23 and the second electrode 25. Further, a second substrate 26 is provided on the thermoelectric conversion layer 24. The thermoelectric conversion element 2 has the same structure as the thermoelectric conversion element 1, except the positions where the first electrode 23 and the second electrode 25 are disposed and whether or not the metal plate is formed.

For the thermoelectric conversion element 2, the substrate 22, the first electrode 23, the second electrode 25, and the thermoelectric conversion layer 24 are formed in this order.

The surface of the thermoelectric conversion layer is preferably covered with an electrode or a substrate, from the standpoint of the protection of the thermoelectric conversion layer. For example, as illustrated in FIG. 1, it is preferable that one surface of the thermoelectric conversion layer 14 be covered with the first substrate 12 with the first electrode 13 interposed therebetween, and the other surface thereof be covered with the second substrate 16 with the second electrode 15 interposed therebetween. In this case, the second substrate 16 is not provided at the outside of the second electrode 15 and the second electrode 15 may be exposed as the topmost surface to air.

Further, as illustrated in FIG. 2, it is preferable that one surface of the thermoelectric conversion layer 24 be covered with the first electrode 23, the second electrode 25, and the first substrate 22, and the other surface thereof be covered with the second substrate 26. In this case, the second substrate 26 is not provided at the outside of the thermoelectric conversion layer 24 and the thermoelectric conversion layer 24 may be exposed as the topmost surface to air.

In the thermoelectric conversion element of the present invention, it is preferable that the substrate is provided with the thermoelectric conversion layer in a film form.

The thermoelectric conversion performance of the thermoelectric conversion element of the present invention may be defined in figure of merit ZT represented by the following Equation (A).

Figure of merit ZT=S²σT/κ (A)

In Equation (A), S (V/K): Thermopower per absolute temperature 1K (Seebeck coefficient)

σ (S/m): Electrical conductivity

κ (W/mK): Thermal conductivity

T (K): Absolute temperature

The thermoelectric conversion element of the present invention transfers a temperature difference to the thickness direction or the surface direction in a state where the temperature difference is generated in the thickness direction or the surface direction of the thermoelectric conversion layer. Therefore, it is preferable that the dispersion for a thermoelectric conversion layer of the present invention is formed to have a thickness to some extent and then a thermoelectric conversion layer is formed. For this reason, it is preferable to form the thermoelectric conversion layer by coating method such as a printing method. In this case, the dispersion for a thermoelectric conversion layer may need to have a high solid content concentration and a high viscosity and to be excellent in film-forming property, printing property, and the like. In some cases, substrate adhesiveness or the like may be required.

Here, a state where the solid content concentration of the dispersion for a thermoelectric conversion layer is high means that the solid content concentration thereof is at least 0.1 w/v % and preferably 0.5 w/v % or more. In addition, a state where the viscosity of the dispersion for a thermoelectric conversion layer is high means that the viscosity thereof at 25° C. is at least 4 mPa·s, preferably 10 mPa·s or more, and more preferably 50 mPa·s or more.

The film-forming property and the printing property mean as described above.

The term “substrate adhesiveness” indicates a degree of adhesion of the dispersion for a thermoelectric conversion layer to a substrate when the dispersion for a thermoelectric conversion layer is printed or applied to the substrate, and the expression “being excellent in substrate adhesiveness” means a state where the coating layer of the dispersion for a thermoelectric conversion layer is not peeled off and is in close contact with the substrate.

According to the present invention, in addition to the dispersibility of the dispersion for a thermoelectric conversion layer, it is possible to meet the demand relating such film-forming property and printing property. That is, the dispersion for a thermoelectric conversion layer to be used in the present invention becomes a dispersion having a high solid content concentration and a high viscosity which has favorable dispersibility of the nano conductive material and is excellent in film-forming property and printing property. Therefore, the dispersion for a thermoelectric conversion layer to be used in the present invention can be preferably for forming the thermoelectric conversion layer, particularly, can be preferably for forming the thermoelectric conversion layer by a coating method such as a printing method.

Hereinafter, the method of preparing a dispersion for a thermoelectric conversion layer of the present invention and the method of producing a thermoelectric conversion element of the present invention will be described.

The method of producing a thermoelectric conversion element of the present invention includes a step of preparing a dispersion for the thermoelectric conversion layer containing a nano conductive material by subjecting at least the nano conductive material and a dispersion medium to a high-speed rotating thin film dispersion method and a step of applying the prepared dispersion for a thermoelectric conversion layer on or above the substrate and then drying the dispersion for a thermoelectric conversion layer.

In this way, in the method of producing a thermoelectric conversion element of the present invention, the dispersion for a thermoelectric conversion layer to be used in the present invention is prepared by performing the dispersion preparing step that is the method of preparing a dispersion for a thermoelectric conversion layer of the present invention.

Each component used in the method of preparing a dispersion for a thermoelectric conversion layer of the present invention and the method of preparing a thermoelectric conversion element of the present invention will be described.

Examples of these components used in the methods include a nano conductive material, a dispersion medium, and, as required, a dispersant, a non-conjugated polymer, a dopant, an excitation assist agent, a metal element, and other components.

### <Nano Conductive Material>

A nano conductive material to be used in the present invention may be a material having electrical conductivity in which the length of at least one side is nanometer sized. As such a nano conductive material, a carbon material (hereinafter, referred to as “the nanocarbon material” in some cases) having electrical conductivity in which the length of at least one side is nanometer sized, a metal material (hereinafter, referred to as “the nano-metal material” in some cases) in which the length of at least one side is nanometer sized, or the like is exemplified.

Here, the length of one side may be the length of any side of the nano conductive material, and is, although not particularly limited, preferably the length in the longitudinal direction or the length in the transverse direction (also referred to as “a diameter”) of a non-aggregated body (a state where any of nano conductive material is not aggregated, such as a primary particle or one molecule) of the nano conductive material.

The length of one side can be measured by image analysis of, for example, a transmission electron microscope (TEM), or a dynamic light scattering method (particularly in the case of particles).

Among the nanocarbon materials and the nano-metal materials, as the nano conductive material used in the present invention, nanocarbon materials such as a carbon nanotube (hereinafter, also referred to as “CNT”), a carbon nanofiber, fullerene, graphite, graphene, and carbon nanoparticles, and metal nanowires, which will be respectively described below, are preferable, and a carbon nanotube is particularly preferable from the standpoint of improving electrical conductivity and the dispersibility in the dispersion medium.

One kind of the nano conductive materials may be used alone, or two or more kinds thereof may be used in combination. When two or more kinds are used in combination as the nano conductive material, at least one kind of nanocarbon materials and at least one kind of nano-metal materials may be used in combination, or two kinds of respective nanocarbon materials or nano-metal materials may be used in combination.

### 1. Nanocarbon Material

As the nanocarbon material, for example, the nanometer-sized conductive material obtained by the chemical bonding of carbon atoms by means of a carbon-carbon bond formed at sp² hybrid orbital of a carbon atom is exemplified. Specific examples thereof include fullerene (including metal-containing fullerene and onion-shaped fullerene), a carbon nanotube (including peapods), a carbon nanohorn having a shape in which one end of a carbon nanotube is blocked, a carbon nanofiber, a carbon nanowall, a carbon nanofilament, a carbon nanocoil, vapor grown carbonfiber (VGCF), graphite, graphene, carbon nanoparticles, and a cup-shaped nanocarbon substance in which a hole is formed on the top portion of a carbon nanotube. In addition, various carbon blacks having a graphite crystalline structure and electrical conductivity can be used as the nanocarbon material, and examples thereof include Ketjen Black (registered trademark) and acetylene black. Specifically, carbon blacks such as “Vulcan” (registered trademark) are exemplified.

These nanocarbon materials can be produced by a production method of the related art. Specifically, examples thereof include catalytic hydrogen reduction of carbon dioxide, an arc discharge method, a laser vaporization method (a laser ablation method), a vapor-phase epitaxial method such as a chemical vapor deposition method (hereinafter, referred to as “the CVD method”), a vapor-phase flow method, a HiPco method in which carbon monoxide is allowed to react together with an iron catalyst under high temperature and high pressure to grow carbon in a gas phase, and an oil furnace method. The nanocarbon material produced in this way can be used as it is, or a nanocarbon material subjected to purification by cleaning, centrifugal separation, filtration, oxidation, chromatograph, or the like can also be used. Further, a nanocarbon material subjected to pulverization by using ball type kneading apparatuses such as a ball mill, a vibration mill, a sand mill and a roll mill, or a nanocarbon material subjected to cutting to have a short length by a chemical or physical treatment can also be used as necessary.

Among the nanocarbon materials described above, a carbon nanotube, a carbon nanofiber, graphite, graphene, and carbon nanoparticles are preferable, and a carbon nanotube is particularly preferable.

Hereinafter, explanation will be made as to the carbon nanotube. The CNT includes a single-walled CNT in which one sheet of carbon film (graphene sheet) is cylindrically wound, a double-walled CNT in which two graphene sheets are concentrically wound, and a multi-walled CNT in which a plurality of graphene sheets are concentrically wound. In the present invention, the single-walled CNT, the double-walled CNT, and the multi-walled CNT may be used alone, or in combination with two or more kinds. A single-walled CNT and a double-walled CNT have excellent properties in the electrical conductivity and the semiconductor characteristics, and therefore a single-walled CNT and a double-walled CNT are preferably used, and a single-walled CNT is more preferably used.

For a single-walled CNT, the symmetry of the spiral structure based on the direction of hexagon of graphene of a graphene sheet is referred to as axial chirality, and a two-dimensional lattice vector from a reference point of a 6-membered ring on graphene is referred to as a chiral vector. (n, m) obtained by the indexation of this chiral vector is referred to as a chiral index, and metallic CNT and semiconductive CNT can be classified by this chiral index. Specifically, the CNT that has n-m being a multiple of 3 is metallic, while the CNT that has n-m not being a multiple of 3 is semiconductive.

The single-walled CNT may be used in the form of a semiconductive one or a metallic one, or both in combination with the semiconductive one and the metallic one.

Moreover, the CNT may include a metal therein, or one including a molecule of fullerene or the like therein may also be used.

The CNT can be produced by an arc discharge method, CVD method, a laser ablation method, or the like. The CNT used in the present invention may be obtained by any method, but preferably by the arc discharge method and the CVD method.

Upon producing the CNT, fullerene, graphite, and amorphous carbon is simultaneously formed as by-products in some cases. In order to remove these by-products, purification may be performed. A method of purification of the CNT is not particularly limited, but acid treatment by nitric acid, sulfuric acid, or the like, or ultrasonication is effective in removal of the impurities. In addition thereto, separation and removal using a filter is also preferably performed from the standpoint of an improvement of purity.

After purification, the CNT obtained can also be directly used. Moreover, the CNT is generally produced in the form of strings, and therefore may be cut into a desired length according to a use. The CNT can be cut in the form of short fibers by acid treatment by nitric acid or sulfuric acid, ultrasonication, a freeze mill process, or the like. Moreover, in addition thereto, separation using the filter is also preferred from the standpoint of an improvement of purity.

In the present invention, not only a cut CNT, but also a CNT previously prepared in the form of short fibers can be used. Such a CNT in the form of short fibers can be obtained, for example, by forming on a substrate a catalyst metal such as iron and cobalt, and according to the CVD method, allowing on the surface thereof vapor deposition of the CNT by thermally decomposing a carbon compound at 700 to 900° C., thereby obtaining the CNT in the shape of alignment on a substrate surface in a vertical direction. The thus prepared CNT in the form of short fibers can be taken out from the substrate by a method of stripping off the CNT, or the like. Moreover, the CNT in the form of short fibers can also be obtained by supporting a catalyst metal on a porous support such as porous silicon or on an anodized film of alumina to allow on a surface thereof vapor deposition of a CNT according to the CVD method. The CNT in the form of aligned short fibers can also be prepared according to a method in which a molecule such as iron phthalocyanine containing a catalyst metal in the molecule is used as a raw material, and a CNT is prepared on a substrate by performing CVD in a gas flow of argon/hydrogen. Furthermore, the CNT in the form of aligned short fibers can also be obtained on a SiC single crystal surface according to an epitaxial growth method.

A mean length in the longitudinal direction (also simply referred to as “length”) of the CNT used in the present invention is not particularly limited, but from the standpoints of durability, transparency, film-forming property, electrical conductivity, or the like, the length is preferably 0.01 μm or more and 2,000 μm or less, more preferably 0.01 μm or more and 2,000 μm or less, further preferably 1 μm or more, and particularly preferably 1 μm or more and 1,000 μm or less.

A diameter of the CNT used in the present invention is not particularly limited, but from the standpoints of durability, transparency, film-forming property, electrical conductivity, or the like, the diameter is preferably 0.4 nm or more to 100 nm or less, more preferably 50 nm or less, and further preferably 15 nm or less. In particular, a single-walled CNT is used, the diameter is preferably 0.5 nm or more and 3 nm or less, more preferably 1.0 nm or more and 3 nm or less, further preferably 1.5 nm or more and 2.5 nm or less, and particularly preferably 1.5 nm or more and 2.0 nm or less. The diameter can be measured by a method to be described later.

There are cases in which the CNT used in the present invention includes defective CNT. Such defects of the CNT degrade the electrical conductivity of the dispersion for a thermoelectric conversion layer and the like, and thus it is preferable to reduce the defects of the CNT. The amount of the defects of the CNT can be estimated from the ratio G/D (also referred to as “G/D ratio”) of the G band intensity to the D band intensity in the Raman spectrum. It can be assumed that a high G/D ratio indicates the CNT material including a small amount of defects. In particular, when a single-walled CNT may be used, the G/D ratio is preferably 10 or more, and more preferably 30 or more.

In a case where the nanocarbon material is a carbon nanohorn, a carbon nanofiber, a carbon nanofilament, a carbon nanocoil, vapor grown carbonfiber (VGCF), a cup-shaped nanocarbon substance, or the like, the length in the longitudinal direction is not particularly limited, but is the same as that of the CNT described above.

In a case where the nanocarbon material is a carbon nanowall, graphite, and graphene, the film thickness is not particularly limited, but is preferably 1 to 100 nm and the length of one side (average value) is preferably 1 to 100 μm.

In a case where the nanocarbon material is carbon nanoparticles, the diameter (average particle diameter) is not particularly limited, but is preferably 1 to 1,000 nm.

### 2. Nano-Metal Material

The nano-metal material is, for example, a fibrous or particulate metal material, and specific examples thereof include a fibrous metal material (also referred to as “a metal fiber”) and a particulate metal material (also referred to as “metal nanoparticles”). As the nano-metal material, metal nanowires to be described later are preferable.

The metal fiber is preferably in the form of solid fibers or hollow fibers. A metal fiber having a solid structure which has an average short axis length of 1 to 1,000 nm and an average long axis length of 1 to 100 μm is referred to as a metal nanowire. A metal fiber having a hollow structure which has an average short axis length of 1 to 1,000 nm and an average long axis length of 0.1 to 1,000 μm is referred to as a metal nanotube.

The material of the metal fiber may be a metal having electrical conductivity, and can be appropriately selected depending on the purposes. For example, as the material, a metal of at least one metal element selected from the group consisting of the metals of the 4th period, the 5th period and the 6th period of the Long Periodic Table (IUPAC 1991) is preferred; a metal of at least one metal element selected from the group consisting of Group 2 to Group 14 is more preferred; and a metal of at least one metal element selected from the group consisting of Group 2, Group 8, Group 9, Group 10, Group 11, Group 12, Group 13 and Group 14 is further preferred.

Specific examples of the metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, and alloys thereof. Among these, silver or an alloy containing silver is preferred from the standpoint of being excellent in electrical conductivity. Examples of a metal to be used for alloy containing silver include platinum, osmium, palladium, and iridium. It is particularly preferable to include the metal as a main component, and one kind thereof may be used alone or two or more kinds thereof may be used in combination.

The shape of the metal nanowires is not particularly limited as long as the metal nanowires are formed by the above-described metal and have a solid structure, and the shape thereof can be appropriately selected depending on the purposes. For example, it is possible to take an arbitrary shape such as a cylindrical shape, a rectangular parallelepiped shape, or a columnar shape with a polygonal cross-section. However, a cylindrical shape or a cross-sectional shape with a polygonal cross-section with rounded corners is preferred from the standpoint of increasing transparency of the thermoelectric conversion layer. The cross-sectional shape of the metal nanowires can be examined by observing the cross-section using a transmission electron microscope (TEM).

The average short axis length (referred to as “an average short axis diameter” or “an average diameter” in some cases) of the metal nanowires is preferably 50 nm or less, more preferably 1 to 50 nm, even more preferably 10 to 40 nm, and particularly preferably 15 to 35 nm, from the same standpoint as in the nano conductive material described above. The average short axis length is determined from the average value of measured short axis lengths obtained by observing 300 metal nanowires with a transmission electron microscope (TEM; JEM-2000FX manufactured by JEOL Ltd.). In cases where the short axis of the metal nanowires is not circular, the maximum length is used as the short axis length.

Similarly, the average long axis length (referred to as “an average length” in some cases) of the metal nanowires is preferably 1 μm or more, more preferably 1 to 40 μm, even more preferably 3 to 35 μM, and particularly preferably 5 to 30 μm. The average long axis length of the metal nanowires is, for example, determined from the average value of measured long axis lengths obtained by observing 300 metal nanowires with a transmission electron microscope (TEM; JEM-2000FX manufactured by JEOL Ltd.). When a metal nanowire is curved, a circle having the arc of the metal nanowire is taken into account and the value calculated from the radius and the curvature of the circle is used as the long axis length.

The metal nanowire may be produced by any method. The metal nanowire is preferably produced by reducing metal ions while heating in a solvent in which a halogen compound and a dispersant are dissolved, as described in JP-A-2012-230881. Detailed description of the halogen compound, the dispersant, the solvent, heating conditions, or the like is described in JP-A-2012-230881.

In addition to the above-described production methods, the methods described in JP-A-2009-215594, JP-A-2009-242880, JP-A-2009-299162, JP-A-2010-84173, JP-A-2010-86714 or the like may be used to manufacture the metal nanowires.

The shape of the metal nanotubes is not particularly limited as long as the metal nanotubes are formed by the above-described metal and have a hollow structure. The metal nanotubes may have a single-walled structure or a multi-walled structure. From the standpoint having excellent electrical conductivity and thermal conductivity, the metal nanotubes preferably have a single-walled structure.

The thickness (difference between the outer diameter and the inner diameter) of the metal nanotube is preferably from 3 nm to 80 nm, and more preferably from 3 nm to 30 nm, from the standpoint of durability, transparency, film-forming properties, and electrical conductivity. The average long axis length of the metal nanotubes is preferably 1 to 40 μm, more preferably 3 to 35 μm, and even more preferably 5 to 30 μm, from the same standpoint as in the nano conductive material described above. It is preferable that the average short axis length of the metal nanotubes be the same as the average short axis length of the metal nanowires.

The metal nanotubes may be produced by any method. For example, the method described in US 2005/0056118 or the like can be used to produce the metal nanotubes.

The metal nanoparticles may be metal fine particles having a particulate shape (including a powder shape) which are formed by the above-described metal, may also be metal fine particles or metal fine particles of which surfaces are covered with a protection agent, or may also be those obtained by dispersing, in a dispersion medium body, the metal fine particles of which surfaces are covered with a protection agent.

As a metal to be used in metal nanoparticles, among the above-described metals, silver, copper, gold, palladium, nickel, or rhodium is preferably exemplified. In addition, an alloy made of at least two or more kinds of these or an alloy made of iron and at least one kind of these can also be used. Examples of the alloy made of two kinds include a platinum-gold alloy, a platinum-palladium alloy, a gold-silver alloy, a silver-palladium alloy, a palladium-gold alloy, a rhodium-palladium alloy, a silver-rhodium alloy, a copper-palladium alloy, and a nickel-palladium alloy. Further, examples of the alloy with iron include an iron-platinum alloy, an iron-platinum-copper alloy, an iron-platinum-tin alloy, an iron-platinum-bismuth alloy, and an iron-platinum-lead alloy.

These metals or alloys can be used alone or two or more kinds thereof can be used in combination.

The average particle diameter (dynamic light scattering method) of the metal nanoparticles is preferably 1 to 150 nm from the standpoint of excellent electrical conductivity.

As the protecting agent of the metal fine particles, for example, a protecting agent described in JP-A-2012-222055 is preferably exemplified. Moreover, a protecting agent having a linear or branched alkyl chain with 10 to 20 carbon atoms, particularly, aliphatic acids or aliphatic amines, aliphatic thiols or aliphatic alcohols, and the like are further exemplified preferably. Here, when the number of carbon atoms is 10 to 20, storage stability of metal nanoparticles is high and electrical conductivity is also excellent. Aliphatic acids, aliphatic amines, aliphatic thiols, and aliphatic alcohols described in JP-A-2012-222055 are preferable.

The metal nanoparticles may be produced by any production method, and examples of the production method include an in-gas evaporation method, a sputtering method, a metal vapor synthesis method, a colloid method, an alkoxide method, a co-precipitation method, a homogeneous precipitation method, a thermal decomposition method, a chemical reduction method, an amine reduction method, and a solvent evaporation method. These production methods each have idiosyncratic features, but particularly, for the purpose of mass production, a chemical reduction method and an amine reduction method are preferably used. When these production methods are performed, as well as selecting and using the above-described protecting agent as necessary, a well-known reducing agent or the like can be appropriately used.

### <Dispersant>

In the method of preparing a dispersion for a thermoelectric conversion layer of the present invention, it is preferable to use a dispersant from the standpoint that the nano conductive material can be dispersed at high rate. That is, it is preferable that the dispersion for a thermoelectric conversion layer to be used in the present invention contain a dispersant.

The dispersant to be used in the present invention is not particularly limited as long as it inhibits the aggregation of the nano conductive material and assists the dispersing of the nano conductive material in the dispersion medium. The dispersant is preferably a low molecule dispersant and a conjugated polymer from the standpoint of the dispersibility of the nano conductive material, and a conjugated polymer is more preferable from the standpoint that the thermoelectric conversion performance of the thermoelectric conversion element can be improved.

### 1. Low Molecule Dispersant

The low molecule dispersant may be a low molecule dispersant having a smaller molecular weight than the conjugated polymer to be described later. Examples of the low molecule dispersant include amine compounds, porphyrin compounds and pyrene compounds. Specific examples thereof include octadecyl amine, 5,10,15,20-tetrakis(hexadecyloxyphenyl)-21H,23H-porphyrin, zinc porphyrin and zinc protoporphyrin.

Examples of the low molecule dispersant also include surfactants. Examples thereof include ionic (anionic, cationic, or zwitterionic (amphoteric)) surfactants and nonionic surfactants, and any one of these can be used in the present invention. Specific examples of the anionic surfactant include fatty acid salts and cholates as carboxylate and sodium linear alkylbenzenesulfonate and sodium lauryl sulfate as sulfonate. Specific examples of the cationic surfactant include an alkyl trimethyl ammonium salt, a dialkyldimethyl ammonium salt, an alkylbenzyldimethyl ammonium salt, and a dialkylimidazolium salt. Specific examples of the zwitterionic surfactant include an alkyldimethylamine oxide and an alkylcarboxy betaine. Specific examples of the nonionic surfactant include a polyoxyethylene alkyl ether, a fatty acid sorbitan ester, an alkyl polyglucoside, a fatty acid diethanolamide, and an alkylmonoglyceryl ether.

In the dispersion for a thermoelectric conversion layer to be used in the present invention, one kind of low molecule dispersant can be used alone or two or more kinds thereof can be used in combination.

### 2. Conjugated Polymer

The conjugated polymer is not particularly limited as long as it is a compound having a main chain with a structure which is conjugated by π electrons or a lone pair. Examples of such a conjugated structure include a structure in which a single bond and a double bond in a main chain are alternately bonded in a carbon-to-carbon bond.

Specific examples of these conjugated polymers include conjugated polymers having a repeating unit of a monomer, by polymerizing or co-polymerizing the monomer, the monomer may be selected form a thiophene compound, a pyrrole compound, an aniline compound, an acetylene compound, a p-phenylene compound, a p-phenylenevinylene compound, a p-phenyleneethynylene compound, a p-fluorenylenevinylene compound, a p-fluorene compound, aromatic polyamine compound (referred to as “arylamine compound”), a polyacene compound, a polyphenanthrene compound, a metal-phthalocyanine compound, a p-xylylene compound, a vinylenesulfide compound, a m-phenylene compound, a naphthalenevinylene compound, a p-phenyleneoxide compound, a phenylenesulfide compound, a furan compound, a selenophene compound, an azo compound, a metal complex compound, and a derivative which substitutes a hydrogen atom of these compounds with the substituent (referred to as “introducing a substituent into a compound”). All of the above-described compounds have no substituent, and a compound having a substituent is referred to as a derivative.

Among them, a conjugated polymer, which is obtained by polymerization or copolymerization of at least one compound or derivate selected from the group consisting of a thiophene compound, a pyrrole compound, an aniline compound, an acetylene compound, a p-phenylene compound, a p-phenylenevinylene compound, a p-phenyleneethynylene compound, a fluorene compound, an arylamine compound, and derivatives thereof, is preferable from the standpoint of the dispersibility of the nano conductive material and the thermoelectric conversion performance.

A substituent to be introduced into the compound described above is not particularly limited, but a substituent which can improve the dispersibility of the conjugated polymer in the dispersion medium is preferable in consideration of compatibility with other components, varieties of dispersion mediums to be used, and the like.

Such a substituent is not particularly limited, and for example, substituents which R¹ to R¹³ in the following Formulae (1) to (5) may have are preferably exemplified.

When an organic solvent is used as the medium, preferable examples of the substituent include a linear, branched, or cyclic alkyl group, alkoxy group, or thioalkyl (alkylthio) group, and also alkoxyalkyleneoxy group, alkoxyalkyleneoxyalkyl group, crown ether group, aryl group. These groups may further have a substituent.

The number of carbon atoms of the substituent is not particularly limited, but is preferably 1 to 12, and more preferably, 4 to 12. Alkyl group, alkoxy group, thioalkyl group, alkoxyalkyleneoxy group, or alkoxyalkyleneoxyalkyl group, each of them has a long-chain with 6 to 12 carbon atoms, is particularly preferred.

When an aqueous medium is used as the medium, it is preferable that each of the monomer or the above-described substituent further has a hydrophilic group such as a carboxylic acid group, a sulfonate group, a hydroxyl group, and a phosphate group. In addition thereto, a dialkylamino group, a monoalkylamino group, an amino group not substituted with alkyl group, a carboxyl group, an alkoxycarbonyl group, an aryloxycarbonyl group, an acyloxy group, an amide group, a carbamoyl group, a nitro group, a cyano group, an isocyanate group, an isocyano group, a halogen atom, a perfluoroalkyl group, a perfluoroalkoxy group, or the like can be introduced as the substituent, and such introduction is preferred.

The number of substituents is not particularly limited, but in consideration of the dispersibility and the compatibility of the electrically conductive polymer, the electrical conductivity, and the like, one or a plurality of substituents can be introduced as appropriate.

As the thiophene-based conjugated polymer obtained by polymerization or copolymerization of a thiophene compound and a derivative thereof, a conjugated polymer having a thiophene compound and a derivative thereof as repeating structures may be used, and examples thereof include polythiophene containing a repeating structure derived from thiophene, a conjugated polymer containing a repeating structure derived from a derivative of a thiophene compound having a substituent introduced into a thiophene ring, and a conjugated polymer containing a repeating structure derived from a thiophene compound having a condensed polycyclic structure including a thiophene ring.

As the thiophene-based conjugated polymer, the conjugated polymer containing a repeating structure derived from a derivative and the conjugated polymer containing a repeating structure derived from a thiophene compound having the condensed polycyclic structure are preferable.

Examples of the conjugated polymer containing a repeating structure derived from a derivative of a thiophene compound having a substituent introduced into a thiophene ring include a conjugated polymer containing a repeating structure represented by the following Formula (1). Examples of the conjugated polymer include poly-alkyl-substituted thiophene-based conjugated polymers such as poly-3-methylthiophene, poly-3-butylthiophene, poly-3-hexylthiophene, poly-3-cyclohexylthiophene, poly-3-(2′-ethylhexyl)thiophene, poly-3-octylthiophene, poly-3-dodecylthiophene, poly-3-(2′-methoxyethoxy)methylthiophene, and poly-3-(methoxyethoxyethoxy)methylthiophene; poly-alkoxy-substituted thiophene-based conjugated polymers such as poly-3-methoxythiophene, poly-3-ethoxythiophene, poly-3-hexyloxythiophene, poly-3-cyclohexyloxythiophene, poly-3-(2-ethylhexyloxy)thiophene, poly-3-dodecyloxythiophene, poly-3-methoxy(diethyleneoxy)thiophene, poly-3-methoxy(triethyleneoxy)thiophene, and poly-(3,4-ethylenedioxythiophene); poly-3-alkoxy-substituted-4-alkyl-substituted thiophene-based conjugated polymers such as poly-3-methoxy-4-methylthiophene, poly-3-hexyloxy-4-methylthiophene, and poly-3-dodecyloxy-4-methylthiophene; and poly-3-thioalkylthiophene-based conjugated polymers such as poly-3-thiohexylthiophene, poly-3-thiooctylthiophene, and poly-3-thiododecylthiophene.

As the thiophene-based conjugated polymer, a conjugated polymer containing a repeating structure represented by the following Formula (1) is preferable, and among the above-described examples, a poly(3-alkyl-substituted thiophene)-based conjugated polymer and a poly(3-alkoxy-substituted thiophene)-based conjugated polymer are preferable.

With regard to polythiophene-based conjugated polymer having a substituent in 3-position, anisotropy arises depending on a bonding direction in 2- or 5-position of a thiophene ring. In polymerization of 3-substituted thiophene, a mixture is produced, including one in which the thiophene rings are bonded in 2-positions with each other (HH coupling: head-to-head), one in which the thiophene rings are bonded in 2-position and 5-position (HT coupling: head-to-tail), or one in which the thiophene rings are bonded in 5-positions with each other (TT coupling: tail-to-tail). A larger ratio of the one in which the thiophene rings are bonded in 2-position and the 5-position is preferred in view of further improved planarity of a polymer main chain to further easily form a π-π stacking structure between the polymers and to further facilitate transfer of electric charges. Ratios of these bonding patterns can be measured by a nuclear magnetic resonance analysis (¹H-NMR). The content ratio of the HT coupling in the thiophene-based conjugated polymer is preferably 50% by mass or more, more preferably 70% by mass or more, and particularly preferably 90% by mass or more.

More specifically, as the conjugated polymer containing a repeating structure derived from a derivative of a thiophene compound having a substituent introduced into a thiophene ring and the conjugated polymer containing a repeating structure derived from a thiophene compound having the condensed polycyclic structure described above, the following A-1 to A-17 can be exemplified. In addition, conjugated polymers including repeating structures A-18 to A-26 to be described later can also be exemplified. In the following formulae, n represents an integer of 10 or more, and “^{t}Bu” represents a t-butyl group.

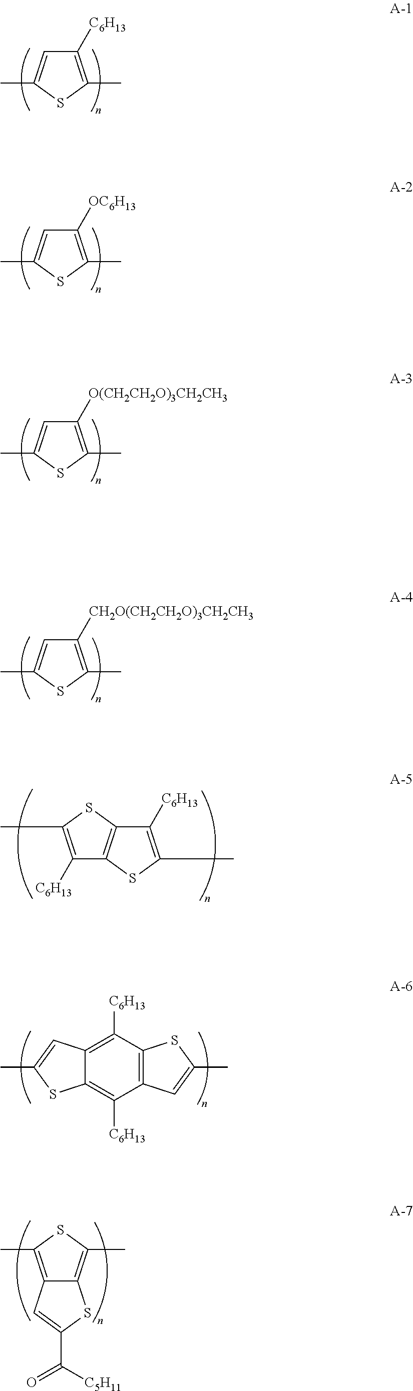

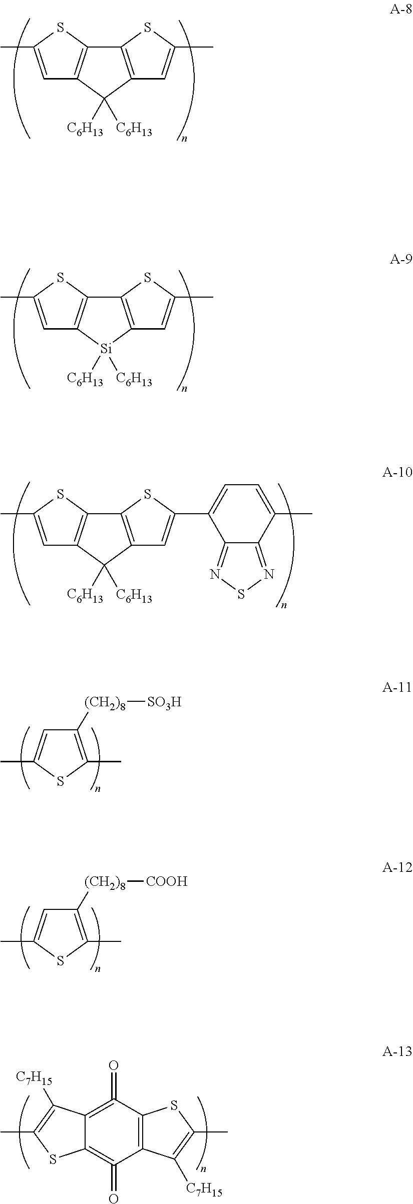

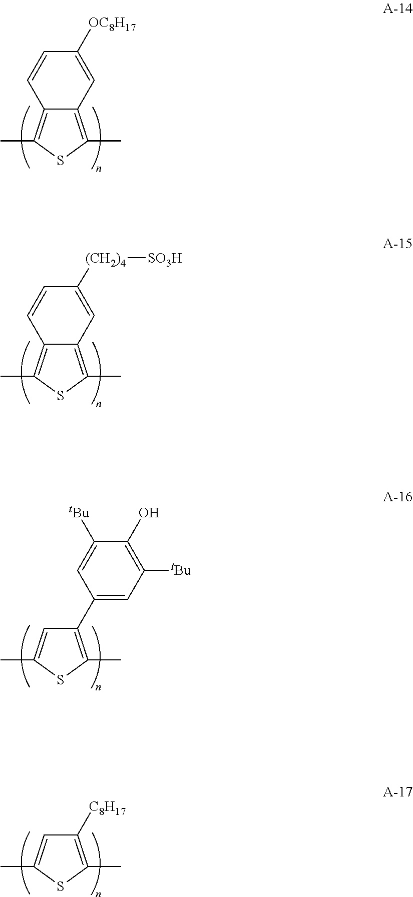

As the pyrrole-based conjugated polymer obtained by polymerization or copolymerization of a pyrrole compound and a derivative thereof, a conjugated polymer having a pyrrole compound and a derivative thereof as repeating structures may be used, and examples thereof include polypyrrole containing a repeating structure derived from pyrrole, a conjugated polymer containing a repeating structure derived from a derivative of a pyrrole compound having a substituent introduced into a pyrrole ring, and a conjugated polymer containing a repeating structure derived from a pyrrole compound having a condensed polycyclic structure including a pyrrole ring.

As the pyrrole-based conjugated polymer, for example, the following polymers B-1 to B-8 can be exemplified. In the following formulae, n represents an integer of 10 or more.

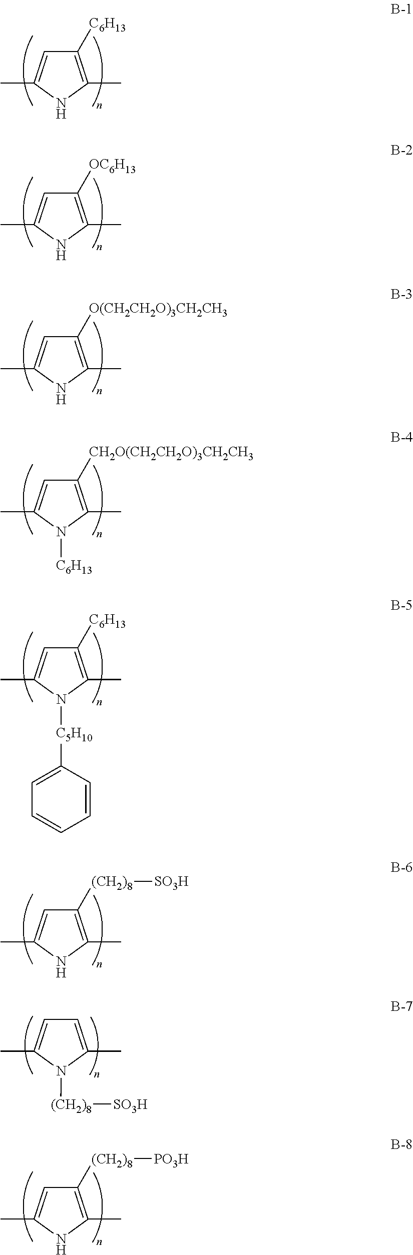

As the aniline-based conjugated polymer obtained by polymerization or copolymerization of a aniline compound and a derivative thereof, a conjugated polymer having a aniline compound and a derivative thereof as repeating structures may be used, and examples thereof include polyaniline containing a repeating structure derived from aniline, a conjugated polymer containing a repeating structure derived from a derivative of a aniline compound having a substituent introduced into a benzene ring of aniline, and a conjugated polymer containing a repeating structure derived from a aniline compound having a condensed polycyclic structure including a benzene ring of aniline.

As the aniline-based conjugated polymer, for example, the following polymers C-1 to C-8 can be exemplified. In the following formulae, n represents an integer of 10 or more; y represents mole ratio when total mole quantity of the copolymer components is set to 1, and is more than 0 and less than 1.

The following polymer C-1 represents a copolymer component and a molar ratio thereof, and the bonding pattern of the copolymer component is not limited to the following pattern.

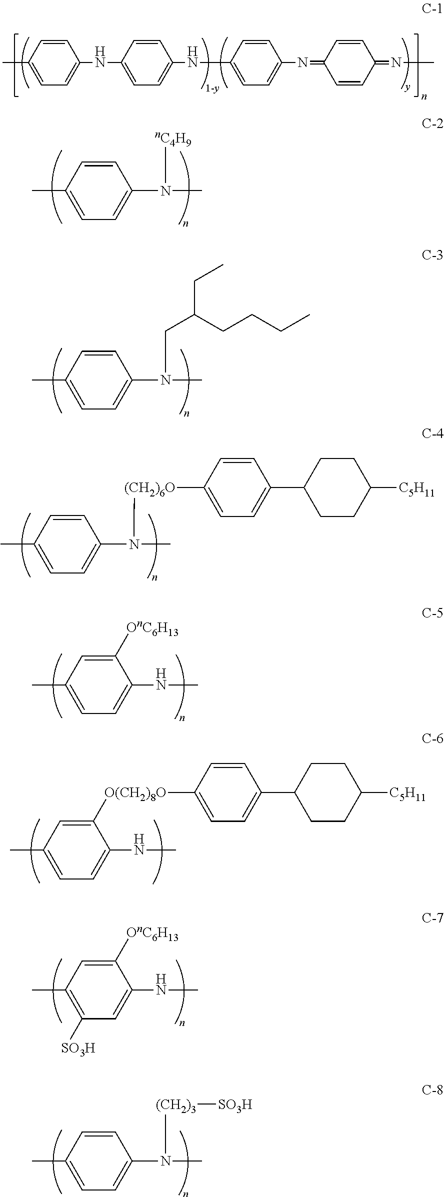

As the acetylene-based conjugated polymer obtained by polymerization or copolymerization of a acetylene compound and a derivative thereof a conjugated polymer having a acetylene compound and a derivative thereof as repeating structures may be used. For example, the following polymers D-1 to D-3 can be exemplified. In the following formulae, n represents an integer of 10 or more.

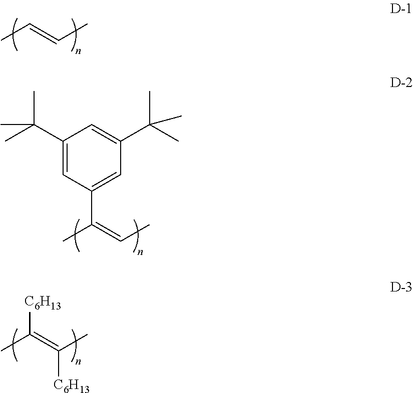

As the p-phenylene conjugated polymer obtained by polymerization or copolymerization of a p-phenylene compound and a derivative thereof, a conjugated polymer having a p-phenylene compound and a derivative thereof as a repeating structure may be used. For example, the following polymers E-1 to E-9 can be exemplified. In the following formulae, n represents an integer of 10 or more. Further, in the following polymer E-2, Ac represents an acetyl group.

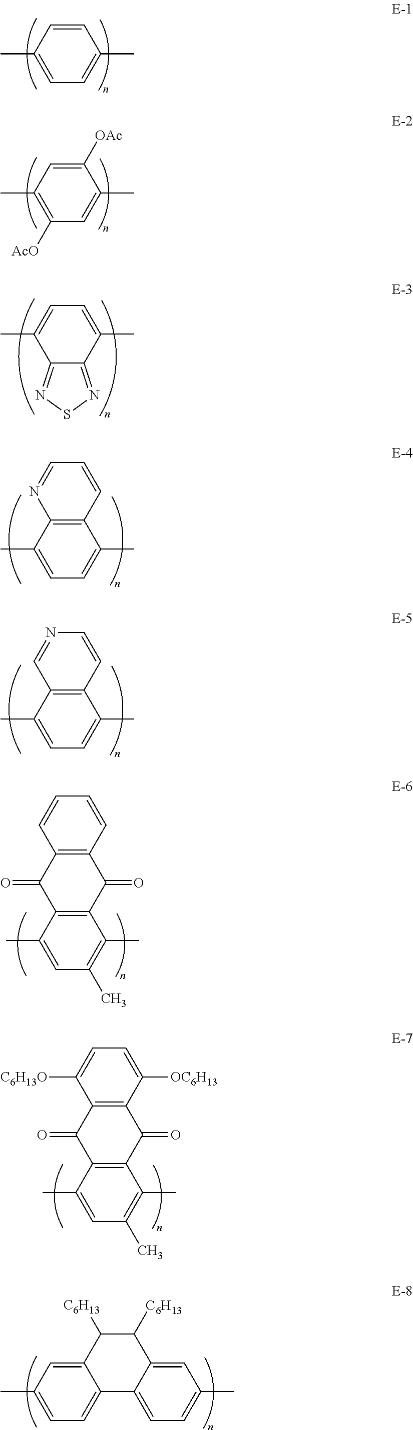

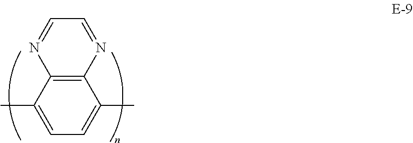

As the p-phenylenevinylene-based conjugated polymer obtained by polymerization or copolymerization of a p-phenylenevinylene compound and a derivative thereof, a conjugated polymer having a p-phenylenevinylene compound and a derivative thereof as repeating structures may be used. For example, the following polymers F-1 to F-3 can be exemplified. In the following formulae, n represents an integer of 10 or more.

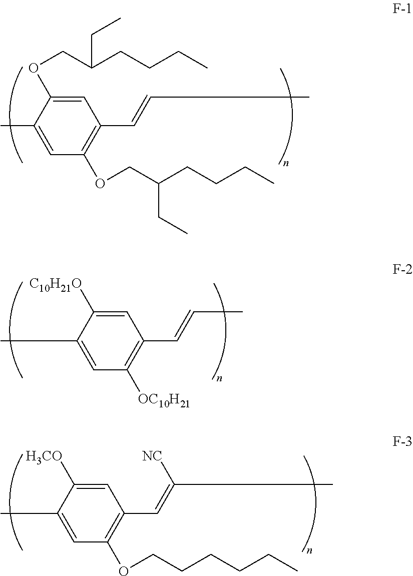

As the p-phenyleneethynylene-based conjugated polymer obtained by polymerization or copolymerization of a p-phenyleneethynylene compound and a derivative thereof, a conjugated polymer having a p-phenyleneethynylene compound and a derivative thereof as repeating structures may be used. For example, the following polymers G-1 and G-2 can be exemplified. In the following formulae, n represents an integer of 10 or more.

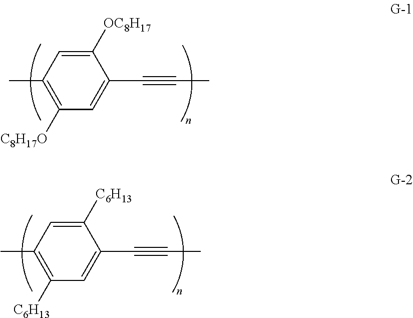

As a conjugated polymer obtained by polymerization or copolymerization of a compound other than the above-described compounds and a derivative thereof, a conjugated polymer having a compound other than the above-described compounds and a derivative thereof as a repeating structure may be used. For example, the following polymers H-1 to H-13 can be exemplified. In the following formulae, n represents an integer of 10 or more.

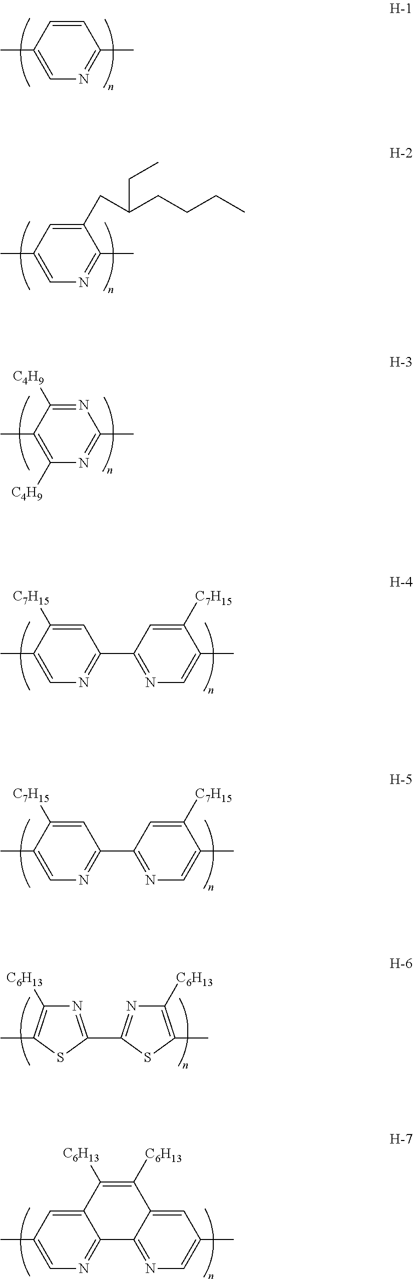

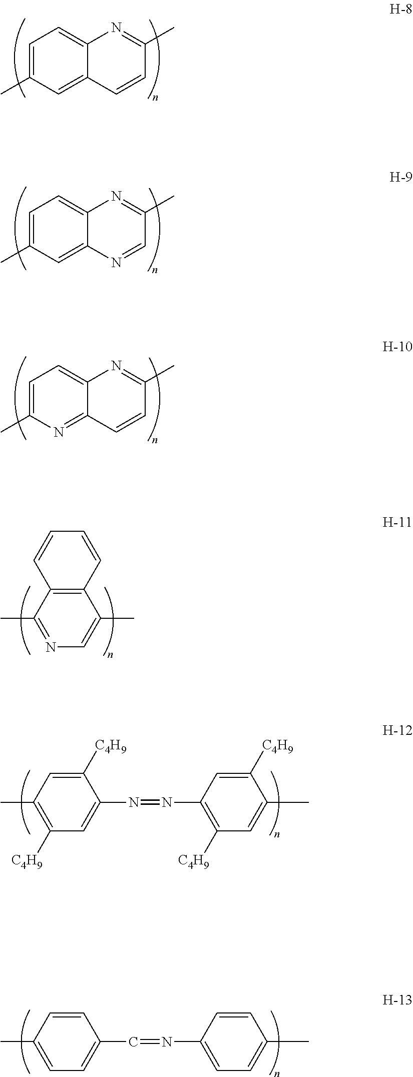

Among the above-described conjugated polymers, a linear conjugated polymer is preferably used. Such a linear conjugated polymer can be obtained, for example, in a case of the polythiophene-based polymer or the polypyrrole-based polymer, by bonding of the thiophene rings or pyrrole rings of each monomer in 2-position and 5-position, respectively. In a case of the poly-p-phenylene-based polymer, the poly-p-phenylenevinylene-based polymer, or the poly-p-phenyleneethynylene-based polymer, such a linear conjugated polymer can be obtained by bonding of the phenylene groups of each monomer in a para position (1-position and 4-position).

The conjugated polymer used in the present invention may have the above-mentioned repeating structures (hereinafter, a monomer to form this repeating structures is also referred to as “first monomer (group of first monomers)”) alone in one kind or two or more kinds. Moreover, the conjugated polymer may simultaneously have a repeating structure derived from a monomer having any other structure (hereinafter, also referred to as “second monomer”), in addition to the repeating unit derived from the first monomer. In a case of a conjugated polymer formed of a plurality of kinds of repeating structures, the polymer may be a block copolymer, a random copolymer, or a graft polymer.

Specific examples of the second monomers having other structures used in combination with the above-described first monomer include a monomer derived from a carbazole compound, and a monomer derived from a dibenzo[b,d]silole group, a cyclopenta[2,1-b; 3,4-b′]dithiophene group, a pyrrolo[3,4-c]pyrrole-1,4(2H,5H)-dione group, a benzo[2,1,3]thiadiazole-4,8-diyl group, an azo group, a 5H-dibenzo[b,d]silole group, a thiazole group, an imidazole group, an oxadiazole group, a thiadiazole group, or a triazole group, and a derivative formed by further introducing a substituent into each of these compounds. Specific examples of the substituents to be introduced thereinto include ones similar to the above-mentioned substituents.

The conjugated polymer used in the present invention has the repeating structures derived from one kind or a plurality of kinds of monomers selected from the group of first monomers in an amount of preferably 50% by mass or more, and more preferably 70% by mass or more, in total, in the conjugated polymer. The conjugated polymer further preferably consists of the repeating structures derived from one kind or a plurality of kinds of monomers selected from the group of the first monomers. The conjugated polymer is particularly preferably a conjugated polymer consisting of a single repeating structure derived from a monomer selected from the group of the first monomers.

Among the groups of the first monomers, a polythiophene polymer including a repeating structure derived from a thiophene compound and a derivative thereof is preferably used. In particular, a polythiophene-based conjugated polymer having a repeating structure derived from compounds, derivatives thereof, or thiophene compounds having a condensed polycyclic structure (thiophene ring-containing condensed aromatic ring structure), represented respectively by the following formulae (1) to (5), is preferred.

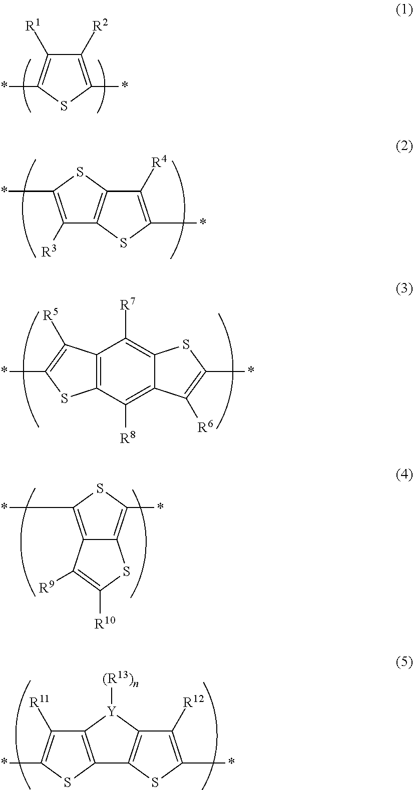

In formulae (1) to (5), R¹ to R¹³ each independently represent a hydrogen atom, a halogen atom, an alkyl group, an alkoxy group, an alkyl group substituted with a fluorine atom, an alkoxy group substituted with a fluorine atom, an amino group, an alkylthio group, a polyalkyleneoxy group, an acyloxy group, or an alkyloxycarbonyl group; Y represents a carbon atom, a nitrogen atom or a silicon atom; n represents an integer of 1 when Y is a nitrogen atom, or n represents an integer of 2 when Y is a carbon atom or a silicon atom; and the symbol “*” represents a connection site of each repeating structure.

In R¹ to R¹³, examples of the halogen atom include a fluorine atom, a chlorine atom, a bromine atom and an iodine atom. Among these, a fluorine atom and a chlorine atom are preferable.

The alkyl group includes a linear, branched or cyclic alkyl group. The alkyl group is preferably an alkyl group having 1 to 14 carbon atoms. Specific examples thereof include methyl, ethyl, n-propyl, i-propyl, n-butyl, t-butyl, s-butyl, n-pentyl, t-amyl, n-hexyl, 2-ethylhexyl, octyl, nonyl, decyl, dodecyl, and tetradecyl.

The alkoxy group is preferably an alkoxy group having 1 to 14 carbon atoms. Specific examples thereof include methoxy, ethoxy, n-propyloxy, i-propyloxy, n-butoxy, t-butoxy, s-butoxy, n-pentyloxy, t-amyloxy, n-hexyloxy, 2-ethylhexyloxy, octyloxy, nonyloxy, decyloxy, dodecyloxy, and tetradecyloxy.

The alkyl group substituted with a fluorine atom is preferably an alkyl group substituted with a fluorine atom which has 1 to 10 carbon atoms. Specific examples thereof include a perfluoroalkyl group such as CF₃—, CF₃CF₂—, n-C₃F₇—, i-C₃F₇—, n-C₄F₉—, t-C₄F₉—, s-C₄F₉—, n-C₅F₁₁—, CF₃CF₂C(CF₃)₂—, n-C₆F₁₃—, C₈F₁₇—, C₉F₁₉—, and C₁₀F₂₁—. Another examples thereof include an alkyl group in which a part of hydrogen atoms is substituted with a fluorine atom, such as CF₃(CF₂)₂CH₂—, CF₃(CF₂)₄CH₂—, and CF₃(CF₂)₅CH₂CH₂—.

The alkoxy group substituted with a fluorine atom is preferably an alkoxy group substituted with a fluorine atom which has 1 to 10 carbon atoms. Specific examples thereof include a perfluoroalkoxy group such as CF₃O—, CF₃CF₂O—, n-C₃F₇O—, i-C₃F₇O—, n-C₄F₉O—, t-C₄F₉O—, s-C₄F₉O—, n-C₅F₁₁O—, CF₃CF₂C(CF₃)₂O —, n-C₆F₁₃O —, C₈F₁₇O —, C₉F₁₉O —, and C₁₀F₂₁O —. Another examples thereof include an alkoxy group in which a part of hydrogen atoms is substituted with a fluorine atom, such as CF₃(CF₂)₂CH₂O—, CF₃(CF₂)₄CH₂O—, and CF₃(CF₂)₅CH₂CH₂O—.

The amino group includes an alkyl amino group and an arylamino group. The amino group is preferably an amino group having 0 to 16 carbon atoms. Specific examples thereof include amino, monoethylamino, diethylamino, monohexylamino, dihexylamino, dioctylamino, monododecyl amino, diphenylamino, dixylylamino, ditolylamino, and monophenylamino.

The alkylthio group is preferably an alkylthio group having 1 to 14 carbon atoms. Specific examples thereof include CH₃S—, CH₃CH₂S—, n-C₃H₇S—, i-C₃H₇S—, n-C₄H₉S—, t-C₄H₉S—, s-C₄H₉S—, n-C₅H₁₁S—, CH₃CH₂C(CH₃)₂S—, n-C₆H₁₃S—, cyclo-C₆H₁₁S—, CH₃(CH₂)₅CH₂CH₂S—, C₆H₁₃S—, C₈H₁₇S—, C₉H₁₉S—, C₁₀H₂₁S—, and 2-ethylhexylthio.

The polyalkyleneoxy group is preferably a polyalkyleneoxy group having 3 to 20 carbon atoms. Specific examples thereof include polyethyleneoxy, and polypropyleneoxy.

The acyloxy group is preferably an acyloxy group having 1 to 14 carbon atoms. Specific examples thereof include acetyloxy, ethylcarbonyloxy, butylcarbonyloxy, octylcarbonyloxy, dodecylcarbonyloxy, and phenylcarbonyloxy.

The alkyloxycarbonyl group is preferably an alkyloxycarbonyl group having 1 to 14 carbon atoms. Specific examples thereof include methoxycarbonyl, ethoxycarbonyl, n-propyloxycarbonyl, iso-propyloxycarbonyl, n-butoxycarbonyl, t-butoxycarbonyl, n-hexyloxycarbonyl, dodecyloxycarbonyl.

These groups may be further substituted.

R¹ to R¹³ each are preferably an alkyl group, an alkoxy group, an amino group, an alkylthio group, a polyalkyleneoxy group, or a hydrogen atom; more preferably an alkyl group, an alkoxy group, an alkylthio group, or a polyalkyleneoxy group; and particularly preferably an alkyl group, an alkoxy group, or a polyalkyleneoxy group.

Y is preferably a carbon atom or a nitrogen atom, and more preferably a carbon atom.

As the repeating structure represented by any one of Formulae (1) to (5), the following repeating structures A-18 to A-26 can be exemplified. However, the present invention is not limited thereto.

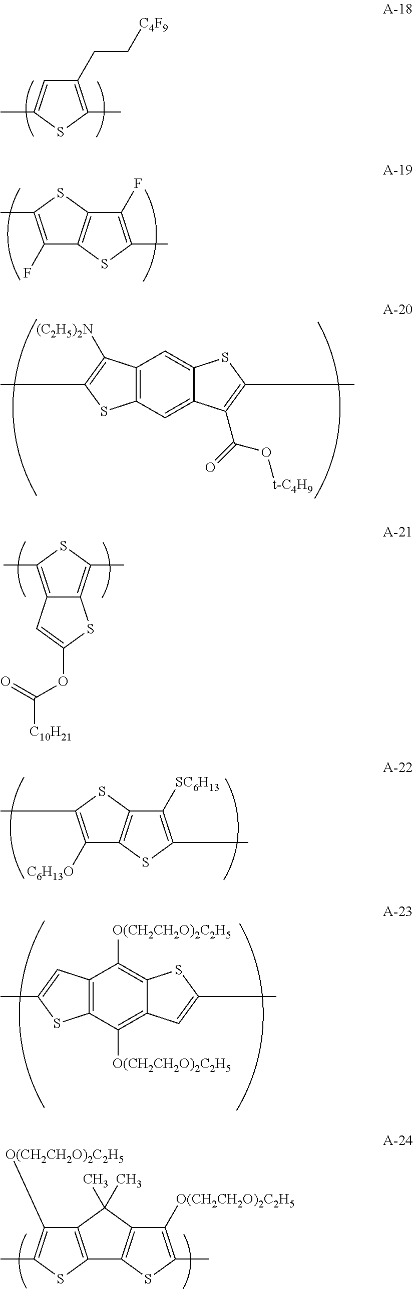

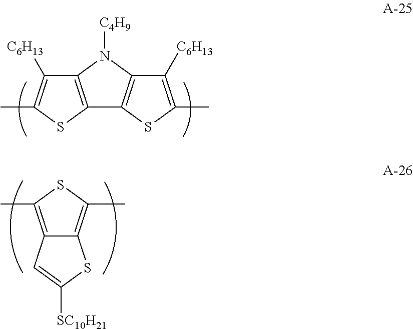

The molecular weight of the above-described conjugated polymer is not particularly limited, and a polymer having a high molecular weight as well as an oligomer (for example, a weight average molecular weight of about 1,000 to 10,000) having a molecular weight less than that may be used.

From the standpoint of achieving high electrical conductivity, the conjugated polymer is preferably hardly degradable by acid, light, or heat. In order to achieve high electrical conductivity, the conjugated polymer which may generate the intramolecular carrier transfer through a long conjugated chain of the conjugated polymer and the intermolecular carrier hopping is preferable. In order to achieve the purpose, the molecular weight of the conjugated polymer is preferably large to some extent. From this standpoint, the molecular weight of the conjugated polymer used in the present invention is preferably 5,000 or more, more preferably 7,000 to 300,000, and further preferably 8,000 to 100,000 in terms of weight average molecular weight. The weight average molecular weight can be measured by gel permeation chromatography (GPC).

These conjugated polymers can be produced by allowing polymerization of the above-described monomer by a method in accordance with an ordinary oxidation polymerization process.

Moreover, commercially available products can also be used. A specific example includes regioregular poly(3-hexylthiophene-2,5-diyl) manufactured by Aldrich Corporation.

In addition to the above-described conjugated polymers, examples of the conjugated polymer for use in the present invention include a conjugated polymer containing at least a fluorene structure represented by Formula (1A) or (1B) as a repeating unit.

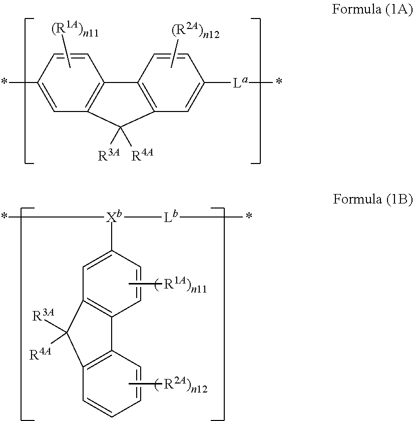

In the Formulae, R^{1A} and R^{2A} each independently represent a substituent. R^{3A} and R^{4A} each independently represent an aromatic hydrocarbon ring group, an aromatic heterocyclic group, an alkyl group or an alkoxy group. Herein, R^{3A} and R^{4A} may be bonded to each other to form a ring. n11 and n12b each independently represent an integer of 0 to 3, and n12 represents an integer of 0 to 2. L^{a} represents a single bond, —N(Ra1)-, or a linking group formed by combination of groups selected from the group consisting of a divalent aromatic hydrocarbon ring group, a divalent aromatic heterocyclic group and —N(Ra1)-. L^{b} represents a single bond, a divalent aromatic hydrocarbon ring group, a divalent aromatic heterocyclic group, —N(Ra1)-, or a linking group formed by combination of these groups. Herein, Ra1 represents a substituent. X^{b} represents a trivalent aromatic hydrocarbon ring group, a trivalent aromatic heterocyclic group, or >N—. The symbol “*” represents a binding site.

Examples of the substituent represented by R^{1A} and R^{2A} include those exemplified as the following substituent W1.

### (Substituent W1)

Examples of the substituent W1 include a halogen atom, an alkyl group, an alkenyl group, an alkynyl group, a cycloalkyl group, a cycloalkenyl group, an aryl group (also referred to as “aromatic hydrocarbon ring group”), a diarylboryl group, a dihydroxyboryl group, a dialkoxyboryl group, a heterocyclic group (including a heteroaryl group (also referred to as “aromatic heterocyclic group”), and preferred examples of the atom for forming the ring of the group include an oxygen atom, a sulfur atom, a nitrogen atom, a silicon atom, and a boron atom), an alkoxy group, an aryloxy group, an alkylthio group, an arylthio group, an alkyl- or aryl-sulfonyl group, an alkyl- or aryl-sulfinyl group, an amino group (including an amino group, an alkylamino group, an arylamino group, and a heterocyclic amino group), an acylamino group, an alkyl- or aryl-sulfonamide group, an alkyl- or aryl-carbamoyl group, an alkyl- or aryl-sulfamoyl group, an acyl group, an alkoxycarbonyl group, an aryloxycarbonyl group, an acyloxy group, a ureido group, an urethane group, an imide group, a hydroxy group, a cyano group, and a nitro group.

Among these, an aromatic hydrocarbon ring group, a heterocyclic group, an alkyl group, an alkoxy group, an alkylthio group, an amino group, and a hydroxy group are preferred; an aromatic hydrocarbon ring group, a heterocyclic group, an alkyl group, an alkoxy group, and a hydroxy group are more preferred; an aromatic hydrocarbon ring group, an aromatic heterocyclic group, an alkyl group, and an alkoxy group are further preferred; and an alkyl group is particularly preferred.

When R^{1A} and R^{2A} are an alkylthio group, the number of carbon atoms is preferably 1 to 24, more preferably 1 to 20, and further preferably 6 to 16. The alkylthio group may have a substituent, and examples of the substituent include those exemplified as the above-described substituent W1.

Examples of the alkylthio group include methylthio, ethylthio, isopropylthio, t-butylthio, n-hexylthio, n-octylthio, 2-ethylhexylthio, and n-octadecylthio.

When R^{1A} and R^{2A} are an amino group, the number of carbon atoms is preferably 0 to 24, more preferably 1 to 20, and further preferably 1 to 16. Examples of the amino group include amino, methylamino, N,N-diethylamino, phenylamino, and N-methyl-N-phenylamino. Among these, an alkyl amino group and an arylamino group are preferable.

The alkyl amino group, the arylamino group and the heterocyclic amino group may have a substituent, and examples of the substituent include those exemplified as the above-described substituent W1.

When R^{1A} and R^{2A} each are an aromatic hydrocarbon ring group, an aromatic heterocyclic group, an alkyl group or an alkoxy group, examples thereof include the aromatic hydrocarbon ring group, the aromatic heterocyclic group, the alkyl group and the alkoxy group of R^{3A} and R^{4A} described below.

The number of carbon atoms of the alkyl group and the alkoxy group is preferably 1 to 18, more preferably 1 to 12, and further preferably 1 to 8.

Preferable ranges of the aromatic hydrocarbon ring group and the aromatic heterocyclic group are the same as those of R^{3A} and R^{4A}.

n11 and n12 each are preferably 0 or 1.

The number of carbon atoms of the aromatic hydrocarbon ring of the aromatic hydrocarbon ring group represented by R^{3A} and R^{4A} is preferably 6 to 24, more preferably 6 to 20, and further preferably 6 to 18. Examples of the aromatic hydrocarbon ring include a benzene ring and a naphthalene ring. This ring may be fused with a ring such as an aromatic hydrocarbon ring, an aliphatic hydrocarbon ring and a heterocycle. The aromatic hydrocarbon ring group may have a substituent, and examples of the substituent include those exemplified as the above-described substituent W1. As the substituent, an alkyl group, an alkoxy group, an alkylthio group, an amino group, and a hydroxy group are preferred; an alkyl group, an alkoxy group, and a hydroxy group are more preferred; and an alkyl group, and an alkoxy group are further preferred.

The number of carbon atoms of the aromatic heterocycle of the aromatic heterocyclic group represented by R^{3A} and R^{4A} is preferably 2 to 24, more preferably 3 to 20, and further preferably 3 to 18. The atom for forming the ring of the aromatic heterocycle is preferably a nitrogen atom, an oxygen atom, and a sulfur atom. Moreover, the aromatic heterocycle is preferably a 5-membered or 6-membered ring. This ring may be fused with a ring such as an aromatic hydrocarbon ring, an aliphatic hydrocarbon ring and a heterocycle. The aromatic heterocyclic group may have a substituent, and examples of the substituent include those exemplified as the above-described substituent W1. As the substituent, an alkyl group, an alkoxy group, and an alkylthio group are preferred; an alkyl group, and an alkoxy group are more preferred; and an alkyl group is further preferred.

Examples of the aromatic heterocyclic group include a pyrrole ring, a thiophene ring, an imidazole ring, a pyrazole ring, a thiazole ring, an isothiazole ring, a pyridine ring, a pyrimidine ring, a pyridazine ring, a pyrazine ring, a triazine ring, an indole ring, an isoindole ring, a quinoline ring, an isoquinoline ring, a quinazoline ring, a phthalazine ring, a pteridine ring, a coumarin ring, a chromone ring, a 1,4-benzodiazepine ring, a benzimidazole ring, a benzofuran ring, a purine ring, an acridine ring, a phenoxazine ring, a phenothiazine ring, a furan ring, a selenophene ring, a tellurophene ring, an oxazole ring, an isoxazole ring, a pyridone-2-one ring, a selenopyran ring, and a telluropyran ring. Among these, a thiophene ring, a pyrrole ring, a furan ring, an imidazole ring, a pyridine ring, a quinoline ring, and an indole ring are preferred.

The number of carbon atoms of the alkyl group represented by R^{3A} and R^{4A} is preferably 1 to 24, more preferably 1 to 20, and further preferably 6 to 16. The alkyl group may be a linear, branched or cyclic alkyl group. Further, the alkyl group may have a substituent, and examples of the substituent include those exemplified as the above-described substituent W 1.

Examples of the alkyl group include methyl, ethyl, iso-propyl, t-butyl, n-hexyl, n-octyl, 2-ethylhexyl, and n-octadecyl.

The number of carbon atoms of the alkoxy group represented by R^{3A} and R^{4A} is preferably 1 to 24, more preferably 1 to 20, and further preferably 6 to 16. The alkoxy group may have a substituent, and examples of the substituent include those exemplified as the above-described substituent W1.

Examples of the alkoxy group include methoxy, ethoxy, iso-propyloxy, t-butoxy, n-hexyloxy, n-octyloxy, 2-ethylhexyloxy, and n-octadecyloxy.

It is preferable that at least one of R^{3A} and R^{4A} is an aromatic hydrocarbon ring group or an aromatic heterocyclic group.

R^{3A} and R^{4A} may be bonded to each other to form a ring. The ring is preferably 3- to 7-membered ring, and may be a saturated hydrocarbon ring, an unsaturated hydrocarbon ring, an aromatic hydrocarbon ring, or a heterocycle (including an aromatic heterocycle). The formed ring may be a monocyclic ring or a fused polycyclic ring. The formed ring may have a substituent, and examples of the substituent include those exemplified as the above-described substituent W1.

In the present invention, these formed rings are preferably a fluorene ring, and a ring having a Spiro structure in 9-position, that is, the following structure is preferable.

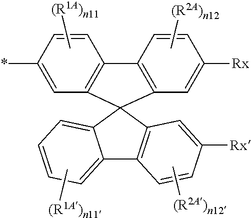

Herein, R^{1A}, R^{2A}, n11 and n12 each have the same meaning as R^{1A}, R^{2A}, n11 and n12 in Formulae (1A) and (1B); and preferable ranges thereof are also the same.

R^{1A}′, R^{2A}′ and n12′ each have the same meaning as R^{1A}, R^{2A} and n12; and preferable ranges thereof are also the same. n11′ represents an integer of 0 to 4.

In the case of Formula (1A) (that is, a case where two benzene rings of fluorene rings are incorporated into a polymer main chain), Rx represents a bonding hand. In the case of Formula (1B) (that is, a case where one benzene ring is bonded to a polymer main chain), Rx represents a hydrogen atom or a substituent. Examples of the substituent represented by Rx include those exemplified as the above-described substituent W1. Among these, an aromatic hydrocarbon ring group, a heterocyclic group, an alkyl group, an alkoxy group, an alkylthio group, an amino group, and a hydroxy group are preferred; an alkyl group, an alkoxy group, and a hydroxy group are more preferred; and an alkyl group is particularly preferred.

Rx′ represents a hydrogen atom or a substituent. Examples of the substituent represented by Rx′ include those exemplified as the above-described substituent W1. Among these, an aromatic hydrocarbon ring group, a heterocyclic group, an alkyl group, an alkoxy group, an alkylthio group, an amino group, and a hydroxy group are preferred; an alkyl group, an alkoxy group, and a hydroxy group are more preferred; and an alkoxy group is particularly preferred.

The symbol “*” represents a binding site.

The number of carbon atoms of the aromatic hydrocarbon ring of the divalent aromatic hydrocarbon ring group represented by L^{a} and L^{b} is preferably 6 to 24, more preferably 6 to 20, and further preferably 6 to 18. Examples of the aromatic hydrocarbon ring include a benzene ring and a naphthalene ring. This ring may be fused with a ring such as an aromatic hydrocarbon ring, an aliphatic hydrocarbon ring and a heterocycle. The aromatic hydrocarbon ring group may have a substituent, and examples of the substituent thereof include those exemplified as the above-described substituent W1. As the substituent, an alkyl group, an alkoxy group, an alkylthio group, an amino group, and a hydroxy group are preferred; an alkyl group, an alkoxy group, and a hydroxy group are more preferred; and an alkyl group, and an alkoxy group are further preferred.

The aromatic hydrocarbon ring is preferably a benzene ring, a naphthalene ring, or a fluorene ring.

The number of carbon atoms of the aromatic heterocycle of the divalent aromatic heterocyclic group represented by L^{a} and L^{b} is preferably 2 to 24, more preferably 3 to 20, and further preferably 3 to 18. The atom for forming the ring of the aromatic heterocycle is preferably a nitrogen atom, an oxygen atom, and a sulfur atom. Moreover, the aromatic heterocycle is preferably a 5-membered or 6-membered ring. This ring may be fused with a ring such as an aromatic hydrocarbon ring, an aliphatic hydrocarbon ring and a heterocycle. The aromatic heterocyclic group may have a substituent, and examples of the substituent thereof include those exemplified as the above-described substituent W1. As the substituent, an alkyl group, an alkoxy group, and an alkylthio group are preferred; an alkyl group, and an alkoxy group are more preferred; and an alkyl group is further preferred.

Examples of the aromatic heterocyclic group include a thiazole ring, a pyrrole ring, a furan ring, a pyrazole ring, an imidazole ring, a triazole ring, a thiadiazole ring, an oxadiazole ring, a pyridine ring, a pyrimidine ring, a pyridazine ring, a triazine ring, a benzothiazole ring, an indole ring, a benzothiadiazole ring, a quinoxaline ring, a phenoxazine ring, a dibenzofuran ring, a dibenzothiazole ring, a dibenzosilanolcyclopentadiene ring, a carbazole ring, a phenothiazine ring, a thiophene ring, an isothiazole ring, an isoindole ring, a quinoline ring, an isoquinoline ring, a quinazoline ring, a phthalazine ring, a pteridine ring, a coumarin ring, a chromone ring, a 1,4-benzodiazepine ring, a benzimidazole ring, a benzofuran ring, a purine ring, an acridine ring, a selenophene ring, a tellurophene ring, an oxazole ring, an isoxazole ring, a pyridone-2-one ring, a selenopyran ring, and a telluropyran ring.

Ra1 of —N(Ra1)- represented by L^{a} and L^{b} represents a substituent. Examples of the substituent include those exemplified as the above-described substituent W1.

Ra1 is preferably an alkyl group, an aryl group or a heterocyclic group. These groups may further have a substituent. Examples of the substituent with which these groups are substituted include those exemplified as the above-described substituent W1.

The number of carbon atoms of the alkyl group represented by Ra1 is preferably 1 to 18. The number of carbon atoms of the aryl group represented by Ra1 is preferably 6 to 24, more preferably 6 to 20, and further preferably 6 to 12.

The heterocyclic group represented by Ra1 is preferably an aromatic heterocyclic group, and more preferably an aromatic heterocyclic group exemplified as R^{3A} and R^{4A}.

The linking group formed by combination of groups selected from the group consisting of a divalent aromatic hydrocarbon ring group, a divalent aromatic heterocyclic group, and —N(Ra1)- represented by L^{a} and L^{b} may be combined in any manners as long as the combination example is a group formed by combination of two or more of these groups.

Examples thereof include -(a divalent aromatic hydrocarbon ring group)-(a divalent aromatic hydrocarbon ring group)-, -(a divalent aromatic heterocyclic group)-(a divalent aromatic heterocyclic group)-, -(a divalent aromatic hydrocarbon ring group)-(a divalent aromatic heterocyclic group)-, -(a divalent aromatic hydrocarbon ring group)-N(Ra1)-, -(a divalent aromatic hydrocarbon ring group)-N(Ra1)-(a divalent aromatic hydrocarbon ring group)-, -(a divalent aromatic heterocyclic group)-N(Ra1)-(a divalent aromatic hydrocarbon ring group)-, -(a divalent aromatic heterocyclic group)-(a divalent aromatic heterocyclic group)-(a divalent aromatic heterocyclic group)-, -(a divalent aromatic hydrocarbon ring group)-N(Ra1)-(a divalent aromatic hydrocarbon ring group)-N(Ra1)-(a divalent aromatic hydrocarbon ring group)-, and -(a divalent aromatic hydrocarbon ring group)-N(Ra1)-(a divalent aromatic hydrocarbon ring group)-(a divalent aromatic hydrocarbon ring group)-N(Ra1)-(a divalent aromatic hydrocarbon ring group)-.

L^{a} is preferably a linking group formed by combination of two or more groups selected from the group consisting of a divalent aromatic hydrocarbon ring group, a divalent aromatic heterocyclic group, and —N(Ra1)- described above.

L^{b} is preferably a divalent aromatic hydrocarbon ring, a divalent aromatic heterocyclic group, —N(Ra1)-, or a linking group formed by combination of these groups.

L^{a} is preferably a linking group represented by Formula (a) or (b).

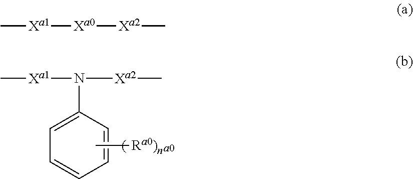

Herein, X^{a0} represents a single bond, a divalent aromatic hydrocarbon ring group, or a divalent aromatic heterocyclic group; and X^{a1} and X^{a2} each independently represent a divalent aromatic hydrocarbon ring group or a divalent aromatic heterocyclic group. R^{a0} represents a substituent, and n^{a0} represents an integer of 0 to 5.

The divalent aromatic hydrocarbon ring group and the divalent aromatic heterocyclic group represented by X^{a0}, X^{a1} and X^{a2} each have the same meaning as the divalent aromatic hydrocarbon ring group and the divalent aromatic heterocyclic group represented by L^{a}; and preferable ranges thereof are also the same.

Examples of the substituent represented by R^{a0} include those exemplified as the above-described substituent W1. Among these, an alkyl group, an alkoxy group, an alkylthio group, an acyl group, an alkoxycarbonyl group, and a halogen atom are preferred; and an alkoxycarbonyl group is particularly preferred.

n^{a0} is preferably 0 or 1.

As an aromatic hydrocarbon ring of a trivalent aromatic hydrocarbon ring group represented by X^{b}, an aromatic hydrocarbon ring represented by L^{a} and L^{b} is exemplified, and the preferable range thereof is the same as that of L^{a} and L^{b}.

Among them, a benzene ring is preferable, and benzen ring formed by bonding a benzene ring of a fluorene ring to 5-position of a phenylene group that forms a polymer main chain of a 1,3-phenylene group is preferable.

As an aromatic heterocycle of a trivalent aromatic heterocyclic group represented by X^{b}, an aromatic heterocycle represented by L^{a} and L^{b} is exemplified, and the preferable range thereof is the same as that of L^{a} and L^{b}.

Among them, an aromatic heterocycle formed by bonding a benzene ring of a fluorene ring to 10-position of a phenoxazine ring, 10-position of a phenothiazine ring, 9-position of a carbazole ring, or 1-position of pyrrole is preferable.

In X^{b}, it is preferable that an atom of X^{b} is a carbon atom forming an aromatic hydrocarbon ring, or a carbon atom or a nitrogen atom forming an aromatic heterocycle, or that X^{b} is >N—. It is particularly preferable that X^{b} is >N—.

The weight average molecular weight (GPC measurement value on the polystyrene equivalent basis) of the conjugated polymer containing at least a fluorene structure represented by Formula (1A) or (1B) as a repeating structure is not particularly limited. However, the weight average molecular weight is preferably 4,000 to 100,000, more preferably 6,000 to 80,000, and particularly preferably 8,000 to 50,000.

A terminal group of the conjugated polymer containing at least the fluorene structure represented by Formula (1A) or (1B) as a repeating structure is, for example, a substituent which is located outside the parentheses of the repeating structure represented by the above Formula (1A) or (1B) and is bonded to the repeating structure. The substituent, which may be the terminal group, may be, although varying depending on a synthesis method of the polymer, a halogen atom (for example, each atom of fluorine, chlorine, bromine, and iodine) derived from a synthetic raw material, a boron-containing substituent, a hydrogen atom generated by side reaction or the like of polymerization reaction, and a phosphorus-containing substituent derived from a catalyst ligand. After the polymerization, the terminal group is also preferably a hydrogen atom or an aryl group introduced by reduction reaction or substitution reaction.

Specific examples of the fluorine structure represented by Formula (1A) or (1B) are shown below, but the present invention is not limited thereto. In the following specific examples, the symbol “*” represents a binding site.

Herein, “Me” represents a methyl group, and “Pr” represents a propyl group.

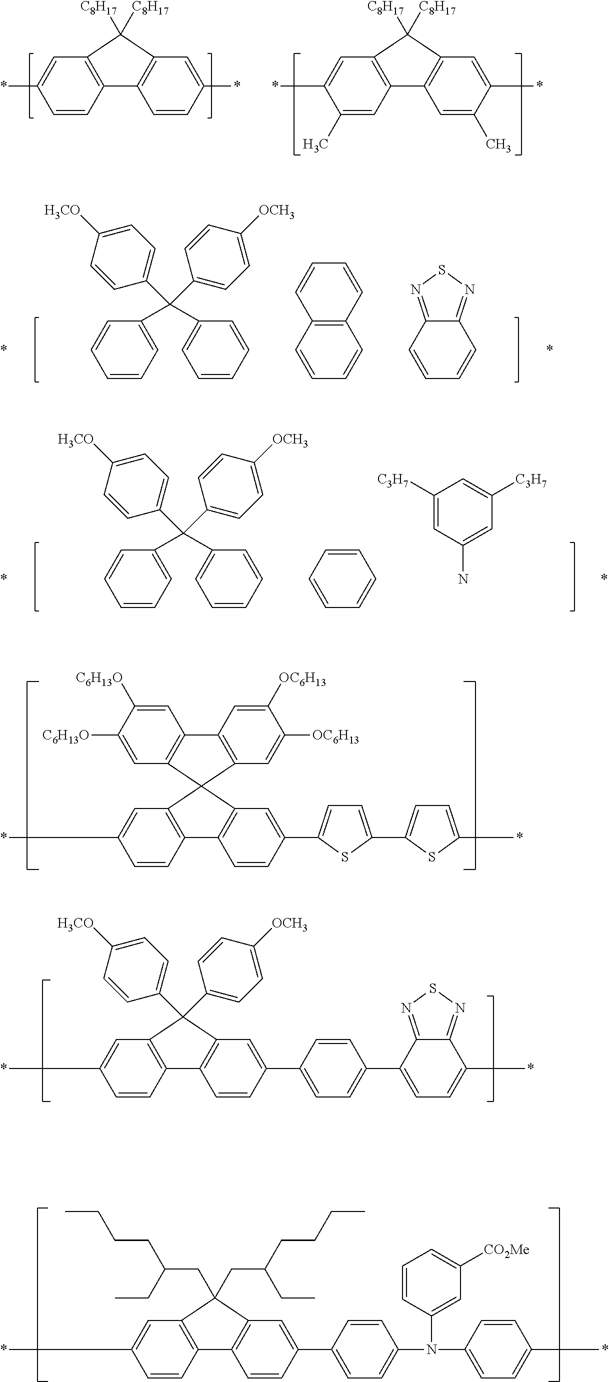

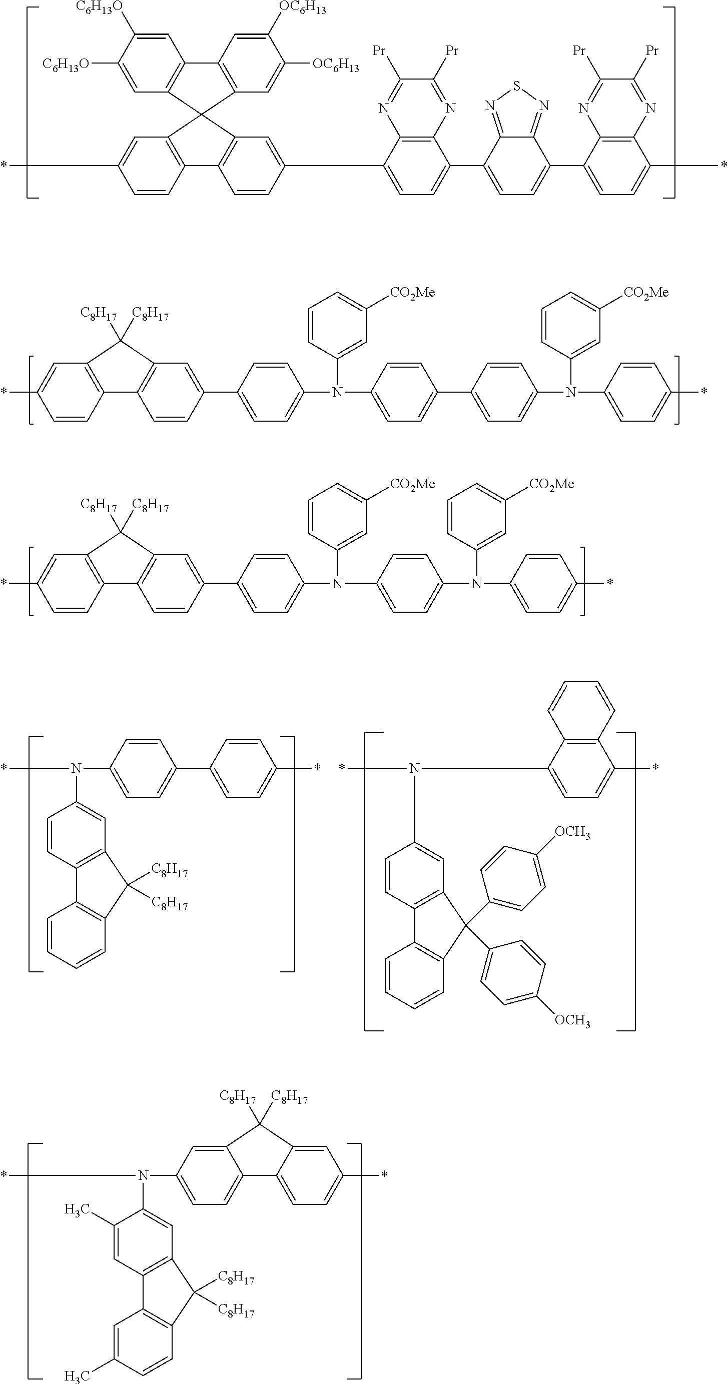

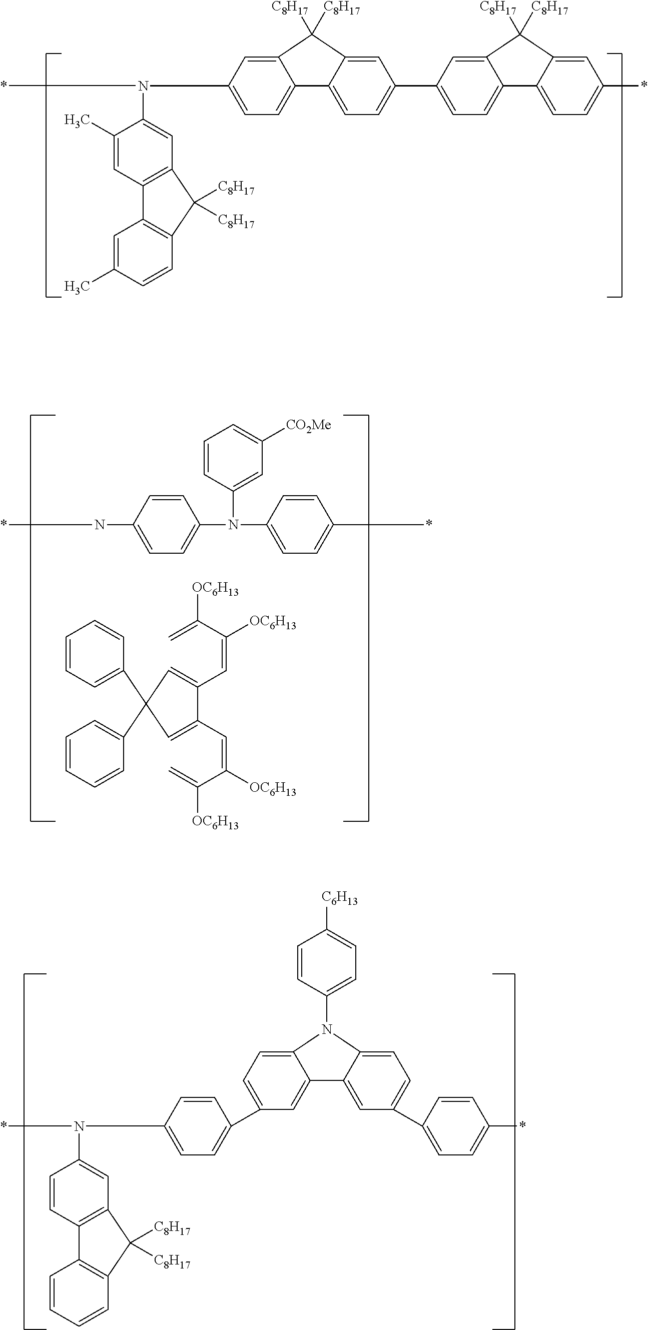

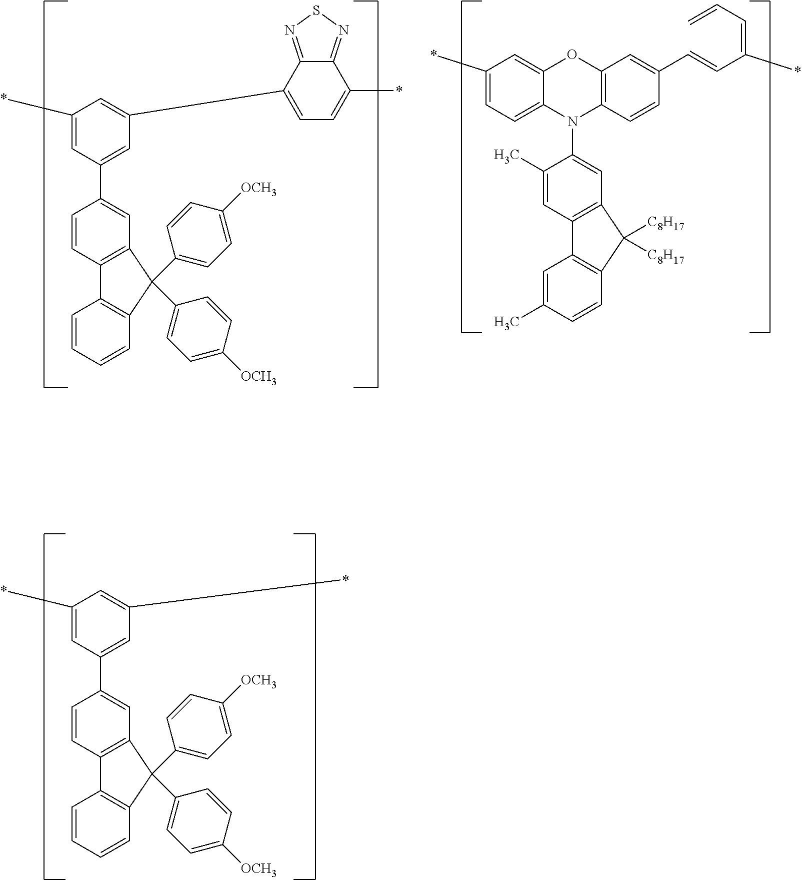

The conjugated polymer containing at least a fluorene structure represented by Formula (1A) or (1B) as a repeating structure can be prepared by polymerization of a compound having the fluorene structure described above using a method according to the well-known method described in Chem. Rev., 2011, Vol. 111, pp. 1417 and the like, or a method according to a general coupling polymerization method.

In addition to the above-described conjugated polymers, examples of the conjugated polymer for use in the present invention include a conjugated polymer containing at least a structure represented by Formula (1) as a repeating unit.

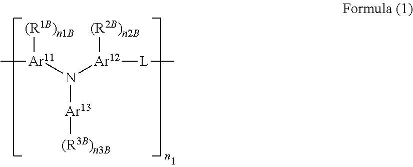

In Formula (1), Ar¹¹ and Ar¹² each independently represent an arylene group or a heteroarylene group. Ar¹³ represents an arylene group or a heteroarylene group. R^{1B}, R^{2B} and R^{3B} each independently represent a substituent. Herein, R^{1B} and R^{2B} may be bonded to each other to form a ring, R^{1B} and R^{3B} may be bonded to each other to form a ring, and R^{2B} and R^{3B} may be bonded to each other to form a ring. L represents a single bond, or a linking group represented by any one of Formulae (1-1) to (1-5). n1B, n2B and n3B each independently represent an integer of 0 to 4, and n₁ represents an integer of 5 or more.

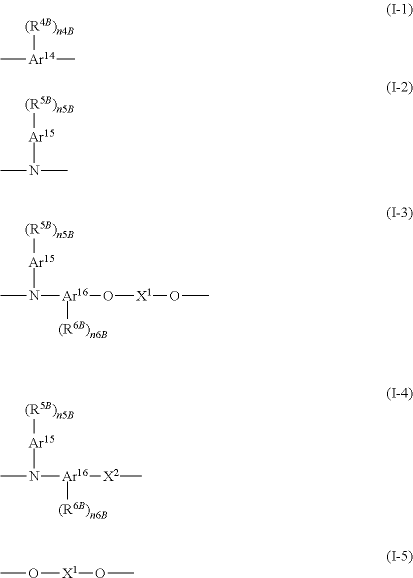

Herein, Ar¹⁴ and Ar¹⁶ each independently represent an arylene group or a heteroarylene group, and Ar¹⁵ represents an aryl group or a heteroaryl group. R^{4B} to R^{6B} each independently represent a substituent. Herein, R^{4B} and R^{2B} may be bonded to each other to form a ring, R^{5B} and R^{2B} may be bonded to each other to form a ring, R^{6B} and R^{2B} may be bonded to each other to form a ring, and R^{5B} and R^{6B} may be bonded to each other to form a ring. n4B to n6B each independently represent an integer of 0 to 4. X¹ represents an arylenecarbonylarylene group or an arylenesulfonylarylene group, and X² represents an arylene group, a heteroarylene group, or a linking group formed by combination of these groups.

Ar¹¹ and Ar¹² each independently represent an arylene group or a heteroarylene group, and Ar¹³ represents an aryl group or a heteroaryl group. An aromatic hydrocarbon ring (aromatic ring) and an aromatic heterocycle of these groups are preferably the following rings.

The number of carbon atoms of the aromatic ring is preferably 6 to 50, more preferably 6 to 40, and further preferably 6 to 20. Examples of the aromatic ring include a benzene ring, a naphthalene ring, an anthracene ring, a phenanthrene ring, an indacene ring, and a fluorene ring. The ring may be a monocyclic ring or a ring fused with other rings. Examples of the ring which may be fused include an aromatic ring, an alicyclic ring, an aromatic heterocycle, and a non-aromatic heterocycle.

The number of carbon atoms of the aromatic heterocycle is preferably 2 to 50, more preferably 2 to 40, further preferably 2 to 20, and particularly preferably 3 to 20. The hetero atom for forming the ring of the aromatic heterocycle is preferably an oxygen atom, a sulfur atom, a nitrogen atom, and a silicon atom. The aromatic heterocycle may be fused with other rings. Examples of the ring which may be fused include an aromatic ring, an alicyclic ring, an aromatic heterocycle, and a non-aromatic heterocycle. Examples of the aromatic heterocycle include a thiophene ring, a furan ring, a pyrrole ring, an imidazole ring, a pyridine ring, an oxazole ring, a thiazole ring and a thiadiazole ring, and a benzo-condensed ring of these (for example, benzothiophene) and a dibenzo-condensed ring of these (for example, dibenzothiophene and carbazole).

R^{1B}, R^{2B} and R^{3B} each represent a substituent. Examples of the substituent W2 include those as exemplified in the above-described substituent W1, except for the diarylboryl group, the dihydroxyboryl group and the dialkoxyboryl group.

R^{1B}, R^{2B} and R^{3B} each are preferably an alkyl group, an aryl group, a heterocyclic group, an alkoxy group, an alkylthio group, an amino group, an acyl group, an acylamino group, an alkyl- or aryl-sulfonamide group, an alkoxycarbonyl group, an alkyl- or aryl-carbamoyl group, or an alkyl- or aryl-sulfamoyl group.

The aromatic ring of the aryl group is preferably a benzene ring, a naphthalene ring, or a fluorene ring; and the heterocycle of the heterocyclic group is preferably a carbazole ring, a dibenzothiophene ring, or a 9-silafluorene ring.

L represents a single bond, or a linking group represented by any one of Formulae (1-1) to (1-5); preferably a linking group represented by any one of Formulae (1-1) to (1-4).

Ar¹⁴ and Ar¹⁶ each have the same meaning as Ar¹¹ and Ar¹², and preferable ranges thereof are also the same. Ar¹⁵ has the same meaning as Ar¹³, and a preferable range thereof is also the same. R^{4B} to R^{6B} each have the same meaning as R^{1B} to R^{3B}, and preferable ranges thereof are also the same.

X¹ represents an arylenecarbonylarylene group or an arylenesulfonylarylene group, and is represented by “—Ar^{a}—C(═O)—Ar^{b}—” or “—Ar^{a}—SO₂—Ar^{b}—”. Herein, Ar^{a} and Ar^{b} each independently represent an arylene group, and the arylene group may have a substituent. Examples of the substituent include those exemplified as the above-described substituent W2. Examples of the aromatic ring of the arylene group include those exemplified as Ar¹¹. Ar^{a} and Ar^{b} each are preferably a phenylene group, more preferably a 1,4-phenylene group.

X² represents an arylene group, a heteroarylene group, or a linking group formed by combination of these groups. Examples of the ring of these groups include those exemplified in Ar¹¹ described above, and preferable ranges thereof are also the same as those in Ar¹¹.

R^{1B} and R^{2B} may be bonded to each other to form a ring, R^{1B} and R^{3B} may be bonded to each other to form a ring, R^{2B} and R^{3B} may be bonded to each other to form a ring, R^{4B} and R^{2B} may be bonded to each other to form a ring, R^{5B} and R^{2B} may be bonded to each other to form a ring, R^{6B} and R^{2B} may be bonded to each other to form a ring, and R^{5B} and R^{6B} may be bonded to each other to form a ring. The ring formed by these groups may be an aromatic ring or an aromatic heterocycle. Examples thereof include a naphthalene ring, a fluorene ring, a carbazole ring, a dibenzothiophene ring, and a 9-silafluorene ring.

It is preferable that R^{1B} and R^{3B} are bonded to each other to form a ring, and R^{2B} is bonded to R^{4B} or R^{5B} to form a ring. As the formed ring in this case, a carbazole ring is preferable.

The formed carbazole ring is a group represented by any one of the following Formulae.

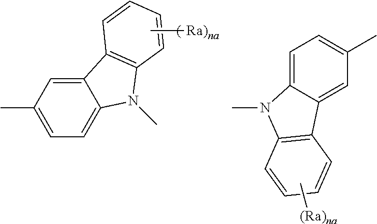

Herein, Ra has the same meaning as R^{2B} to R^{3B}, and a preferred range thereof is also the same. na has the same meaning as n1B to n3B, and a preferred range thereof is also the same.

na is preferably 0 or 1, more preferably 1. Ra is preferably an alkyl group.

n1B, n2B and n3B each represent an integer of 0 to 4, preferably an integer of 0 to 2, and an integer of 0 to 1. n1B, n2B and n3B may be the same or different from each other. However, it is preferable that these are different from each other.

Herein, the basic structure of Ar¹¹ and X² is particularly preferably a group represented by any one of the following Formulae. These rings shown in below may have a substituent.

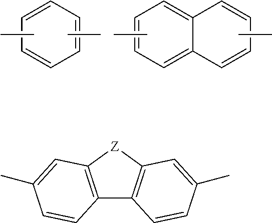

Herein, Z represents —C(Rb)₂— or —Si(Rb)₂—, and Rb represents an alkyl group.

As the repeating unit represented by Formula (1), a structure represented by any one of Formulae (2) to (6) is preferable.

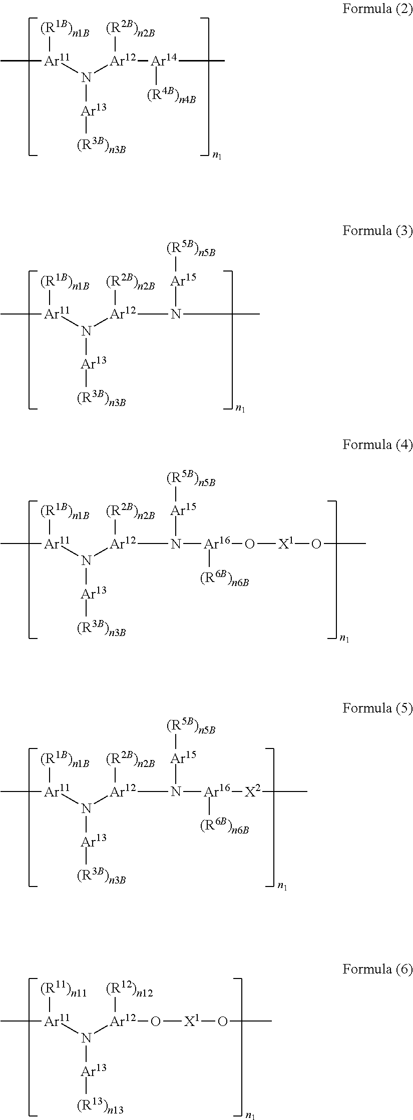

In Formulae (2) to (6), Ar¹¹ to Ar¹⁶, R^{1B} to R^{6B}, n1B to n6B, X¹ and X² have the same as Ar¹¹ to Ar¹⁶, R^{1B} to R^{6B}, n1B to n6B, X¹ and X² in Formula (1), respectively.

Among the repeating units represented by any one of Formulae (2) to (6), the structure represented by Formula (3), (4) or (5) is preferable, and the structure represented by Formula (4) is particularly preferable.

n₁ is an integer of 5 or more, and the preferable range thereof varies depending on the molecular weight of the repeating structure, but the weight average molecular weight (GPC measurement value on the polystyrene equivalent basis) of the conjugated polymer having the relevant repeating structure is preferably 5,000 to 100,000, more preferably 8,000 to 50,000, and particularly preferably 10,000 to 20,000.

The terminal group of the conjugated polymer is positioned outside parentheses of the repeating structures represented by Formulae (1) to (6) and is a substituent bonded to the repeating structure. The substituent forming the terminal group is as described above.

Specific examples of the repeating unit represented by Formula (1) forming the conjugated polymer are shown below, but the present invention is not limited thereto. In the following specific examples, the symbol “*” represents a binding site.

Herein, “Et” represents an ethyl group, “Bu(n)” represents a n-butyl group, and “Ph” represents a phenyl group (—C₆H₅).

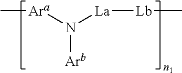

| Ar^{a} | La | Ar^{b} | Lb |
|---|---|---|---|
| 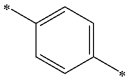 | 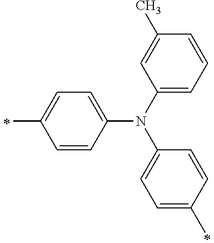 | 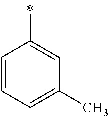 | 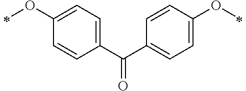 |
| 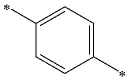 | 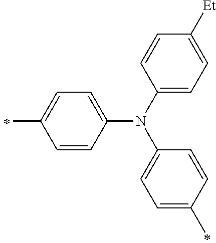 | 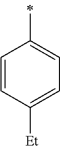 | 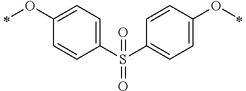 |
| 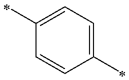 | 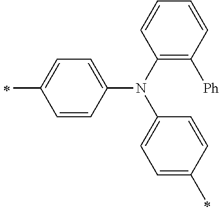 | 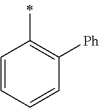 | 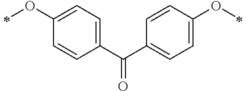 |
| 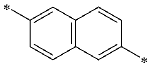 | 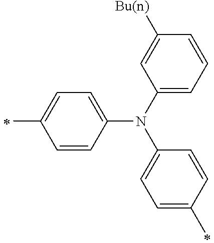 | 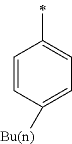 | 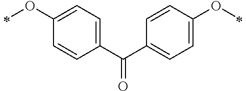 |
| 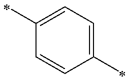 | 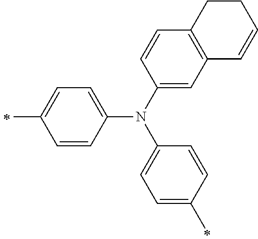 | 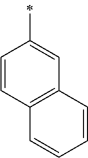 | 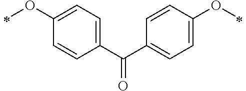 |
| 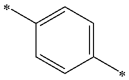 | 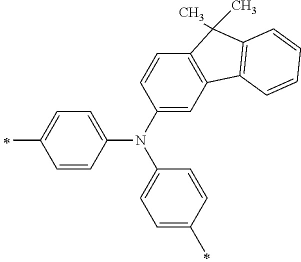 | 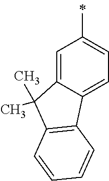 | 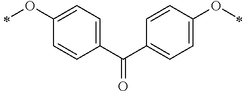 |
| 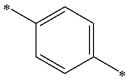 | 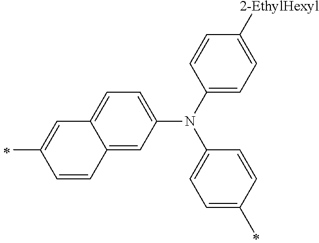 | 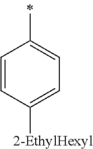 | 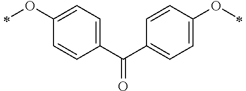 |
| 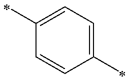 | 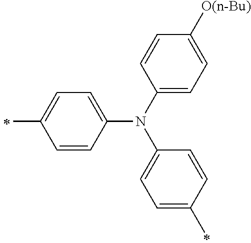 | 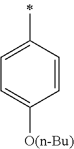 | 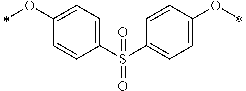 |
| 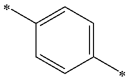 | 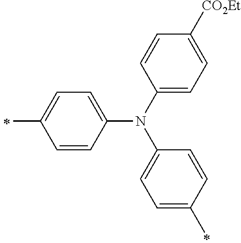 | 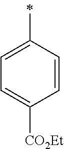 | 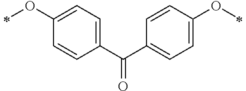 |
| 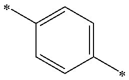 | 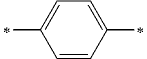 | 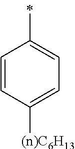 | 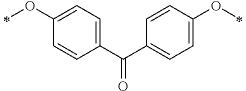 |
| 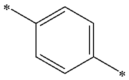 | 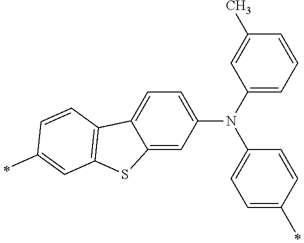 | 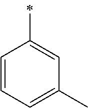 | 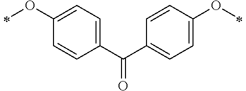 |
| 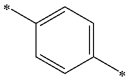 | 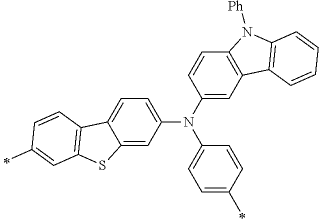 | 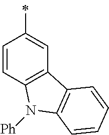 | 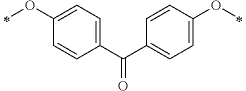 |
| 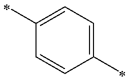 | 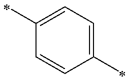 | 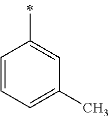 | 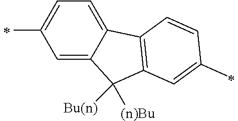 |
| 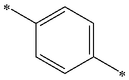 | 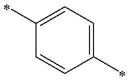 | 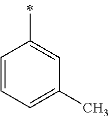 | 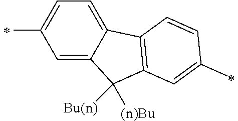 |
| 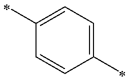 | 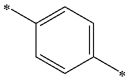 | 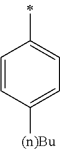 | 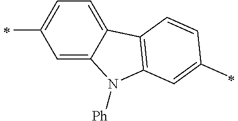 |
| 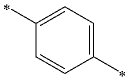 | 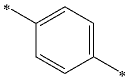 | 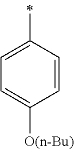 | 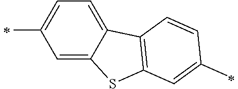 |
| 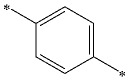 | 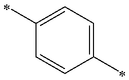 | 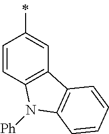 | 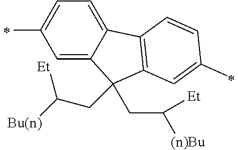 |
| 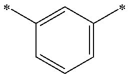 | 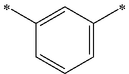 | 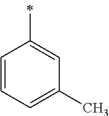 | 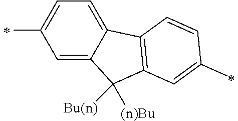 |
| 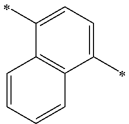 | 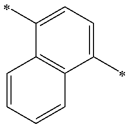 | 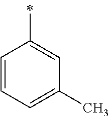 | 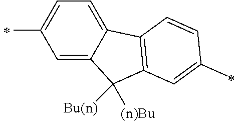 |

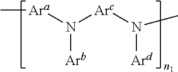

| Ar^{a} | Ar^{c} | Ar^{b} | Ar^{d} |
|---|---|---|---|
| 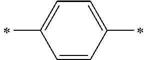 | 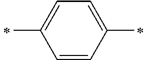 | 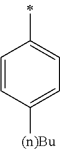 | 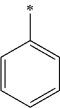 |
| 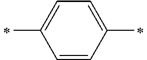 | 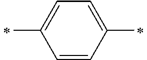 | 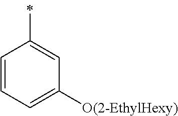 | 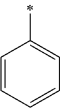 |
| 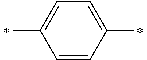 | 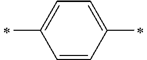 | 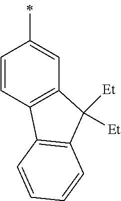 | 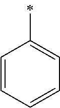 |
| 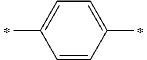 | 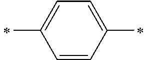 | 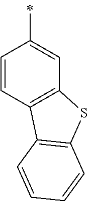 | 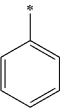 |
| 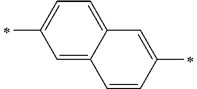 | 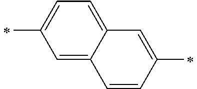 | 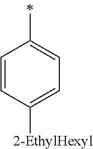 | 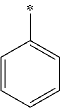 |
| 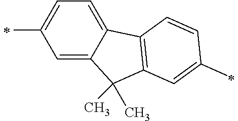 | 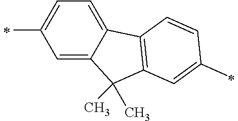 | 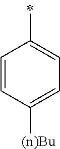 | 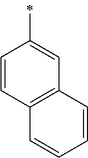 |
| 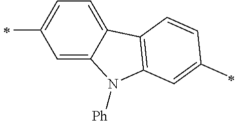 | 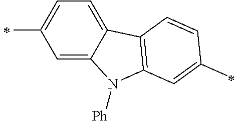 | 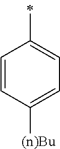 | 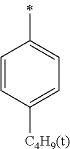 |
| 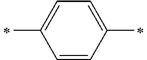 | 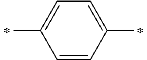 | 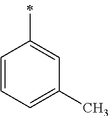 | 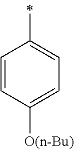 |
| 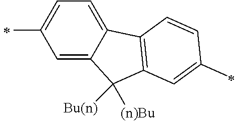 | 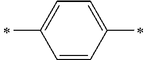 | 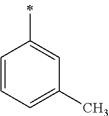 | 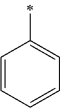 |
| 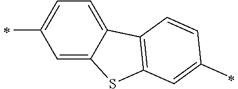 | 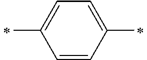 | 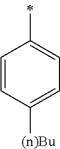 | 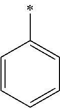 |

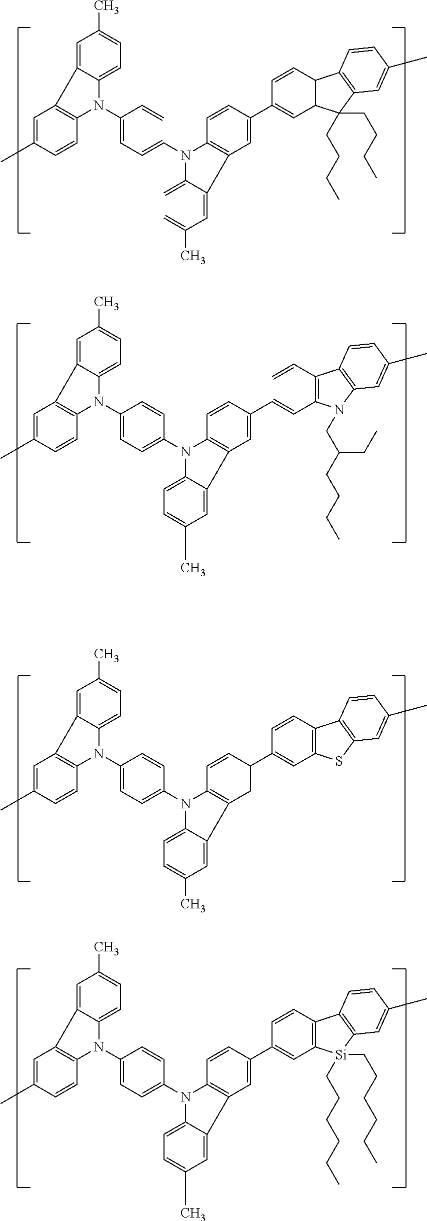

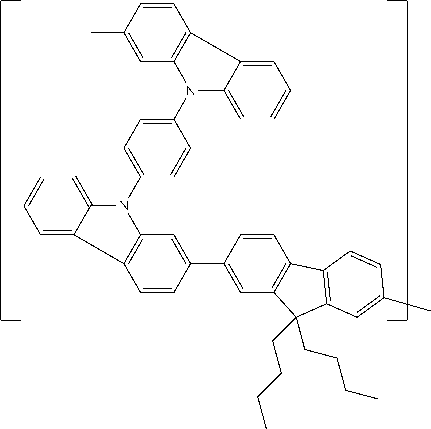

The conjugated polymer having the structure represented by the above Formula (1) as a repeating structure can be produced by the polymerization of one kind or plural kinds of raw material compounds having a part or whole of the structure represented by the above Formula (1) using a method according to a general oxidation polymerization method or coupling polymerization method.

The synthesis of the raw material compound can be performed according to a general method. A raw material, which is not available, among the raw materials used in the present invention can be synthesized by amination of an aryl compound, and conventionally, can be synthesized by Ullmann reaction and reaction techniques derived therefrom. In recent years, arylamination using a palladium complex catalyst is significantly developed and the synthesis can be performed by Buchwald-Hartwig reaction and reaction techniques derived therefrom. As a representative example of Buchwald-Hartwig reaction, reaction techniques described in Organic Synthesis, Vol. 78, p. 23 and Journal of American Chemical Society, 1994, Vol. 116, p. 7901 can be exemplified.

In the dispersion for a thermoelectric conversion layer to be used in the present invention, one kind of the conjugated polymers described above can be used alone or two or more kinds thereof can be used in combination.

### <Non-Conjugated Polymer>

In the method of preparing a dispersion for a thermoelectric conversion layer of the present invention, it is preferable to use a non-conjugated polymer in terms that the film-forming property of the dispersion for a thermoelectric conversion layer can be further improved. That is, the dispersion for a thermoelectric conversion layer contains preferably a non-conjugated polymer.

The non-conjugated polymer is a polymer compound having no molecule structure to be conjugated. That is, the non-conjugated polymer is not particularly limited as long as it is a polymer compound which is not conjugated by means of π electrons or lone-pair electrons. Such a non-conjugated polymer is not necessarily a high-molecular compound, and also includes an oligomer compound.

There is no particular limitation on such a non-conjugated polymer, and a generally known non-conjugated polymer can be used. It is preferable to use a polymer selected from the group consisting of a polyvinyl polymer obtained by the polymerization of a vinyl compound, poly(meth)acrylate, polycarbonate, polyester, polyamide, polyimide, a fluorine polymer containing, as a repeating structure, a constituent derived from a fluorine compound, and polysiloxane.

In the present invention, the term “(meth)acrylate” means both or either of acrylate and methacrylate, and a mixture of these.

Specific examples of the vinyl compound which may form a polyvinyl polymer include vinylarylamines such as styrene, vinylpyrrolidone, vinylcarbazole, vinylpyridine, vinylnaphthalene, vinylphenol, vinyl acetate, styrenesulfonic acid, and vinyltriphenylamine; and vinyltrialkylamines such as vinyltributylamine.

Specific examples of the (meth)acrylate compound which may form the poly(meth)acrylate, include acrylate monomers including non-substituted alkly acrylate group-containing hydrophobic acrylates such as methyl acrylate, ethyl acrylate, propyl acrylate, and butyl acrylate; acryl hydroxyalkly esters such as 2-hydroxyethyl acrylate, 1-hydroxyethyl acrylate, 2-hydroxypropyl acrylate, 3-hydroxypropyl acrylate, 1-hydroxypropyl acrylate, 4-hydroxybutyl acrylate, 3-hydroxybutyl acrylate, 2-hydroxybutyl acrylate, and 1-hydroxybutyl acrylate; and methacrylate monomers in which the acryloyl groups of these monomers are changed to methacryloyl groups.

Specific examples of the polycarbonate include general-purpose polycarbonates formed from bisphenol A and phosgene, IUPIZETA (trade name, manufactured by MITSUBISHI GAS CHEMICAL CO., INC.), and PANLITE (trade name, manufactured b TEIJIN LIMITED).

As the compound for forming the polyester, polyalcohol, and a hydroxy acid such as polycarboxylic acid and lactic acid can be exemplified. Specific examples of the polyester include VYLON (trade name, manufactured by TOYOBO CO., LTD.).

Specific examples of the polyamide include PA-100 (trade name, manufactured by T&K TOKA CO., LTD).

Specific examples of the polyimide include SOLPIT 6,6-PI (trade name, manufactured by Solpit Industries, Ltd.).

As the fluorine-containing compound, specifically, vinylidene fluoride, vinyl fluoride, and the like can be exemplified.

Specific examples of the polysiloxane include polydiphenylsiloxane and polyphenylmethylsiloxane.

The non-conjugated polymer may be a homopolymer or a copolymer of each compound described above, if possible.

In the present invention, it is more preferable to use a polyvinyl polymer that is formed by polymerizing a vinyl compound, as the non-conjugated polymer.

It is preferable that the non-conjugated polymer be hydrophobic, and it is more preferable that the non-conjugated polymer do not have a hydrophilic group such as a sulfonic acid group or a hydroxyl group in the molecule. Furthermore, a non-conjugated polymer having a solubility parameter (SP value) of 11 or less is preferred.

In the present invention, the solubility parameter means a Hildebrand SP value and a value obtained by Fedors' estimation method is employed.

By using a non-conjugated polymer together with the conjugated polymer in the preparation of a dispersion for a thermoelectric conversion layer, an enhancement of the thermoelectric conversion performance of the thermoelectric conversion element can be promoted. The mechanism thereof include some points that are not clearly understood, but it is speculated to be because: (1) since a non-conjugated polymer has a broad gap (band gap) between the HOMO (Highest Occupied Molecular Orbital) level and the LUMO (Lowest Unoccupied Molecular Orbital) level, the carrier concentration in the conjugated polymer can be maintained at an appropriately low level, so that the Seebeck coefficient can be retained at a higher level than a system that does not include a non-conjugated polymer; and further (2) transport routes of the carriers are formed as a result of the co-presence of the conjugated polymer and the nano conductive material, and a high electrical conductivity can be retained. That is, when three components of the nano conductive material, a non-conjugated polymer and a conjugated polymer are allowed to co-exist in the dispersion, both the Seebeck coefficient and the electrical conductivity can be enhanced, and as a result, the thermoelectric conversion performance (ZT value) is significantly enhanced.

In the dispersion for a thermoelectric conversion layer, one kind of the non-conjugated polymers described above can be used alone or two or more kinds thereof can be used in combination.

### <Dispersion Medium>

In the method of preparing a dispersion for a thermoelectric conversion layer of the present invention, a dispersion medium is used. That is, the dispersion for a thermoelectric conversion layer contains a dispersion medium and a nano conductive material is dispersed in this dispersion medium.

The dispersion medium may be any dispersion medium capable of satisfactorily dispersing the nano conductive material. Water, an organic solvent, and mixed solvents thereof can be used. The dispersion medium is preferably an organic solvent, and preferred examples include alcohols such as 1-methoxy-2-propanol (PGME); aliphatic halogen solvents such as chloroform; aprotic polar solvents such as DMF, NMP and DMSO; aromatic solvents such as chlorobenzene, dichlorobenzene, benzene, toluene, xylene, mesitylene, tetralin, tetramethylbenzene, and pyridine; ketone solvents such as cyclohexanone, acetone, and methyl ethyl ketone; and ether solvents such as diethyl ether, THF, t-butyl methyl ether, dimethoxyethane, diglyme and propyleneglycol-1-monomethylether-2-acetate (PGMEA), and more preferred examples include halogen solvents such as chloroform, aprotic polar solvents such as DMF and NMP; aromatic solvents such as dichlorobenzene, xylene, tetralin, mesitylene, and tetramethylbenzene; and ether solvents such as THF. Further, an organic solvent to be used in an ink jet printing method to be described later is also preferable.

In the dispersion for a thermoelectric conversion layer, one kind of the dispersion mediums can be used alone or two or more kinds thereof can be used in combination.

Furthermore, it is preferable to have the dispersion medium degassed in advance. It is preferable to adjust the dissolved oxygen concentration in dispersion medium to 10 ppm or less. Examples of the method of degassing include a method of irradiating ultrasonic waves under reduced pressure; and a method of bubbling an inert gas such as argon.

Furthermore, it is preferable to have the dispersion medium dehydrated in advance. It is preferable to adjust the amount of water in the dispersion medium to 1,000 ppm or less, and more preferably to 100 ppm or less. Regarding the method of dehydration in the dispersion medium, known methods such as a method of using a molecular sieve, and distillation, can be used.

### <Dopant>

In the method of preparing a dispersion for a thermoelectric conversion layer of the present invention, it is also preferable to use a dopant.

### A. Case of Using the Conjugated Polymer Described Above

In the case of using the above-described conjugated polymer in the method of preparing a dispersion for a thermoelectric conversion layer of the present invention, it is preferable to further use a dopant in terms that the electrical conductivity of the thermoelectric conversion layer can be further improved by an increase in carrier concentration. That is, the dispersion of the present invention contains preferably a conjugated polymer and a dopant.

The dopant is a compound that is doped into the conjugated polymer, and may be any compound capable of doping the conjugated polymer to have a positive charge (p-type doping) by protonizing the conjugated polymer or eliminating electrons from the π-conjugated system of the conjugated polymer. Specifically, an onium salt compound, an oxidizing agent, an acidic compound, an electron acceptor compound and the like as described below can be used.

### 1. Onium Salt Compound

The onium salt compound to be used as the dopant preferably includes a compound (an acid generator, acid precursor) that generates acid by providing energy such as irradiation of active energy rays (such as radiation and electromagnetic waves), and an application of heat. Specific examples of such onium salt compounds include a sulfonium salt, an iodonium salt, an ammonium salt, a carbonium salt, and a phosphonium salt. Among these, a sulfonium salt, an iodonium salt, an ammonium salt, or a carbonium salt is preferred, a sulfonium salt, an iodonium salt, or a carbonium salt is more preferred, a sulfonium salt, an iodonium salt is particularly preferred. Specific examples of an anion part constituting such a salt include counter anions of strong acid.

Specific examples of the sulfonium salts include compounds represented by the following Formulae (I) and (II), specific examples of the iodonium salts include compounds represented by the following Formula (III), specific examples of the ammonium salts include compounds represented by the following Formula (IV), and specific examples of the carbonium salts include compounds represented by the following Formula (V), respectively, and such compounds are preferably used in the present invention.

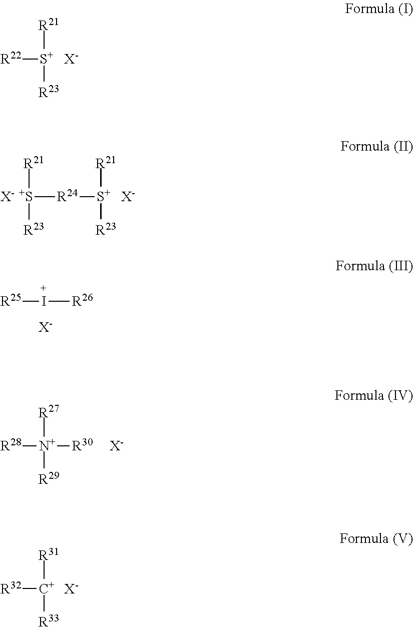

In Formulae (I) to (V), R²¹ to R²³, R²⁵ to R²⁶, and R³¹ to R³³ each independently represent an alkyl group, an aralkyl group, an aryl group, or an aromatic heterocyclic group. R²⁷ to R³⁰ each independently represent a hydrogen atom, or an alkyl group, an aralkyl group, an aryl group, an aromatic heterocyclic group, an alkoxy group, or an aryloxy group. R²⁴ represents an alkylene group or an arylene group. The substituents R²¹ to R³³ may be further substituted with a substituent. X⁻ represents an anion of strong acid.

Any two groups of R²¹ to R²³ in Formula (I), R²¹ and R²³ in Formula (II), R²⁵ and R²⁶ in Formula (III), any two groups of R²⁷ to R³⁰ in Formula (IV), and any two groups of R³¹ to R³³ in Formula (V) may be bonded with each other in each Formula to form an aliphatic ring, an aromatic ring, or a heterocyclic ring.

In R²¹ to R²³, or R²⁵ to R³³, the alkyl group includes a linear, branched or cyclic alkyl group. The linear or branched alkyl group is preferably an alkyl group having 1 to 20 carbon atoms, and specific examples thereof include methyl, ethyl, propyl, n-butyl, sec-butyl, t-butyl, hexyl, octyl, and dodecyl.

The cycloalkyl group is preferably a cycloalkyl group having 3 to 20 carbon atoms, and specific examples thereof include cyclopropyl, cyclopentyl, cyclohexyl, bicyclooctyl, norbornyl, and adamantyl.

The aralkyl group is preferably an aralkyl group having 7 to 15 carbon atoms, and specific examples thereof include benzyl and phenetyl.

The aryl group is preferably an aryl group having 6 to 20 carbon atoms, and specific examples thereof include phenyl, naphthyl, anthranyl, phenacyl, and pyrenyl.

Specific examples of the aromatic heterocyclic group include a pyridine ring group, a pyrazole ring group, an imidazole ring group, a benzimidazole ring group, an indole ring group, a quinoline ring group, an isoquinoline ring group, a purine ring group, a pyrimidine ring group, an oxazole ring group, a thiazole ring group, and a thiazine ring group.

In R²⁷ to R³⁰, the alkoxy group is preferably a linear or branched alkoxy group having 1 to 20 carbon atoms, and specific examples thereof include methoxy, ethoxy, iso-propoxy, butoxy, and hexyloxy.

The aryloxy group is preferably an aryloxy group having 6 to 20 carbon atoms, and specific examples thereof include phenoxy and naphthyloxy.

In R²⁴, the alkylene group includes a linear, branched and cyclic alkylene group, and an alkylene group having 2 to 20 carbon atoms is preferred. Specific examples of the linear or branched alkylene group include ethylene, propylene, butylene, and hexylene. The cyclic alkylene group is preferably a cyclic alkylene group having 3 to 20 carbon atoms, and specific examples thereof include cyclopentyl, cyclohexylene, bicyclooctylene, norbornylene, and adamantylene.

The arylene group is preferably an arylene group having 6 to 20 carbon atoms, and specific examples thereof include phenylene, naphthylene, and anthranylene.

When R²¹ to R³³ further have a substituent, specific examples of preferred substituents include an alkyl group having 1 to 4 carbon atoms, an alkoxy group having 1 to 4 carbon atoms, a halogen atom (a fluorine atom, a chlorine atom, or an iodine atom), an aryl group having 6 to 10 carbon atoms, an aryloxy group having 6 to 10 carbon atoms, an alkenyl group having 2 to 6 carbon atoms, a cyano group, a hydroxyl group, a carboxy group, an acyl group, an alkoxycarbonyl group, an alkylcarbonylalkyl group, an arylcarbonyl group, an arylcarbonylalkyl group, a nitro group, an alkylsulfonyl group, a trifluoromethyl group, and —S—R⁴¹. In addition, R⁴¹ has the same meaning as R²¹.

X⁻ is preferably an anion of aryl sulfonic acid, an anion of perfluoroalkyl sulfonic acid, an anion of perhalogenated Lewis acid, an anion of perfluoroalkyl sulfonimide, an anion of perhalogenated acid, or an anion of alkyl or aryl borate. These anions may further have a substituent, and a specific example of the substituent includes a fluoro group.

Specific examples of the anions of aryl sulfonic acid include p-CH₃C₆H₄SO₃⁻, C₆H₅PhSO₃⁻, an anion of naphthalene sulfonic acid, an anion of naphthoquinone sulfonic acid, an anion of naphthalene disulfonic acid, and an anion of anthraquinone sulfonic acid.

Specific examples of the anions of perfluoroalkyl sulfonic acid include CF₃SO₃⁻, C₄F₉SO₃⁻, and C₈F₁₇SO₃⁻.

Specific examples of the anions of perhalogenated Lewis acid include PF₆⁻, SbF₆⁻, BF₄⁻, AsF₆⁻, and FeCl₄⁻.

Specific examples of the anions of perfluoroalkyl sulfonimide include CF₃SO₂—N⁻—SO₂CF₃, and C₄F₉SO₂—N⁻—SO₂C₄F₉.

Specific examples of the anions of perhalogenated acid include ClO₄⁻, BrO₄⁻, and IO₄⁻.

Specific examples of the anions of alkyl or aryl borate include (C₆H₅)₄B⁻, (C₆F₅)₄B⁻, (p-CH₃C₆H₄)₄B⁻, and (C₆H₄F)₄B⁻.

Specific examples of the onium salt compounds are shown below, but the present invention is not limited thereto.

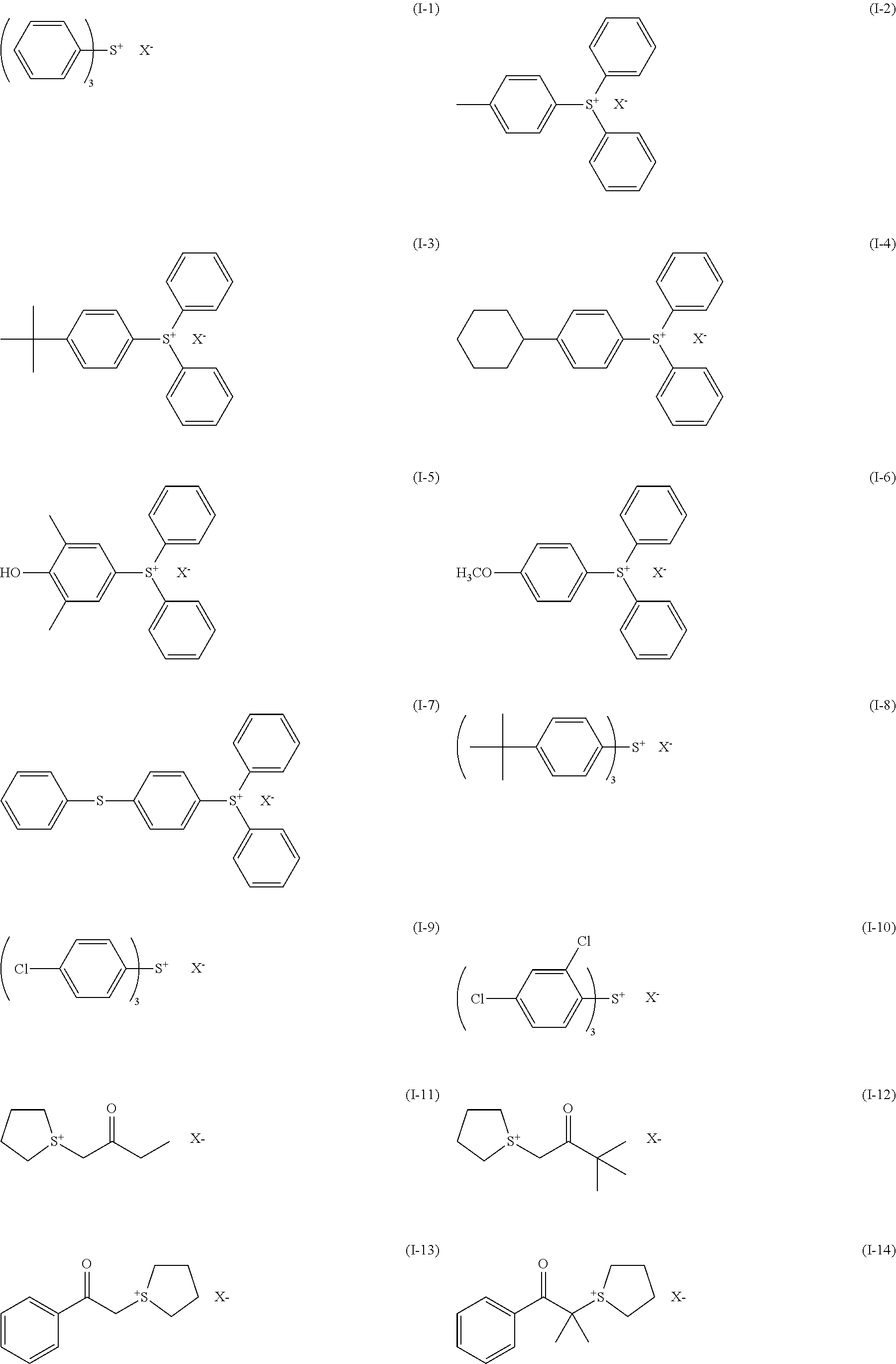

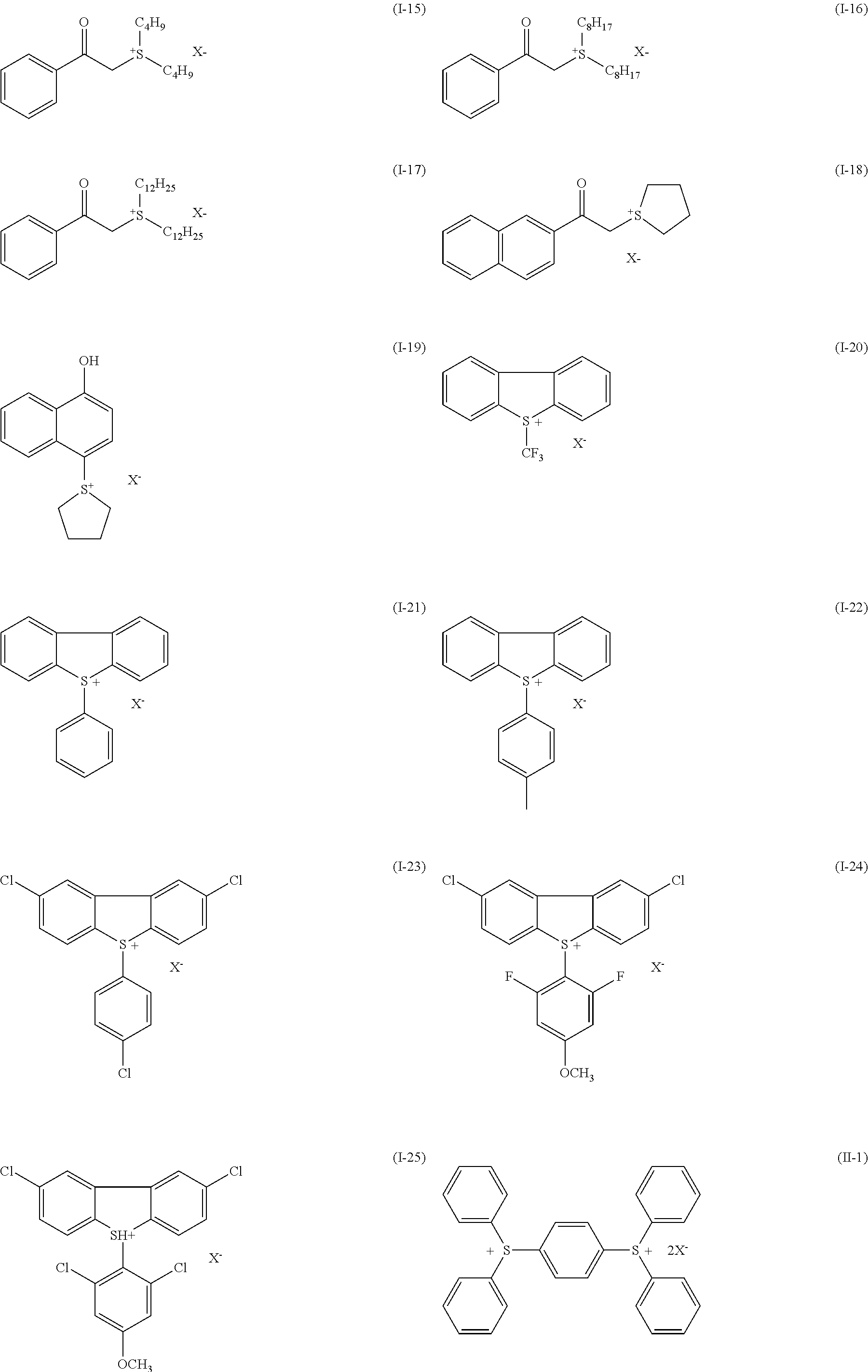

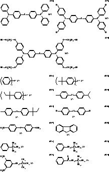

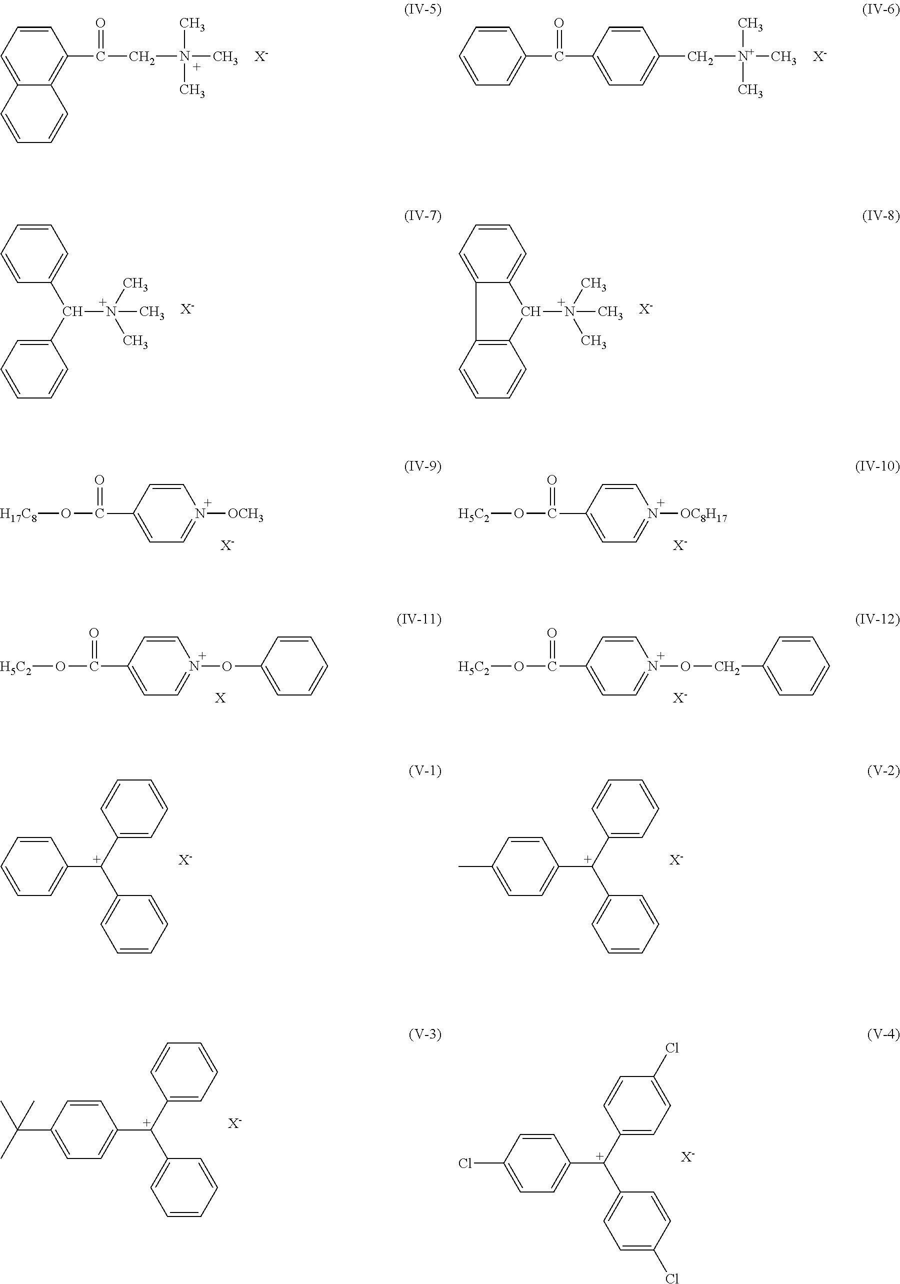

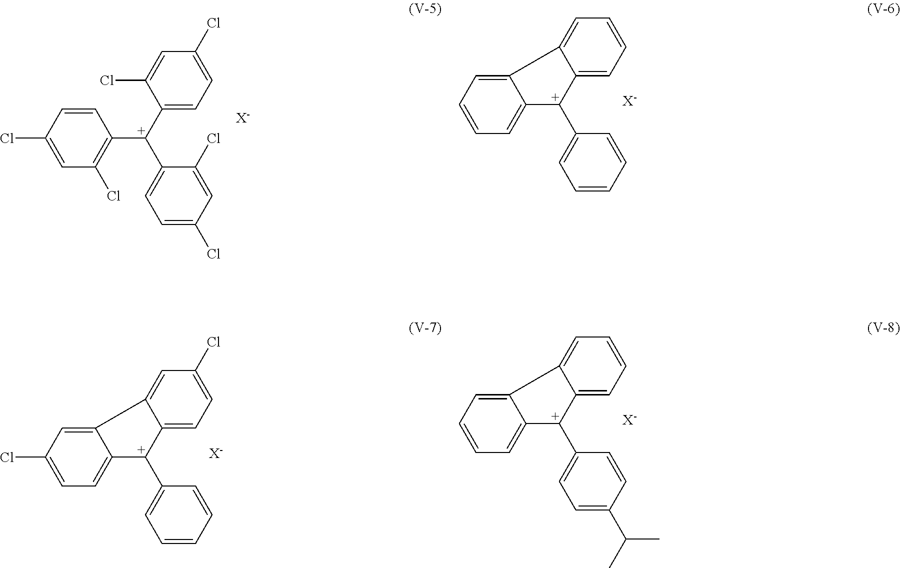

In the above-described specific examples, X⁻ represents PF₆⁻, SbF₆⁻, CF₃SO₃⁻, p-CH₃C₆H₄SO₃⁻, BF₄⁻, (C₆H₅)₄B⁻, RfSO₃⁻, (C₆F₅)₄B⁻, or an anion represented by the following formula: and Rf represents a perfluoroalkyl group.

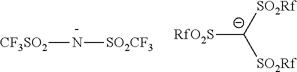

In the present invention, an onium salt compound represented by the following Formula (VI) or (VII) is particularly preferred.

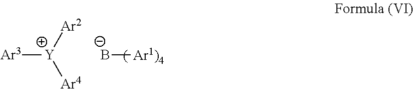

In Formula (VI), Y represents a carbon atom or a sulfur atom, Ar¹ represents an aryl group, and Ar² to Ar⁴ each independently represent an aryl group or an aromatic heterocyclic group. Ar¹ to Ar⁴ may further have a substituent.

Ar¹ is preferably a fluoro-substituted aryl group or an aryl group replaced by at least one perfluoroalkyl group; more preferably a pentafluorophenyl group or a phenyl group replaced by at least one perfluoroalkyl group; and particularly preferably a pentafluorophenyl group.

The aryl groups or the aromatic heterocyclic groups of Ar² to Ar⁴ have the same meaning as the aryl groups or the aromatic heterocyclic groups of R²¹ to R²³, or R²⁵ to R³³, and are preferably an aryl group, and more preferably a phenyl group. These groups may further have a substituent, and specific examples of the substituents include the above-mentioned substituents of R²¹ to R³³.

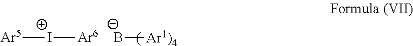

In Formula (VII), Ar¹ represents an aryl group, and Ar⁵ and Ar⁶ each independently represent an aryl group or an aromatic heterocyclic group. Ar¹, Ar⁵, and Ar⁶ may further have a substituent.

Ar¹ has the same meaning as Ar¹ in Formula (VI), and a preferred range thereof is also the same.

Ar⁵ and Ar⁶ each have the same meaning as Ar² to Ar⁴ in Formula (VI), and a preferred range thereof is also the same.

The onium salt compound can be synthesized by an ordinary synthesis method. Moreover, a commercially available reagent or the like can also be used.

As one embodiment of a synthetic method of the onium salt compound, a method of synthesizing triphenylsulfonium tetrakis(pentafluorophenyl)borate is shown below. However, the present invention is in no way limited thereto. Any other onium salt compounds can also be synthesized in a synthetic method in accordance with the following synthetic method.

Into a 500 mL volume three-necked flask, 2.68 g of triphenylsulfonium bromide (manufactured by Tokyo Chemical Industry Co., Ltd.), 5.00 g of a lithium tetrakis(pentafluorophenyl)borate-ethyl ether complex (manufactured by Tokyo Chemical Industry Co., Ltd.), and 146 mL of ethanol are put, the resultant mixture is stirred at 25° C. (in the present specification, referred to as “room temperature”) for 2 hours, and then 200 mL of pure water is added thereto, and a precipitated white solid is fractionated by filtration. This white solid is washed with pure water and ethanol, and subjected to vacuum drying, and thus as an onium salt 6.18 g of triphenylsulfonium tetrakis(pentafluorophenyl)borate can be obtained.

### 2. Oxidizing Agent, Acid Compound, and Electron Acceptor Compound

Specific examples of the oxidizing agent to be used as the dopant in the present invention include halogen (Cl₂, Br₂, I₂, ICl, ICl₃, IBr, IF), Lewis acid (PF₅, AsF₅, SbF₅, BF₃, BCl₃, BBr₃, SO₃), a transition metal compound (FeCl₃, FeOCl, TiCl₄, ZrCl₄, HfCl₄, NbF₅, NbCl₅, TaCl₅, MoF₅, MoCl₅, WF₆, WCl₆, UF₆, LnCl₃ (Ln=lanthanoid such as La, Ce, Pr, Nd and Sm), and also O₂, O₃, XeOF₄, (NO₂⁺)(SbF₆⁻), (NO₂⁺)(SbCl₆⁻), (NO₂⁺)(BF₄⁻), FSO₂OOSO₂F, AgClO₄, H₂IrCl₆ and La(NO₃)₃.6H₂O.

Examples of the acidic compound include polyphosphoric acid, a hydroxy compound, a carboxy compound and a sulfonic acid compound as disclosed below, and protic acids (HF, HCl, HNO₃, H₂SO₄, HClO₄, FSO₃H, ClSO₃H, CF₃SO₃H, various organic acids, amino acids, and the like).

Examples of the electron acceptor compound include TCNQ (tetracyanoquinodimethane), tetrafluorotetracyanoquinodimethane, halogenated tetracyanoquinodimethane, 1,1-dicyanovinylene, 1,1,2-tricyanovinylene, benzoquinone, pentatluorophenol, dicyanotluorenone, cyano-fluoroalkylsulfonyl-fluorenone, pyridine, pyrazine, triazine, tetrazine, pyridopyrazine, benzothiadiazole, heterocyclic thiadiazole, porphyrin, phthalocyanine, boron quinolate compounds, boron diketonate compounds, boron diisoindomethene compounds, carborane compounds, other boron atom-containing compounds, and the electron acceptor compounds described in Chemistry Letter, 1991, pp. 1707-1710.

### —Polyphosphoric Acid—

Polyphosphoric acid includes diphosphoric acid, pyrophosphoric acid, triphosphoric acid, tetraphosphoric acid, metaphosphoric acid and polyphosphoric acid, and a salt thereof. Polyphosphoric acid may be a mixture thereof. In the present invention, polyphosphoric acid includes preferably diphosphoric acid, pyrophosphoric acid, triphosphoric acid and polyphosphoric acid, and further preferably, polyphosphoric acid. Polyphosphoric acid can be synthesized by heating H₃PO₄ with a sufficient amount of P₄O₁₀ (phosphoric anhydride), or by heating H₃PO₄ to remove water.

### —Hydroxy Compound—

The hydroxy compound only needs to include at least one hydroxyl group, and preferably, a phenolic hydroxyl group. The hydroxy compound is preferably a compound represented by Formula (VIII).

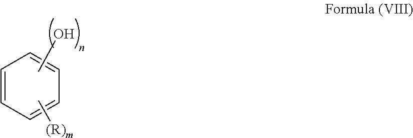

In Formula (VIII), R represents a sulfo group, a halogen atom, an alkyl group, an aryl group, a carboxy group, an alkoxycarbonyl group, n represents 1 to 6, m represents 0 to 5.

R is preferably a sulfo group, an alkyl group, an aryl group, a carboxy group, an alkoxycarbonyl group, more preferably a sulfo group.

n is preferably 1 to 5, more preferably 1 to 4, further preferably 1 to 3.

m is 0 to 5, preferably 0 to 4, more preferably 0 to 3.

### —Carboxy Compound—

The carboxy compound only needs to include at least one carboxy group, and is preferably a compound represented by Formula (IX) or (X).

HOOC-A-COOH Formula (IX)

In Formula (IX), a symbol A represents a divalent linking group. The divalent linking group is preferably a combination of an alkylene group, an arylene group or an alkenylene group with an oxygen atom, a sulfur atom or a nitrogen atom; and more preferably a combination of an alkylene group or an arylene group with an oxygen atom or a sulfur atom. In addition, when the divalent linking group is a combination of an alkylene group and a sulfur atom, the compound corresponds also to a thioether compound. Use of such a thioether compound is also preferred.

When the divalent linking group represented by A includes an alkylene group, the alkylene group may have a substituent. The substituent is preferably an alkyl group, and more preferably has a carboxy group as a substituent.

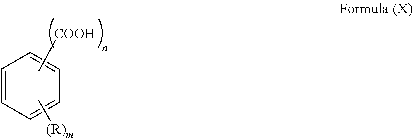

In Formula (X), R represents a sulfo group, a halogen atom, an alkyl group, an aryl group, a hydroxy group, or an alkoxycarbonyl group; n represents 1 to 6; and m represents 0 to 5.

R is preferably a sulfo group, an alkyl group, an aryl group, a hydroxy group, or an alkoxycarbonyl group; more preferably a sulfo group, or an alkoxycarbonyl group.

n is preferably 1 to 5, more preferably 1 to 4, further preferably 1 to 3.

m is 0 to 5, preferably 0 to 4, more preferably 0 to 3.

### —Sulfonic Acid Compound—

A sulfonic acid compound has at least one sulfo group, and preferably has two or more sulfo groups. The sulfonic acid compound is preferably replaced by an aryl group or an alkyl group, and more preferably, an aryl group.

In the hydroxy compound and the carboxy compound described above, a compound having a sulfo group as a substituent is classified into the hydroxy compound and the carboxy compound as described above. Therefore, the sulfonic acid compound does not include a hydroxy compound and a carboxy compound each having a sulfo group.

In the present invention, it is not essential to use these dopants, but when dopant is used, a further enhancement of the thermoelectric conversion performance can be expected as a result of an enhancement of electrical conductivity, and thus it is preferable. In case of using the dopant, one kind can be used alone, or two or more kinds thereof can be used in combination.

Among the dopants described above, an onium salt compound is preferably used from the standpoint of improving the dispersibility and the film-forming property of the dispersion for a thermoelectric conversion layer. The onium salt compound is neutral before acid release, and generates an acid by being decomposed when energy such as light or heat is imparted, and this acid causes doping effect to be developed. Therefore, after a film of the dispersion for a thermoelectric conversion layer is formed in a desired shape as the thermoelectric conversion layer, the doping is carried out by light irradiation or the like and thus the doping effect can be exerted. Further, since the onium salt compound is neutral before acid release, each component such as the conjugated polymer or the nano conductive material is uniformly dissolved or dispersed in the dispersion for a thermoelectric conversion layer without the aggregation or precipitation of the above-described conjugated polymer. Due to this uniform solubility or dispersibility of the dispersion for a thermoelectric conversion layer, excellent electrical conductivity can be exerted after doping. Further, since favorable coating property or film-forming property can be achieved, the formation of a film such as the thermoelectric conversion layer and the like is also excellent.

### B. Case of not Using the Conjugated Polymer

Even in the case of not using the conjugated polymer, a dopant can be used for improving the electrical conductivity of a nano conductive material to be used, particularly, the CNT and for adjusting an electric property such as pn polarity. It is possible to adjust the electrical conductivity of a nano conductive material, particularly, the CNT or pn polarity by appropriately selecting kinds or an amount of the dopant.

As a p-type dopant, the onium salt compound, the oxidizing agent, the acidic compound, the electron acceptor compound and the like as described above can be preferably used.

As an n-type dopant, a well-known dopant can be used. For example, it is possible to use a reducing material or electron donating compound and the like. Examples thereof include an amine compound such as ammonia or tetramethyl phenylenediamine, an imine compound such as polyethylenimine, an alkali metal such as potassium, a phosphine compound such as triphenylphosphine or trioctylphosphine, a metal hydride such as sodium borohydride or lithium aluminum hydride, hydrazine, and the like. Specifically, a well-known compound as described in Scientific Reports 3, 3344 can be used.

Further, in addition to the use of the above-described dopant in combination, doping is performed by introducing a minute amount of an element other than carbon into a nanotube during the synthesis of the nanotube such that the electrical property of the CNT may be adjusted. Specifically, a well-known method as described in U.S. patent Ser. No. 11/488,387 can be used.

### <Thermal Excitation Assist Agent>

In the case of using the above-described conjugated polymer in the method of preparing a dispersion for a thermoelectric conversion layer of the present invention, it is preferable to further use a thermal excitation assist agent in terms of further improving thermoelectric conversion performance. That is, the dispersion for a thermoelectric conversion layer contains preferably a conjugated polymer and a thermal excitation assist agent.

A thermal excitation assist agent is a substance having a molecular orbital with a particular energy level difference relative to the energy level of the molecular orbital of the conjugated polymer, and when used together with the conjugated polymer, the thermal excitation assist agent can increase the thermal excitation efficiency and thereby enhance the thermopower of the thermoelectric conversion layer.

The thermal excitation assist agent used in the present invention refers to a compound which has a LUMO with a lower energy level than that of the LUMO of the above-described conjugated polymer, and thereby does not form a doping level in the conjugated polymer. The dopant described above is a compound that forms a doping level in the conjugated polymer, and forms a doping level irrespective of the presence or absence of a thermal excitation assist agent.

Whether or not the doping level is formed in the conjugated polymer can be evaluated by measurement of absorption spectra. A compound that forms the doping level or a compound that does not form the doping level refer to ones evaluated by the following method.

### —Method for Evaluating Presence or Absence of Doping Level Formation—

Conjugated polymer A before doping and another component B are mixed in a mass ratio of 1:1, and absorption spectra of a thin-filmed sample is observed. As a result, when a new absorption peak different from absorption peaks of conjugated polymer A alone or component B alone appears, and a wavelength of the new absorption peak is on a side of wavelength longer than an absorption maximum wavelength of the conjugated polymer A, the doping level is judged to be generated. In this case, component B is defined as a dopant. On the other hand, in a case where the new absorption peak is not present in the absorption spectra of the sample, the component B is defined as a thermal excitation assist agent.

The LUMO of the thermal excitation assist agent has a lower energy level in comparison with the LUMO of the above-described conjugated polymer, and functions as an acceptor level of thermal excitation electrons generated from the HOMO of the conjugated polymer.

Further, when an absolute value of the energy level of the HOMO of the conjugated polymer and an absolute value of the energy level of the LUMO of the thermal excitation assist agent have relation satisfying the following numerical expression (I), the dispersion for a thermoelectric conversion layer can be used to produce a thermoelectric conversion layer having excellent thermopower.

0.1 eV≦|(HOMO of a conjugated polymer)|−|(LUMO of a thermal excitation assist agent)|≦1.9 eV Numerical expression (I)

The above-described numerical expression (I) represents an energy difference between the absolute value of the HOMO of the conjugated polymer and the absolute value of the LUMO of the thermal excitation assist agent. The energy difference between both orbitals is preferably within the range of the above-described numerical expression (I), in terms of improving the thermopower of the thermoelectric conversion element. That is, when the energy difference is 0.1 eV or more (including a case where the energy level of the LUMO of the thermal excitation assist agent is larger than the energy level of the HOMO of the conjugated polymer), the activation energy of electron transfer between the HOMO (donor) of the conjugated polymer and the LUMO (acceptor) of the thermal excitation assist agent increases. Therefore, the aggregation caused by the oxidation-reduction reaction is less likely to occur between the conjugated polymer and the thermal excitation assist agent. As a result, the film-forming property of the dispersant for a thermoelectric conversion layer and the electrical conductivity of the thermoelectric conversion layer are excellent. Meanwhile, when the energy difference between both orbitals is 1.9 eV or less, the energy difference becomes smaller than the thermal excitation energy. Therefore, the thermal excitation carrier occurs and an effect of addition of the thermal excitation assist agent is exerted.

In this way, in the present invention, the thermal excitation assist agent and the conjugated polymer are distinguished by an absolute value of the energy level of the LUMO. Specifically, the thermal excitation assist agent is a compound having the LUMO of which the absolute value of the energy level is lower than that of the conjugated polymer used concurrently, preferably having the LUMO satisfying the above-described numerical expression.

In addition, with regard to the energy levels of the HOMO and the LUMO of the conjugated polymer and the thermal excitation assist agent, the HOMO energy levels of a coarting film (a glass substrate) can be measured according to a photoelectron spectroscopy, the film of which is prepared using each single component. The LUMO level can be calculated by measuring a band gap using a UV-Vis spectrophotometer, and then adding the HOMO energy as measured above. In the present invention, with regard to the energy levels of the HOMO and the LUMO of the conjugated polymer and the thermal excitation assist agent, values measured and calculated by the method are used.

When a thermal excitation assist agent is used, the thermal excitation efficiency is increased, and the number of thermal excitation carriers is increased, so that the thermopower of the thermoelectric conversion element is increased. Such effect caused by a thermal excitation assist agent is different from the technique of enhancing the thermoelectric conversion performance by the doping effect on the conjugated polymer.

As can be seen from the formula (A), for enhancement of the thermoelectric conversion performance of a thermoelectric conversion element, the absolute value of the Seebeck coefficient S and the electrical conductivity σ of the thermoelectric conversion layer may be made larger, and the thermal conductivity κ may be made smaller.

The thermal excitation assist agent enhances the thermoelectric conversion performance by increasing the Seebeck coefficient S. When a thermal excitation assist agent is used, electrons generated by thermal excitation are present in the LUMO of the thermal excitation assist agent, which is an acceptor level. Therefore, holes on the conjugated polymer and electrons on the thermal excitation assist agent exist in a physically isolated manner. Therefore, it becomes difficult for the doping level of the conjugated polymer to be saturated by the electrons generated by thermal excitation, and the Seebeck coefficient S can be increased.

The thermal excitation assist agent is preferably a polymer compound including at least one kind of structure selected from a benzothiadiazole structure, a benzothiazole structure, a dithienosilole structure, a cyclopentadithiophene structure, a thienothiophene structure, a thiophene structure, a fluorene structure and a phenylenevinylene structure, or a fullerene compound, a phthalocyanine compound, a perylenedicarboxyimide compound or a tetracyanoquinodimethane compound; and more preferably a polymer compound including at least one kind of structure selected from a benzothiadiazole skeleton, a benzothiazole structure, a dithienosilole structure, a cyclopentadithiophene structure and a thienothiophene structure, or a fullerene compound, a phthalocyanine compound, a perylenedicarboxyimide compound or a tetracyanoquinodimethane compound.

For a preferable compound as the above-described thermal excitation assist agent, a compound which can be used as in the “conjugated polymer” is also included. When two kinds of the conjugated polymers A and B are used in combination, in the case of the combination of the conjugated polymers satisfying the following numerical expression (II), the conjugated polymer B is defined as a thermal excitation assist agent and can be used.

0.1 eV≦|(HOMO of a conjugated polymer)|−|(LUMO of a thermal excitation assist agent)|≦1.9 eV Numerical expression (II)

The above-described numerical expression (II) represents an energy difference between the absolute value of the HOMO of the conjugated polymer A and the absolute value of the LUMO of the conjugated polymer B.

Specific examples of the thermal excitation assist agents satisfying the above-mentioned features include the following ones, but the present invention is not limited thereto. In the following exemplified compounds, n represents an integer (preferably an integer of 10 or more), and Me represents a methyl group.

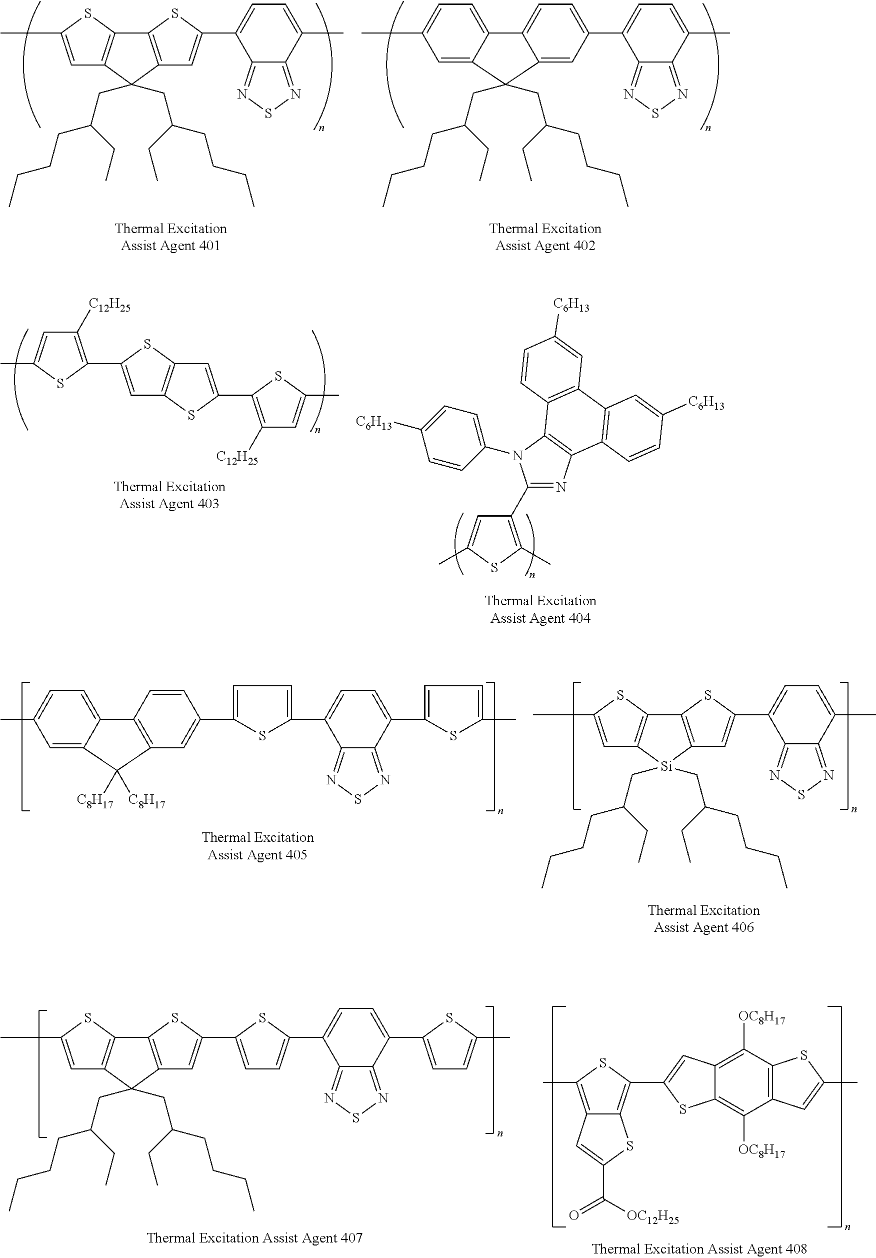

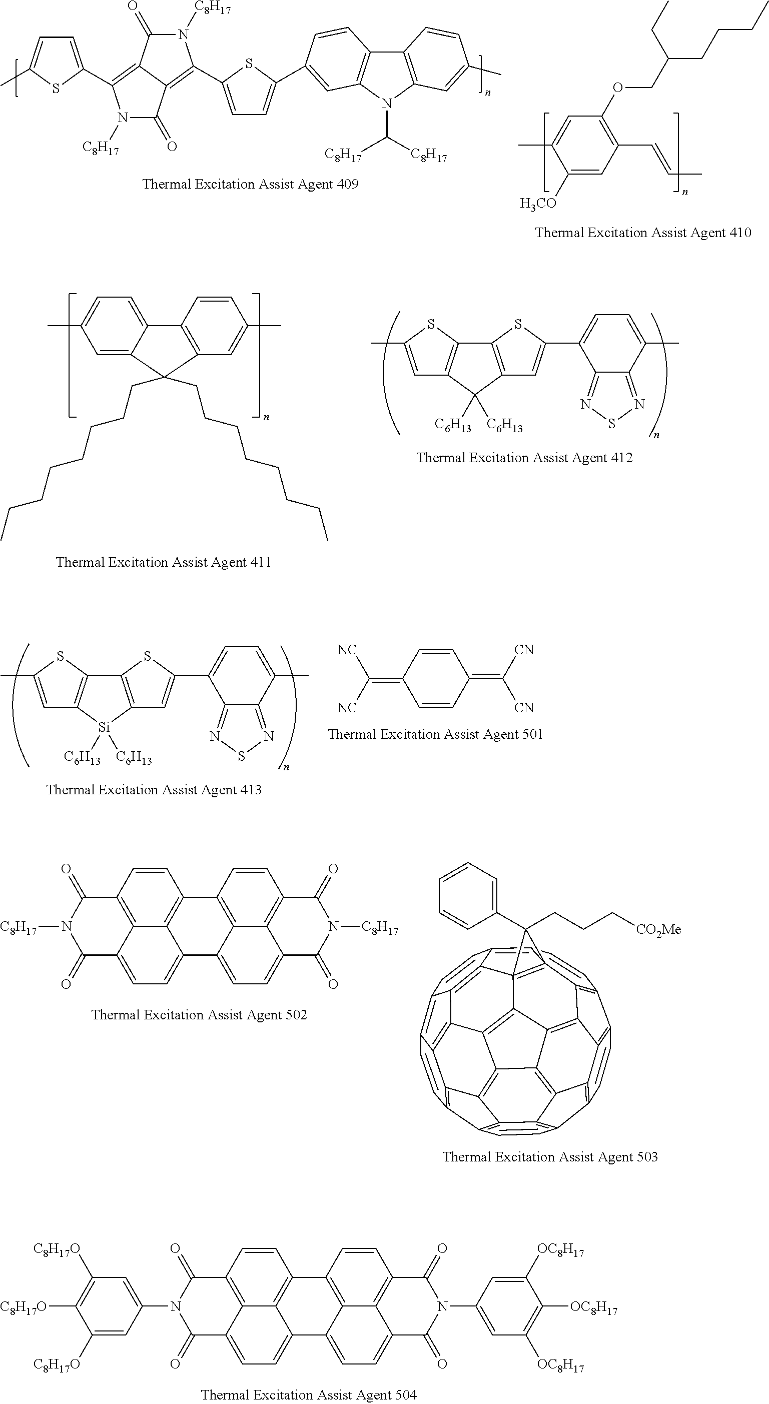

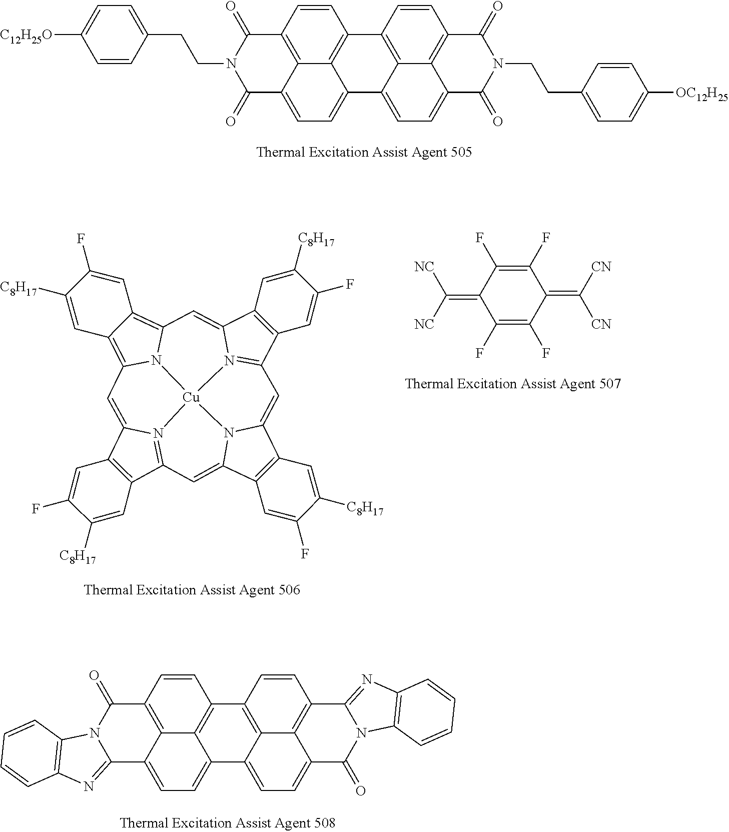

In the dispersion for a thermoelectric conversion layer to be used in the present invention, the above-described thermal excitation assist agent can be used alone in one kind or in combination with two or more kinds.

### <Metal Element>

In the method of preparing a dispersion for a thermoelectric conversion layer of the present invention, a metal element is preferably used as a simple substance, an ion, or the like, in terms of further improving thermoelectric conversion performance. That is, the dispersion for a thermoelectric conversion layer preferably contains a metal element. One kind of the metal elements can be used alone or two or more kinds thereof can be used in combination.

Here, in the case of using a metal element as a simple substance, metal which is nano-sized by a mechanical treatment or the like is used as the above-described metal nanoparticles, and aside from this, this metal can be used as, for example, submicron-sized metal particles.

When the metal element is added to the dispersion for a thermoelectric conversion layer, electron transportation in the thermoelectric conversion layer to be formed is promoted by the metal element, and thus thermoelectric conversion performance are considered to be improved. The metal element is not particularly limited, but a metal element having an atomic weight of 45 to 200 is preferable, a transition metal element is more preferable, and zinc, iron, palladium, nickel, cobalt, molybdenum, platinum, and tin are particularly preferable, in terms of thermoelectric conversion performance.

### <Other Component>

In the method of preparing a dispersion for a thermoelectric conversion layer of the present invention, in addition to the above-described components, an antioxidant, a light-resistant stabilizer, a heat-resistant stabilizer, a plasticizer and the like can be used. That is, the dispersion for a thermoelectric conversion layer may contain an antioxidant, a light-resistant stabilizer, a heat-resistant stabilizer, a plasticizer and the like.

Specific examples of the antioxidant include IRGANOX 1010 (manufactured by Nihon Ciba-Geigy K.K.), SUMILIZER GA-80 (manufactured by Sumitomo Chemical Co., Ltd.), SUMILIZER GS (manufactured by Sumitomo Chemical Co., Ltd.) and SUMILIZER GM (manufactured by Sumitomo Chemical Co., Ltd.). Specific examples of the light-resistant stabilizer include TINUVIN 234 (manufactured by BASF), CHIMASSORB 81 (manufactured by BASF) and CYASORB UV-3853 (manufactured by Sun Chemical Corporation). Specific examples of the heat-resistant stabilizer include IRGANOX 1726 (manufactured by BASF). Specific examples of the plasticizer include ADK CIZER RS (manufactured by ADEKA Corporation).

### <Preparation of the Dispersion for Thermoelectric Conversion Layer>

The dispersion for a thermoelectric conversion layer to be used in the present invention is prepared by subjecting at least a nano conductive material and a dispersion medium to the high-speed rotating thin film dispersion method.

For preparing the dispersion for a thermoelectric conversion layer, at least a nano conductive material and a dispersion medium may be directly subjected to the high-speed rotating thin film dispersion method, but it is preferable that at least a nano conductive material and a dispersion medium be preliminarily mixed to prepare a preliminary mixture before they are subjected to the high-speed rotating thin film dispersion method, and then the preliminary mixture be subjected to the high-speed rotating thin film dispersion method. When at least a nano conductive material and a dispersion medium are preliminarily mixed, the dispersibility by the high-speed rotating thin film dispersion method can be improved.

This preliminary mixing can be performed in such a manner that the nano conductive material is mixed with the dispersion medium and, as required, a dispersant, a non-conjugated polymer, a dopant, a thermal excitation assist agent, other components, and the like using a general mixing device under normal pressure. For example, each component is stirred, shaken, and kneaded in the dispersion medium. The ultrasonication may be performed in order to promote dissolution and dispersion. In the preliminary mixing, for example, a mechanical homogenizer method, a jaw-crusher method, an ultracentrifugation mill method, a cutting mill method, an automatic mortar method, a disc mill method, a ball mill method, an ultrasonic dispersion method, or the like can be employed. Further, as necessary, these methods may be used in combination of two or more thereof.

This preliminary mixing can be performed, for example, at a temperature of 0° C. or higher. When, in the preliminary mixing, heating is performed preferably at a temperature of room temperature to a boiling temperature of the dispersion medium, and more preferably at 50° C. or lower, a mixing time is increased, or an intensity of stirring, shaking, kneading or applying ultrasonic waves and the like is increased, the dispersibility of the nano conductive material can be increased to some extent. When an onium salt is used, the preliminary mixing may be performed under a temperature at which the onium salt does not generate an acid and in a state where radiation, electromagnetic waves, or the like is blocked.

The preliminary mixing can be performed under atmospheric air, but preferably in an inert atmosphere. The inert atmosphere means a state where an oxygen concentration is less than a concentration in atmospheric air. Preferably, the atmosphere has an oxygen concentration of 10% or less. As a method of achieving the inert atmosphere, a method of replacing atmospheric air by a gas such as nitrogen or argon is exemplified and is preferably used.

The solid content concentration of the preliminary mixture is preferably 0.2 to 20 w/v % and more preferably 0.5 to 20 w/v % in terms of the fact that a great shear stress is generated by the high-speed rotating thin film dispersion method described below.

The mixing rate of the nano conductive material is preferably 10% by mass or more, more preferably 15 to 100% by mass, and even more preferably 20 to 100% by mass in the total solid content of the preliminary mixture, in terms of film-forming property, electrical conductivity, and thermoelectric conversion performance.

The mixing rate of the conjugated polymer in the dispersant is preferably 0 to 80% by mass, preferably 3 to 80% by mass, more preferably 5 to 70% by mass, even more preferably 10 to 60% by mass, and particularly preferably 10 to 50% by mass in the total solid content of the preliminary mixture, in terms of the dispersibility of the nano conductive material, and the electrical conductivity and the thermoelectric conversion performance of the thermoelectric conversion element. Even in the case of containing a non-conjugated polymer, the mixing rate of the conjugated polymer is preferably within the above range.

In the case of using a low molecule dispersant as a dispersant, the mixing rate of the low molecule dispersant is preferably 3 to 80% by mass, more preferably 5 to 70% by mass, and even more preferably 10 to 60% by mass in the total solid content of the preliminary mixture, in terms of the dispersibility of the nano conductive material.

In the case of using a non-conjugated polymer, the mixing rate of the non-conjugated polymer is preferably 3 to 80% by mass, more preferably 5 to 70% by mass, and even more preferably 10 to 60% by mass in the total solid content of the preliminary mixture, in terms of the film-forming property of the dispersion for a thermoelectric conversion layer.

In the case of using a dopant, the mixing rate of the dopant is preferably 1 to 80% by mass, more preferably 5 to 70% by mass, and even more preferably 5 to 60% by mass in the total solid content of the preliminary mixture, in terms of the electrical conductivity of the thermoelectric conversion layer.

The mixing rate of the thermal excitation assist agent is preferably 0 to 35% by mass, more preferably 3 to 25% by mass, and even more preferably 5 to 20% by mass in the total solid content of the preliminary mixture, in terms of the thermoelectric conversion performance of the thermoelectric conversion layer.

In the case of using a metal element, the mixing rate of the metal element is preferably 50 to 30,000 ppm, more preferably 100 to 10,000 ppm, and even more preferably 200 to 5,000 ppm in the total solid content of the preliminary mixture, in terms of improving thermoelectric conversion performance by preventing cracks due to a decrease in physical strength of the thermoelectric conversion layer from occurring. The concentration (mixing rate) of the metal element in the preliminary mixture can be measured by a well-known analysis method using, for example, an ICP mass spectrometer (for example, “ICPM-8500” (product name) manufactured by Shimadzu Corporation) or an energy dispersive X-ray fluorescence spectrometer (for example, “EDX-720” (trade name) manufactured by Shimadzu Corporation).

The mixing rate of other components is preferably 5% by mass or less and more preferably 0 to 2% by mass in the total solid content of the preliminary mixture.

In the preliminary mixing, the order of mixing each component is not particularly limited, but it is preferable that a component, which can be dissolved in a dispersion medium, be first mixed and dissolved in the dispersion medium and then a component, which can not be dissolved in the dispersion medium, be mixed thereto. For example, it is preferable that, after a dispersant, a non-conjugated polymer, and the like are mixed and dissolved in a dispersion medium, a nano conductive material be mixed thereto.

The viscosity (25° C.) of the preliminary mixture is not particularly limited as long as it is a viscosity in which the preliminary mixture can be subjected to the high-speed rotating thin film dispersion method, but the viscosity is, for example, preferably 10 to 100,000 mPa·s and more preferably 15 to 5,000 mPa·s, in terms of improving handleability and dispersing efficiency by the high-speed rotating thin film dispersion method.

In the method of producing a thermoelectric conversion element of the present invention, the preliminary mixture obtained by performing the preliminary mixing in this way, or the nano conductive material and the dispersion medium which have been not subjected to the preliminary mixing are subjected to the high-speed rotating thin film dispersion method, and the nano conductive material is dispersed in the dispersion medium.

Here, the high-speed rotating thin film dispersion method is a dispersion method of dispersing a dispersion target substance in a cylindrical thin film-shaped dispersion treatment target substance in such a manner that the dispersion treatment target substance is rotated at high speed while being pressed in a cylindrical thin film shape onto an inner surface (inner wall surface) of an apparatus by centrifugal force, and the centrifugal force and shear stress generated by a speed difference with respect to the inner surface of the apparatus are allowed to act on the preliminary mixture or the like.

The dispersion treatment by the high-speed rotating thin film dispersion method can be performed using, for example: an apparatus which includes a tubular outer body having a circular cross section; a tubular stirring blade disposed in the tubular outer body to be rotatable concentrically with the tubular outer body; and an injection tube opening to the lower side of the stirring blade, in which the stirring blade has an outer periphery facing the inner periphery of the tubular outer body with a small space interposed therebetween, and a plurality of through holes penetrating the tubular wall of the stirring blade in the thickness direction. The space between the inner periphery of the tubular outer body and the outer periphery of the stirring blade is appropriately adjusted depending on the treated amount of the dispersion treatment target substance, a target dispersion degree, or the like, and there is no particular limitation on the space. For example, the space is preferably 5 to 0.1 mm and more preferably 2.5 to 0.1 mm. As described herein, the stirring blade has a tubular structure having the above-described outer periphery.

As such an apparatus, for example, a thin-film spin system high-speed mixer “FILMIX” (registered trademark) series (manufactured by PRIMIX Corporation) can be preferably used.

In the method of producing a thermoelectric conversion element of the present invention, as the dispersion treatment target substance of the high-speed rotating thin film dispersion method, the preliminary mixture described above, or the nano conductive material and the dispersion medium (hereinafter, referred to as “the preliminary mixture or the like”) is used. This dispersion method is to disperse the preliminary mixture or the like by centrifugal force and shear stress, and it is possible to suppress the dividing or breaking of the nano conductive material and the occurrence of defects during the dispersion treatment.

The dispersion treatment according to the high-speed rotating thin film dispersion method can be performed in such a manner that the preliminary mixture or the like, that is, a stirring blade is rotated, for example, at a circumferential velocity of 5 to 60 m/sec, preferably 10 to 50 m/sec, more preferably 10 to 45 m/sec, even more preferably 10 to 40 m/sec, particularly preferably 20 to 40 m/sec, and the most preferably 25 to 40 m/sec.

The treatment time can be appropriately decided depending on the dispersion degree or the like of the nano conductive material, and for example, is preferably 1 to 20 minutes and more preferably 2 to 10 minutes.

The dispersion treatment according to the high-speed rotating thin film dispersion method can be performed at 0° C. to room temperature or in heat condition, under normal pressure. The temperature at which the dispersion treatment is performed is decided depending on kinds of the dispersion medium to be used, but is preferably in a range of 10° C. to 55° C. and more preferably at 15° C. to 45° C., from the standpoint of safety and the standpoint of maintaining viscosity properties. Further, this dispersion treatment can also be performed under atmospheric air, or can also be performed in the inert atmosphere described above.

The treatment amount (mixing rate) of each component in a case where the nano conductive material, the dispersion medium, and the like are directly subjected to the high-speed rotating thin film dispersion method is the same as the mixing rate of each component in the preliminary mixing.

When the preliminary mixture or the like is subjected to the high-speed rotating thin film dispersion method in this way, preferably by using a thin-film spin system high-speed mixer “FILMIX”, it is possible to prepare a dispersion for a thermoelectric conversion layer in which the nano conductive material is dispersed in the dispersion medium.

The solid content concentration of the dispersion for a thermoelectric conversion layer to be prepared is preferably 0.2 to 20 w/v % and more preferably 0.5 to 20 w/v % in terms that the dispersion for a thermoelectric conversion layer is excellent in printing property and can be applied by a printing method, and it is possible to make the thermoelectric conversion layer thick.

The content of the nano conductive material in those solid contents is the same as in the preliminary dispersion, and is preferably 10% by mass or more, more preferably 15% by mass or more, and particularly preferably 25% by mass or more, in terms of electrical conductivity and thermoelectric conversion performance. The upper limit is 100% by mass.

The viscosity of the dispersion for a thermoelectric conversion layer at 25° C. is preferably 10 mPa·s or more, more preferably 10 to 100,000 mPa·s, even more preferably 10 to 5,000 mPa·s, and particularly preferably 10 to 1,000 mPa·s, in terms that the dispersion for a thermoelectric conversion layer is excellent in printing property and film-forming property even when being applied by a printing method.

In the nano conductive material dispersed in the dispersion for a thermoelectric conversion layer, as described above, dividing, breaking, and defects are almost suppressed. For example, in a case where the nano conductive material is the above-described nanocarbon material, the quantity of defects can be estimated by means of the intensity ratio [Id/Ig] of the D band intensity (Id) and the G band intensity (Ig) in Raman spectrochemical analysis. As the intensity ratio [Id/Ig] becomes smaller, the quantity of defects can be estimated to be small.

In the present invention, the intensity ratio [Id/Ig] of the nano conductive material in the dispersion is preferably 0.01 to 1.5, more preferably 0.015 to 1.3, and even more preferably 0.02 to 1.2.

In a case where the nano conductive material is a single-walled carbon nanotube, the intensity ratio [Id/Ig] is preferably 0.01 to 0.4, more preferably 0.015 to 0.3, and even more preferably 0.02 to 0.2. Further, in a case where the nano conductive material is a multi-walled carbon nanotube, the intensity ratio [Id/Ig] is preferably 0.2 to 1.5 and more preferably 0.5 to 1.5.

In the nano conductive material dispersed in this dispersion for a thermoelectric conversion layer, the average particle diameter D, which is measured by a dynamic light scattering method, is preferably 1,000 nm or less, more preferably 1,000 to 5 nm, and even more preferably 800 to 5 nm. When the average particle diameter D of the nano conductive material in the dispersion for a thermoelectric conversion layer is within the above range, the electrical conductivity of the thermoelectric conversion element and the film-forming property of the thermoelectric conversion material are excellent. The average particle diameter D is obtained as an arithmetic mean value of the volumetric diameter.

Further, the ratio (dD/D) of the half-value width dD in the particle size distribution and the average particle diameter D, of the nano conductive material in the dispersion for a thermoelectric conversion layer is preferably 5 or less, more preferably 4.5 or less, and even more preferably 4 or less. When the ratio (dD/D) of the nano conductive material in the dispersion for a thermoelectric conversion layer is within the above range, the printing property of the thermoelectric conversion material is excellent.

In the method of producing a thermoelectric conversion element of the present invention, subsequently, the step of applying the dispersion for a thermoelectric conversion layer prepared in the step of preparing a dispersion for a thermoelectric conversion layer on or above the substrate and then drying the dispersion is performed, thereby forming a thermoelectric conversion layer.

For the substrate of the thermoelectric conversion element of the present invention, for example, the first substrate 12 and the second substrate 16 in the above-described thermoelectric conversion element 1, a substrate such as glass, transparent ceramics, a metal, or a plastic film can be used. In the present invention, a substrate having flexibility can also be used. Specifically, it is preferable to use a substrate having flexibility in which the number of cycles on folding endurance test MIT by the measurement method according to ASTM D2176 is 10,000 or more. Such a substrate having flexibility is preferably a plastic film, and preferred examples of the plastic film include plastic films (resin films) of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, polyimide, polycarbonate, polypropylene, polyether sulfone, cycloolefin polymer, polyether ether ketone (PEEK), triacetylcellulose (TAC), and cycloolefin; glass epoxy; and liquid-crystalline polyester.

Among them, from the standpoint of easy availability and economic efficiency, as a substrate which is not dissolved in the dispersion medium and in which printing can be performed, polyether ether ketone, polyethylene terephthalate, polyethylene naphthalate, polyimide, glass epoxy, and liquid-crystalline polyester are preferable, and polyethylene terephthalate, polyethylene naphthalate, polyimide, glass epoxy, and liquid-crystalline polyester are particularly preferable.

In addition, as long as the effect as a substrate is not impaired, a copolymer of the above-described resins or a blended product of these resins and other types of resins can be used.

Further, in order to improve slip properties, a small amount of inorganic or organic fine particles, a bonding property improver or an antistatic agent, such as polyethylene glycol (PEG) or sodium dodecylbenzenesulfonate can be included in the resin film. Examples of the particles may include an inorganic filler such as titanium oxide, calcium carbonate, silica, barium sulfate, or silicone; and an organic filler such as acryl, benzoguanamine, Teflon (registered trademark), or epoxy.

In the method of producing each resin film, well-known methods or conditions can be appropriately selected and used. For example, a polyester film can be formed by processing the above-described polyester resin into a film form by melting extrusion, orientation and crystallization by biaxial stretching in both horizontal and vertical directions, and crystallization by heat treatment.

The thickness of the substrate is preferably 30 to 3,000 μm, more preferably 50 to 1,000 μm, even more preferably 100 to 1,000 μm, and particularly preferably 200 to 800 μm, in terms of thermal conductivity, handleability, durability, and prevention of breakage of the thermoelectric conversion layer due to external impact.

In particular, in this process, it is preferable to use a substrate provided with an electrode on the compression bonding surface with the thermoelectric conversion layer.

The first electrode and the second electrode are preferably formed using any of well-known metals, for example, a metal electrode such as copper, silver, gold, platinum, nickel, chromium, or a copper alloy and a transparent electrode such as indium tin oxide (ITO) or zinc oxide (ZnO). For example, the electrode is formed by preferably using any of copper, gold, platinum, nickel, and a copper alloy, and more preferably using any of gold, platinum, and nickel. Alternatively, it is possible to use a material obtained by solidifying a metal paste prepared in such a manner that the above-described metal is formed into fine particles, and a binder and a solvent are added to the fine particles.

The formation of the electrode can be performed by a plating method, a patterning method using etching, a sputtering method or ion plating method using a lift-off method, or a sputtering method or ion plating method using a metal mask. Alternatively, a metal paste prepared in such a manner that the above-described metal is formed into fine particles, and a binder and a solvent are added to the fine particles may be used. In the case of using the metal paste, a printing method using a screen printing method or a dispenser method can be used. After printing, heating for drying or heating treatment for decomposing a binder or sintering a metal may be performed.

The method of applying the dispersion for a thermoelectric conversion layer on or above the substrate is not particularly limited, and well-known coating methods, such as spin coating, extrusion die coating, blade coating, bar coating, screen printing, an ink jet printing method of ejecting the dispersion for a thermoelectric conversion layer by an ink jet method to perform printing, stencil printing, roll coating, curtain coating, spray coating, and dip coating, can be used. Among them, from the standpoint that the dispersion for a thermoelectric conversion layer is excellent in printing property even when the dispersion has a high solid content concentration and a high viscosity, printing methods such as screen printing, an ink jet printing method, and stencil printing are preferable. In particular, metal mask printing, which is one kind of screen printing, of printing the dispersion for a thermoelectric conversion layer by using a metal mask is particularly preferable from the standpoint that, according to the metal mask printing, a dispersion may be printed on a thick coating film by performing a coating process once and the adhesiveness of the thermoelectric conversion layer to the electrode is excellent.

In the screen printing, in addition to a method in which a photosensitive resin is subjected to patterning exposure on a general stainless steel, nylon, or polyester mesh, development is carried out to produce a plate, thereby performing printing, a method of producing a plate from a metal mask subjected to etching and performing printing, or the like is included.

In order to apply the dispersion for a thermoelectric conversion layer to a desired position and in a desired size when the dispersion for a thermoelectric conversion layer is applied on or above the substrate, various masks and the like can be used.

The metal mask printing method will be described later in detail by means of Examples.

The ink jet printing method is performed as follows.

The total solid content concentration in the dispersion for a thermoelectric conversion layer as the ink jet coating liquid is generally 0.05 to 30 w/v %, more preferably 0.1 to 20 w/v %, and even more preferably 0.5 to 10 w/v %.

The viscosity of this dispersion for a thermoelectric conversion layer is appropriately decided depending on temperature during discharging, from the standpoint of discharging stability.

This dispersion for a thermoelectric conversion layer is filtered through a filter, and then is applied onto a substrate or an electrode as described below and used. The filter used in the filtration through a filter is preferably a polytetrafluoroethylene, polyethylene, or nylon filter having a pore size of 2.0 μm or less, and more preferably 0.5 μm or less.

As an organic solvent to be used as the dispersion medium in the dispersion for a thermoelectric conversion layer for ink jet printing, a conventionally well-known organic solvent can be appropriately used according to the organic materials or the nano conductive material described above.

As the organic solvent, the above-described dispersion medium or the like is exemplified. Examples thereof may include well-known organic solvents such as an aromatic solvent, alcohol solvent, a ketone solvent, an aliphatic hydrocarbon solvent, an amide solvent, and an aliphatic halogen solvent. As these organic solvents, the following solvents other than the above-described solvents are exemplified.

Examples of the aromatic solvent include trimethylbenzene, cumene, ethyl benzene, methylpropyl benzene, methylisopropyl benzene, and tetrahydronaphthalene. Among these, xylene, cumene, trimethylbenzene, tetramethylbenzene and tetrahydronaphthalene are more preferred.

Examples of the alcohol include methanol, ethanol, butanol, benzyl alcohol, and cyclohexanol. Among these, benzyl alcohol and cyclohexanol are more preferred.

Examples of the ketone solvent include 1-octanone, 2-octanone, 1-nonanone, 2-nonanone, 4-heptanone, 1-hexanone, 2-hexanone, 2-butanone, diisobutyl ketone, methylcyclohexanone, phenylacetone, methyl isobutyl ketone, acetylacetone, acetonylacetone, ionone, diacetonyl alcohol, acetylcarbinol, acetophenone, methylnaphthylketone, isophorone, and propylene carbonate. Among these, methyl isobutyl ketone and propylene carbonate are preferred.

Examples of the aliphatic hydrocarbon solvent include pentane, hexane, octane, and decane. Among these, octane and decane are preferred.

Examples of the amide solvent include N-ethyl-2-pyrrolidone, N,N-dimethylacetamide, and 1,3-dimethyl-2-imidazolidinone. Among these, N-methyl-2-pyrrolidone and 1,3-dimethyl-2-imidazolidinone are preferred.

The above-described solvents may be used alone or two or more thereof may be used in combination.

As illustrated in FIG. 3, as a substrate 31 to be used in an ink jet printing method, it is preferable to use a substrate having banks 33 formed thereon such that the banks 33 surround the outer periphery of a region 32 in which the thermoelectric conversion layer is to be formed. That is, the whole region 32 in which the thermoelectric conversion layer is to be formed is partitioned by the banks 33. For this reason, due to the banks 33, the dispersion for a thermoelectric conversion layer ejected according to an ink jet method can be stored in the banks 33 and the thermoelectric conversion layer having a height (not illustrated) can be formed.

Examples of the cross-sectional shape of the bank 33 include an arc shape (a semicircular shape, a semi-elliptical shape), a triangular shape, a parabolic shape, and a trapezoidal shape, and the upper portion of the bank 33 preferably has no flat portion. Therefore, the cross-sectional shape of the bank 33 is preferably a convex curve shape such as a semicircular shape, a semi-elliptical shape, a triangular shape, or a parabolic shape. When the upper portion of the bank 33 has no flat portion, liquid drops attached to the bank 33 are difficult to be accumulated on the upper surface of the bank 33, and the liquid drops can be moved efficiently to the region 32 in which the thermoelectric conversion layer is formed, by passing through the side surface, which is formed by the convex curve, of the bank 33. The bank 33 has more preferably an arc shape and a triangular shape, and more preferably an arc shape.

Examples of the material of the bank 33 include polyimide, novolak resin, epoxy resin, and acrylic resin, and from the standpoint of the liquid-repellent property and heat resistance, polyimide is preferably exemplified.

As necessary, a liquid-repellent treatment may be performed on the bank. As a specific method, a fluorocarbon film is formed on the bank 33 by the CVD method using carbon tetrafluoride (CF₄) as a raw material gas, or a silane coupling agent having a long-chain fluoroalkyl group or a fluorine polymer may be mixed in the bank.

Examples of the method of forming the bank 33 include a method of performing patterning and developing by means of UV light using a photosensitive resist including a dry resist, polyimide, or photosensitive glass, a method of applying, in a laminated manner, a resist on polyimide in which alkaline development can be performed and performing patterning and developing by means of UV light, and a method of performing patterning by screen printing using an epoxy resin and UV cross-linking.

The region 32 in which the thermoelectric conversion layer is to be formed is a region surrounded by the bank 33, and the dispersion for a thermoelectric conversion layer is applied to this region. As necessary, before or after the dispersion for a thermoelectric conversion layer is applied to the region 32 in which the thermoelectric conversion layer is to be formed, a layer may be formed by applying a liquid containing components other than the components contained in the dispersion for a thermoelectric conversion layer.

After the dispersion for a thermoelectric conversion layer is applied in this way, as required, a mask or the like is removed.

Next, the dispersion for a thermoelectric conversion layer is dried. Methods and conditions for drying are not particularly limited as long as the dispersion medium can be vaporized, and for example, the whole substrate may be dried or only the coating film of the dispersion for a thermoelectric conversion layer may be locally dried. As the drying method, for example, drying methods such as a heat drying method and a hot-air blowing method can be employed.

For example, the heating temperature and the heating time after the applying of the dispersion are not particularly limited as long as the dispersion for a thermoelectric conversion layer is dried, but generally, the heating temperature is preferably 100 to 200° C. and more preferably 120 to 160° C. Generally, the heating time is preferably 1 to 120 minutes, more preferably 1 to 60 minutes, and even more preferably 1 to 25 minutes.

Further, an arbitrary method such as a drying method of using a vacuum pump or the like in low-pressure atmosphere, a drying method of using a fan while an air is sent, or a method of performing drying while an inert gas (nitrogen or argon) is supplied can be used.

The thermoelectric conversion layer may be formed to be thick by repeating the coating by ink jet printing or the like and the heating and drying plural times. Further, regarding the heating and drying, a solvent may be completely vaporized or may not be vaporized.

In this way, the thermoelectric conversion layer is formed on or above the substrate. In this case, since the dispersion for a thermoelectric conversion layer has a high solid content concentration and a high viscosity and is excellent in printing property, the thermoelectric conversion layer to be formed is excellent in formability. In addition, it is possible to form a thicker thermoelectric conversion layer by performing coating once as compared to the related art.

The layer thickness of the thermoelectric conversion layer is preferably 0.1 to 1,000 μm and more preferably 1 to 100 μm. When the layer thickness is set to the above range, a temperature difference is easily imparted and resistance in the thermoelectric conversion layer can be prevented from being increased. In the present invention, among the above range, the thickness can be particularly increased.

In general, the thermoelectric conversion element can be further simply produced in comparison with a photoelectric conversion element such as an element for an organic thin film solar cell. In particular, in this case where the dispersion for a thermoelectric conversion layer is used, there is no need for considering light absorption efficiency as compared to the element for an organic thin film solar cell. Therefore, the film thickness can be increased about 100 to 1,000 times and chemical stability to oxygen or moisture in air is improved.

In the method of producing a thermoelectric conversion element of the present invention, when the dispersion for a thermoelectric conversion layer contains the onium salt compound as a dopant, it is preferable to enhance electrical conductivity by subjecting, after film forming, the relevant film to irradiation with active energy ray or heating to perform a doping treatment. This treatment causes generation of acid from the onium salt compound, and when this acid protonates the above-described conjugated polymer, the conjugated polymer is doped with a positive charge (p-type doping).

The active energy rays include radiation and electromagnetic waves, and the radiation includes particle beams (high-speed particle beams) and electromagnetic radiation. Specific examples of the particle beams include charged particle beams such as alpha rays (α-rays), beta rays (β-rays), proton beams, electron beams (meaning ones accelerating an electron by means of an accelerator without depending on nuclear decay), and deuteron beams; non-charged particle beams such as neutron beams; and cosmic rays. Specific examples of the electromagnetic radiation include gamma rays (γ-rays) and X-rays (X-rays and soft X-rays). Specific examples of the electromagnetic waves include radio waves, infrared rays, visible rays, ultraviolet rays (near-ultraviolet rays, far-ultraviolet rays, and extreme ultraviolet rays), X-rays, and gamma rays. Types of active energy rays used in the present invention are not particularly limited. For example, electromagnetic waves having a wavelength near a maximum absorption wavelength of the onium salt compound (an acid generator) may be selected as appropriate.

Among these active energy rays, from standpoints of the doping effect and safety, ultraviolet rays, visible rays, or infrared rays are preferred. Specifically, the active energy rays include rays having a maximum emission wavelength in the range of 240 to 1,100 nm, preferably in the range of 240 to 850 nm, and more preferably in the range of 240 to 670 nm.

For irradiation with active energy rays, radiation equipment or electromagnetic wave irradiation equipment is used. A wavelength of radiation or electromagnetic waves for irradiation is not particularly limited, and one allowing radiation or electromagnetic waves in a wavelength region corresponding to a response wavelength of the onium salt compound may be selected.

Specific examples of the equipment allowing radiation or irradiation with electromagnetic waves include exposure equipment using as a light source an LED lamp, a mercury lamp such as a high-pressure mercury lamp, an ultra-high pressure mercury lamp, a Deep UV lamp, and a low-pressure UV lamp, a halide lamp, a xenon flash lamp, a metal halide lamp, an excimer lamp such as an ArF excimer lamp and a KrF excimer lamp, an extreme ultraviolet ray lamp, electron beams, and an X-ray lamp. Irradiation with ultraviolet rays can be applied using ordinary ultraviolet ray irradiation equipment such as commercially available ultraviolet ray irradiation equipment for curing/bonding/exposure use (for example, SP9-250UB, USHIO INC.).

Exposure time and an amount of light may be selected as appropriate in consideration of a kind of onium salt compound to be used and the doping effect. Specific examples of the amount of light include 10 mJ/cm² to 10 J/cm², and preferably 50 mJ/cm² to 5 J/cm².

When doping is carried out by heating, a formed a thermoelectric conversion layer may be heated to a temperature higher than or equal to the temperature at which the onium salt compound generates acid. A heating temperature is preferably 50° C. to 200° C., and more preferably 70° C. to 150° C. Heating time is preferably 1 minute to 60 minutes, and more preferably 3 minutes to 30 minutes.

The timing of the doping treatment is not particularly limited, but it is preferable to perform the doping treatment after processing the dispersion for a thermoelectric conversion layer by film forming or the like.

In the method of producing a thermoelectric conversion element of the present invention, as required, a step of forming the second electrode on the formed thermoelectric conversion layer and laminating the second substrate thereon is performed. Alternatively, a step of laminating the second substrate having the second electrode on the formed thermoelectric conversion layer is performed. The second electrode is formed by using the electrode materials described above. It is preferable that the second electrode and the thermoelectric conversion layer come into press contact with each other by heating at about 100 to 200° C. from the standpoint of improving adhesiveness.

In this way, according to the method of producing a thermoelectric conversion element of the present invention, the thermoelectric conversion element having the first electrode, the thermoelectric conversion layer, and the second electrode, formed on or above the substrate, is produced. Further, the thermoelectric conversion layer formed by the dispersion for a thermoelectric conversion layer having high dispersibility and excellent printing property is excellent in the film-forming property and the adhesiveness with the substrate. Therefore, according to the thermoelectric conversion element of the present invention provided with this thermoelectric conversion layer, both of high electrical conductivity and excellent thermoelectric conversion performance are achieved.

Therefore, the thermoelectric conversion element of the present invention can be suitably used as a power generation device for an article for thermoelectric generation. Examples of such a power generation device include a generator such as hot spring thermal power generation, solar thermal electric conversion or cogeneration; a power supply for a wrist watch, a semiconductor drive power supply, and a power supply for a (small sized) sensor.

Further, the thermoelectric conversion layer formed by using the dispersion for a thermoelectric conversion layer is preferably used as the thermoelectric conversion layer of the thermoelectric conversion element of the present invention, a thermoelectric conversion film, or various conductive films. In addition, the dispersion for a thermoelectric conversion layer is preferably used as materials for them, for example, as a thermoelectric conversion material or a material for a thermoelectric generator element.

### EXAMPLES

The present invention will be described in more detail based on the following examples, but the invention is not intended to be limited thereto.

In Examples and Comparative Examples, the following polythiophene polymer or conjugated polymers 101 to 103 were used as a conjugated polymer, or the following imidazolium salt was used as a low molecule dispersant.

### <Conjugated Polymer>

Poly(3-octylthiophene-2,5-yl) (regiorandom, manufactured by Aldrich Co., weight average molecular weight: 98,000, also referred to as “P3OT”)

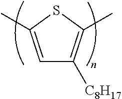

Conjugated polymer 101 (manufactured by Lumtec Corp., molecular weight: 7,000 to 20,000)

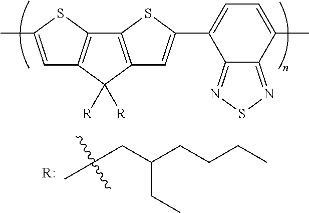

Conjugated polymer 102 (weight average molecular weight: 72,000)

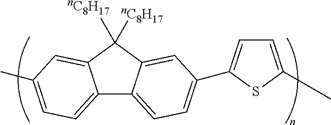

Conjugated polymer 103 (weight average molecular weight: 29,000)

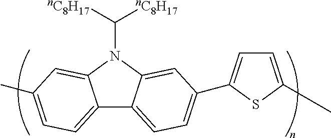

### Synthesis of Conjugated Polymer 102

This polymer was synthesized in accordance with a method described in a non-patent literature (Y. Kawagoe et al., New J. Chem., 2010, vol. 34, p. 637).

### Synthesis of Conjugated Polymer 103

This polymer was synthesized in accordance with a method described in a non-patent literature (L. EUNHEEY et al., Mol. Cryst. Liq. Cryst., vol. 551, p. 130), using 2,5-dibromothiophene as a thiophene raw material.

### <Low Molecule Dispersant>

1-Butyl-3-methylimidazolium hexafluorophosphate (manufactured by Aldrich Co.)

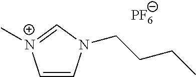

### Example 1 and Comparative Example 1

### 1. Preparation of Dispersion for Thermoelectric Conversion Layer 101

20 mL of o-dichlorobenzene was added to 100 mg of poly(3-octylthiophene-2,5-yl) and 100 mg (in terms of mass conversion of a single-walled carbon nanotube, and hereinafter, the same being applied) of a single-walled carbon nanotube “ASP-100F” (product name, produced by Hanwha Chemical Co., Ltd.), and the preliminary mixing was performed at 20° C. for 15 minutes using a mechanical homogenizer “T10basic” (manufactured by IKA), thereby obtaining a preliminary mixture 101. The solid content concentration of this preliminary mixture 101 was 1.0 w/v % (the CNT content in the solid contents (hereinafter, the same being applied) was 50% by mass).

Subsequently, this preliminary mixture 101 was subjected to the dispersion treatment by the high-speed rotating thin film dispersion method at a circumferential velocity of 40 m/sec for 5 minutes in constant-temperature reservoir at 10° C., using a thin-film spin system high-speed mixer “FILMIX 40-40 type” (manufactured by PRIMIX Corporation, the space between the inner periphery of the tubular outer body and the outer periphery of the stirring blade being adjusted to 2 mm (hereinafter, the same being applied)), thereby preparing a dispersion for a thermoelectric conversion layer 101 of the present invention. The solid content concentration of this dispersion for a thermoelectric conversion layer 101 was 1.0 w/v % (the CNT content was 50% by mass).

### 2. Preparation of Thermoelectric Conversion Layer 101

The dispersion for a thermoelectric conversion layer 101 prepared above is applied on the substrate to form the thermoelectric conversion layer. In detail, after ultrasonic washing in isopropyl alcohol, a 2 mm-thick metal mask having a 13 mm×13 mm opening section formed by a laser process was placed on a 1.1 mm-thick glass substrate which had been subjected to a UV-ozone treatment for 10 minutes. Next, the above-prepared dispersion for a thermoelectric conversion layer 101 was injected through the opening section, and was planarized with a squeegee. In this way, the dispersion for a thermoelectric conversion layer 101 was printed by a metal mask printing method. Then, the metal mask was removed, and subsequently, the glass substrate was heated and dried on an 80° C. hot plate for 45 minutes, thereby preparing a thermoelectric conversion layer 101 on the glass substrate.

### 3. Production of Thermoelectric Conversion Element 101

A thermoelectric conversion element, which has a first electrode, a thermoelectric conversion layer, and a second electrode on a substrate in this order, corresponding to the thermoelectric conversion element 1 shown in FIG. 1 was produced using the dispersion for a thermoelectric conversion layer 101. Hereinafter, the same symbol as the thermoelectric conversion element 1 shown in FIG. 1 is given to a member corresponding to the constituent member of the thermoelectric conversion element 1 shown in FIG. 1.

In detail, after ultrasonic washing in isopropyl alcohol, a 100 nm-thick chromium layer and then a 200 nm-thick gold layer were laminated through an ion plating method on a 40 mm×50 mm glass substrate 12 having a thickness of 1.1 mm using a metal mask having a 20 mm×20 mm opening section formed by etching, thereby forming a first electrode 13.

Subsequently, a 2 mm-thick metal mask having a 13×13 mm opening section formed by laser processing was disposed on the substrate 12 such that the opening section was disposed on the first electrode 13. The dispersion for a thermoelectric conversion layer 101 was printed in the opening section of the metal mask by a printing method such as a metal mask printing method as described above. Then, the glass substrate 12 was heated and dried on an 80° C. hot plate for 45 minutes, thereby forming a thermoelectric conversion layer 14 on the first electrode 13.

Next, a conductive paste “DOTITE D-550” (trade name, manufactured by Fujikura Kasei Co., Ltd., silver paste) was applied using a screen printing method so as to form a second electrode 15 on the thermoelectric conversion layer 14, and thus, a thermoelectric conversion element 101 was produced.

### 4. Preparation of Dispersion for Thermoelectric Conversion Layer 102 and Thermoelectric Conversion Layer 102, and Production of Thermoelectric Conversion Element 102

A preliminary mixture 102 (the solid content concentration being 2.0 w/v % (the CNT content being 50% by mass)) and a dispersion for an thermoelectric conversion layer 102 (the solid content concentration being 2.0 w/v % (the CNT content being 50% by mass)) were prepared in the same manner as in the preparation of the dispersion for the thermoelectric conversion layer 101, except that 200 mg of each of poly(3-octylthiophene-2,5-yl) and the single-walled carbon nanotube was used in the preparation of the dispersion for a thermoelectric conversion layer 101.

Further, a thermoelectric conversion layer 102 was prepared and a thermoelectric conversion element 102 were produced in the same manner as in the preparation of the thermoelectric conversion layer 101 and the production of the thermoelectric conversion element 101, using the dispersion for a thermoelectric conversion layer 102 instead of the dispersion for a thermoelectric conversion layer 101 in the preparation of the thermoelectric conversion layer 101 and the production of the thermoelectric conversion element 101.

### 5. Preparation of Dispersion for Thermoelectric Conversion Layer 103 and Thermoelectric Conversion Layer 103, and Production of Thermoelectric Conversion Element 103

A preliminary mixture 103 (the solid content concentration being 0.5 w/v % (the CNT content being 50% by mass)) and a dispersion for an thermoelectric conversion layer 103 (the solid content concentration being 0.5 w/v % (the CNT content being 50% by mass)) were prepared in the same manner as in the preparation of the dispersion for the thermoelectric conversion layer 101, except that 50 mg of each of poly(3-octylthiophene-2,5-yl) and the single-walled carbon nanotube was used in the preparation of the dispersion for a thermoelectric conversion layer 101.

Further, a thermoelectric conversion layer 103 was prepared and a thermoelectric conversion element 103 was produced in the same manner as in the preparation of the thermoelectric conversion layer 101 and the production of the thermoelectric conversion element 101, using the dispersion for a thermoelectric conversion layer 103 instead of the dispersion for a thermoelectric conversion layer 101 in the preparation of the thermoelectric conversion layer 101 and the production of the thermoelectric conversion element 101.

### 6. Preparation of Dispersion for Thermoelectric Conversion Layer 104 and Thermoelectric Conversion Layer 104, and Production of Thermoelectric Conversion Element 104

A preliminary mixture 104 (the solid content concentration being 20 w/v % (the CNT content being 50% by mass)) and a dispersion for an thermoelectric conversion layer 104 (the solid content concentration being 20 w/v % (the CNT content being 50% by mass)) were prepared in the same manner as in the preparation of the dispersion for the thermoelectric conversion layer 101, except that 2 g of each of poly(3-octylthiophene-2,5-yl) and the single-walled carbon nanotube was used in the preparation of the dispersion for a thermoelectric conversion layer 101.

Further, a thermoelectric conversion layer 104 was prepared and a thermoelectric conversion element 104 was produced in the same manner as in the preparation of the thermoelectric conversion layer 101 and the production of the thermoelectric conversion element 101, using the dispersion for a thermoelectric conversion layer 104 instead of the dispersion for a thermoelectric conversion layer 101 in the preparation of the thermoelectric conversion layer 101 and the production of the thermoelectric conversion element 101.

### 7. Preparation of Dispersion for Thermoelectric Conversion Layer 105 and Thermoelectric Conversion Layer 105, and Production of Thermoelectric Conversion Element 105

A preliminary mixture 105 (the solid content concentration being 0.1 w/v % (the CNT content being 50% by mass)) and a dispersion for an thermoelectric conversion layer 105 (the solid content concentration being 0.1 w/v % (the CNT content being 50% by mass)) were prepared in the same manner as in the preparation of the dispersion for the thermoelectric conversion layer 101, except that 10 mg of each of poly(3-octylthiophene-2,5-yl) and the single-walled carbon nanotube was used in the preparation of the dispersion for a thermoelectric conversion layer 101.

Further, a thermoelectric conversion layer 105 was prepared and a thermoelectric conversion element 105 was produced in the same manner as in the preparation of the thermoelectric conversion layer 101 and the production of the thermoelectric conversion element 101, using the dispersion for a thermoelectric conversion layer 105 instead of the dispersion for a thermoelectric conversion layer 101 in the preparation of the thermoelectric conversion layer 101 and the production of the thermoelectric conversion element 101.

### 8. Preparation of Dispersion for Thermoelectric Conversion Layer 106 and Thermoelectric Conversion Layer 106, and Production of Thermoelectric Conversion Element 106

A preliminary mixture 106 (the solid content concentration being 0.2 w/v % (the CNT content being 50% by mass)) and a dispersion for an thermoelectric conversion layer 106 (the solid content concentration being 0.2 w/v % (the CNT content being 50% by mass)) were prepared in the same manner as in the preparation of the dispersion for the thermoelectric conversion layer 101, except that 20 mg of each of poly(3-octylthiophene-2,5-yl) and the single-walled carbon nanotube was used in the preparation of the dispersion for a thermoelectric conversion layer 101.

Further, a thermoelectric conversion layer 106 was prepared and a thermoelectric conversion element 106 was produced in the same manner as in the preparation of the thermoelectric conversion layer 101 and the production of the thermoelectric conversion element 101, using the dispersion for a thermoelectric conversion layer 106 instead of the dispersion for a thermoelectric conversion layer 101 in the preparation of the thermoelectric conversion layer 101 and the production of the thermoelectric conversion element 101.

### 9. Preparation of Dispersion for Thermoelectric Conversion Layer 107 and Thermoelectric Conversion Layer 107, and Production of Thermoelectric Conversion Element 107

A preliminary mixture 107 (the solid content concentration being 5.0 w/v % (the CNT content being 50% by mass)) and a dispersion for an thermoelectric conversion layer 107 (the solid content concentration being 5.0 w/v % (the CNT content being 50% by mass)) were prepared in the same manner as in the preparation of the dispersion for the thermoelectric conversion layer 101, except that 500 mg of each of poly(3-octylthiophene-2,5-yl) and the single-walled carbon nanotube was used in the preparation of the dispersion for a thermoelectric conversion layer 101.

Further, a thermoelectric conversion layer 107 was prepared and a thermoelectric conversion element 107 was produced in the same manner as in the preparation of the thermoelectric conversion layer 101 and the production of the thermoelectric conversion element 101, using the dispersion for a thermoelectric conversion layer 107 instead of the dispersion for a thermoelectric conversion layer 101 in the preparation of the thermoelectric conversion layer 101 and the production of the thermoelectric conversion element 101.

### 10. Preparation of Dispersion for Thermoelectric Conversion Layer 108 and Thermoelectric Conversion Layer 108, and Production of Thermoelectric Conversion Element 108

A preliminary mixture 108 (the solid content concentration being 10 w/v % (the CNT content being 50% by mass)) and a dispersion for an thermoelectric conversion layer 108 (the solid content concentration being 10 w/v % (the CNT content being 50% by mass)) were prepared in the same manner as in the preparation of the dispersion for the thermoelectric conversion layer 101, except that 1 g of each of poly(3-octylthiophene-2,5-yl) and the single-walled carbon nanotube was used in the preparation of the dispersion for a thermoelectric conversion layer 101.

Further, a thermoelectric conversion layer 108 was prepared and a thermoelectric conversion element 108 was produced in the same manner as in the preparation of the thermoelectric conversion layer 101 and the production of the thermoelectric conversion element 101, using the dispersion for a thermoelectric conversion layer 108 instead of the dispersion for a thermoelectric conversion layer 101 in the preparation of the thermoelectric conversion layer 101 and the production of the thermoelectric conversion element 101.

### 11. Preparation of Dispersion for Thermoelectric Conversion Layer 109 and Thermoelectric Conversion Layer 109, and Production of Thermoelectric Conversion Element 109

A preliminary mixture 109 (the solid content concentration being 1.0 w/v % (the CNT content being 50% by mass)) and a dispersion for a thermoelectric conversion layer 109 (the solid content concentration being 1.0 w/v % (the CNT content being 50% by mass)) were prepared in the same manner as in the preparation of the dispersion for the 101, except that “MC” (product name, produced by Meijo Nano Carbon Co., Ltd.) was used as a single-walled carbon nanotube instead of “ASP-100F” (product name, produced by Hanwha Chemical Co., Ltd.) in the preparation of the dispersion for a thermoelectric conversion layer 101.

Further, a thermoelectric conversion layer 109 was prepared and a thermoelectric conversion element 109 was produced in the same manner as in the preparation of the thermoelectric conversion layer 101 and the production of the thermoelectric conversion element 101, using the dispersion for a thermoelectric conversion layer 109 instead of the dispersion for a thermoelectric conversion layer 101 in the preparation of the thermoelectric conversion layer 101 and the production of the thermoelectric conversion element 101.

### 12. Preparation of Dispersion for Thermoelectric Conversion Layer 110 and Thermoelectric Conversion Layer 110, and Production of Thermoelectric Conversion Element 110

A preliminary mixture 110 (the solid content concentration being 2.0 w/v % (the CNT content being 50% by mass)) and a dispersion for an thermoelectric conversion layer 110 (the solid content concentration being 2.0 w/v % (the CNT content being 50% by mass)) were prepared in the same manner as in the preparation of the dispersion for the thermoelectric conversion layer 109, except that 200 mg of each of poly(3-octylthiophene-2,5-yl) and the single-walled carbon nanotube “MC” (product name, produced by Meijo Nano Carbon Co., Ltd.) was used in the preparation of the dispersion for a thermoelectric conversion layer 109.

Further, a thermoelectric conversion layer 110 was prepared and a thermoelectric conversion element 110 was produced in the same manner as in the preparation of the thermoelectric conversion layer 101 and the production of the thermoelectric conversion element 101, using the dispersion for a thermoelectric conversion layer 110 instead of the dispersion for a thermoelectric conversion layer 101 in the preparation of the thermoelectric conversion layer 101 and the production of the thermoelectric conversion element 101.

### 13. Preparation of Dispersion for Thermoelectric Conversion Layer 111 and Thermoelectric Conversion Layer 111, and Production of Thermoelectric Conversion Element 111

A preliminary mixture 111 (the solid content concentration being 1.0 w/v % (the CNT content being 50% by mass)) and a dispersion for an thermoelectric conversion layer 111 (the solid content concentration being 1.0 w/v % (the CNT content being 50% by mass)) were prepared in the same manner as in the preparation of the dispersion for the thermoelectric conversion layer 101, except that the conjugated polymer 101 was used instead of poly(3-octylthiophene-2,5-yl) in the preparation of the dispersion for a thermoelectric conversion layer 101.

Further, a thermoelectric conversion layer 111 was prepared and a thermoelectric conversion element 111 was produced in the same manner as in the preparation of the thermoelectric conversion layer 101 and the production of the thermoelectric conversion element 101, using the dispersion for a thermoelectric conversion layer 111 instead of the dispersion for a thermoelectric conversion layer 101 in the preparation of the thermoelectric conversion layer 101 and the production of the thermoelectric conversion element 101.

### 14. Preparation of Dispersion for Thermoelectric Conversion Layer 112 and Thermoelectric Conversion Layer 112, and Production of Thermoelectric Conversion Element 112

A preliminary mixture 112 (the solid content concentration being 1.0 w/v % (the CNT content being 50% by mass)) and a dispersion for an thermoelectric conversion layer 112 (the solid content concentration being 1.0 w/v % (the CNT content being 50% by mass)) were prepared in the same manner as in the preparation of the dispersion for the thermoelectric conversion layer 101, except that the conjugated polymer 102 was used instead of poly(3-octylthiophene-2,5-yl) in the preparation of the dispersion for a thermoelectric conversion layer 101.

Further, a thermoelectric conversion layer 112 was prepared and a thermoelectric conversion element 112 was produced in the same manner as in the preparation of the thermoelectric conversion layer 101 and the production of the thermoelectric conversion element 101, using the dispersion for a thermoelectric conversion layer 112 instead of the dispersion for a thermoelectric conversion layer 101 in the preparation of the thermoelectric conversion layer 101 and the production of the thermoelectric conversion element 101.

### 15. Preparation of Dispersion for Thermoelectric Conversion Layer 113 and Thermoelectric Conversion Layer 113, and Production of Thermoelectric Conversion Element 113

A preliminary mixture 113 (the solid content concentration being 1.0 w/v % (the CNT content being 50% by mass)) and a dispersion for an thermoelectric conversion layer 113 (the solid content concentration being 1.0 w/v % (the CNT content being 50% by mass)) were prepared in the same manner as in the preparation of the dispersion for the thermoelectric conversion layer 101, except that the conjugated polymer 103 was used instead of poly(3-octylthiophene-2,5-yl) in the preparation of the dispersion for a thermoelectric conversion layer 101.

Further, a thermoelectric conversion layer 113 was prepared and a thermoelectric conversion element 113 was produced in the same manner as in the preparation of the thermoelectric conversion layer 101 and the production of the thermoelectric conversion element 101, using the dispersion for a thermoelectric conversion layer 113 instead of the dispersion for a thermoelectric conversion layer 101 in the preparation of the thermoelectric conversion layer 101 and the production of the thermoelectric conversion element 101.

### 16. Preparation of Dispersion for Thermoelectric Conversion Layer 114 and Thermoelectric Conversion Layer 114, and Production of Thermoelectric Conversion Element 114

A preliminary mixture 114 (the solid content concentration being 1.0 w/v % (the CNT content being 50% by mass)) and a dispersion for a thermoelectric conversion layer 114 (the solid content concentration being 1.0 w/v % (the CNT content being 50% by mass)) were prepared in the same manner as in the preparation of the dispersion for the 101, except that “HP” (product name, produced by KH Chemicals Co., Ltd.) was used as a single-walled carbon nanotube instead of “ASP-100F” (product name, produced by Hanwha Chemical Co., Ltd.) in the preparation of the dispersion for a thermoelectric conversion layer 101.

Further, a thermoelectric conversion layer 114 was prepared and a thermoelectric conversion element 114 was produced in the same manner as in the preparation of the thermoelectric conversion layer 101 and the production of the thermoelectric conversion element 101, using the dispersion for a thermoelectric conversion layer 114 instead of the dispersion for a thermoelectric conversion layer 101 in the preparation of the thermoelectric conversion layer 101 and the production of the thermoelectric conversion element 101.

### 17. Preparation of Dispersion for Thermoelectric Conversion Layer 115 and Thermoelectric Conversion Layer 115, and Production of Thermoelectric Conversion Element 115

A preliminary mixture 115 (the solid content concentration being 2.0 w/v % (the CNT content being 50% by mass)) and a dispersion for an thermoelectric conversion layer 115 (the solid content concentration being 2.0 w/v % (the CNT content being 50% by mass)) were prepared in the same manner as in the preparation of the dispersion for the thermoelectric conversion layer 114, except that 200 mg of each of poly(3-octylthiophene-2,5-yl) and the single-walled carbon nanotube “HP” (product name, produced by KH Chemicals Co., Ltd.) was used in the preparation of the dispersion for a thermoelectric conversion layer 114.

Further, a thermoelectric conversion layer 115 was prepared and a thermoelectric conversion element 115 was produced in the same manner as in the preparation of the thermoelectric conversion layer 101 and the production of the thermoelectric conversion element 101, using the dispersion for a thermoelectric conversion layer 115 instead of the dispersion for a thermoelectric conversion layer 101 in the preparation of the thermoelectric conversion layer 101 and the production of the thermoelectric conversion element 101.

### 18. Preparation of Dispersion for Thermoelectric Conversion Layer c101 and Thermoelectric Conversion Layer c101, and Production of Thermoelectric Conversion Element c101

A preliminary mixture c101 (the solid content concentration being 20 w/v % (the CNT content being 50% by mass)) was prepared in the same manner as in the preparation of the dispersion for the thermoelectric conversion layer 101, except that 2 g of each of poly(3-octylthiophene-2,5-yl) and the single-walled carbon nanotube was used in the preparation of the dispersion for a thermoelectric conversion layer 101.

Further, a dispersion for a thermoelectric conversion layer c101 (the solid content concentration being 20 w/v % (the CNT content being 50% by mass)) used for comparison was prepared in such a manner that the preliminary mixture c101 was ultrasonic dispersed at 30° C. for 30 minutes using an ultrasonic homogenizer “VC-750” (product name, manufactured by SONICS&MATERIALS, Inc., using a taper microchip (a probe diameter of 6.5 mm), an output of 40 W, direct irradiation, a Duty ratio of 50%).

Further, the thermoelectric conversion layer c101 was tried to prepared and the thermoelectric conversion element c101 were tried to be produced, in the same manner as in the preparation of the thermoelectric conversion layer 101 and the production of the thermoelectric conversion element 101, by using the dispersion for a thermoelectric conversion layer c101 instead of the dispersion for a thermoelectric conversion layer 101 in the preparation of the thermoelectric conversion layer 101 and the production of the thermoelectric conversion element 101. However, it was not possible to produce the thermoelectric conversion layer c101 and the thermoelectric conversion element c101.

The viscosity, the average particle diameter D, the dispersibility, and the thixotropic property of each of the dispersions for a thermoelectric conversion layer 101 to 115, and c101 prepared in this way were evaluated as follows. The results are shown in Table 1.

### [Viscosity and Average Particle Diameter D]

The viscosity was measured using an oscillation-type viscometer “VM-10A” (product name, manufactured by SEKONIC CORPORATION) or a rheometer “MARS” (product name, a viscosity/viscoelasticity measuring apparatus, manufactured by Thermo Fisher Scientific Inc.) after the temperature of each dispersion for a thermoelectric conversion layer was maintained at 25° C. In the viscoelasticity measurement by using a rheometer, a viscosity when a shear speed in the flow curve measurement was 1 Hz was employed.

The average particle diameter D of the single-walled carbon nanotube in each dispersion for a thermoelectric conversion layer was measured using a fiber-optics particle analyzer “FPAR-1000” (product name, manufactured by OTSUKA ELECTRONICS Co., LTD.) by a dynamic light scattering method.

### [Evaluation of Dispersibility]

Regarding the dispersibility of the single-walled carbon nanotube, each dispersion for a thermoelectric conversion layer was put as drops on a slide glass, a cover glass was placed thereon, and then observation was carried out by an optical microscope. The evaluation was carried out based on five grades of ranks 1, 2, 3, 4, and 5 from the order of the excellent dispersibility. When the evaluation rank is any of 1 to 3, it is determined that the carbon nanotube is excellent in dispersibility.
1: No black aggregates were observed.
2: Black aggregates having a size of less than 500 μm were observed.
3: Black aggregates having a size in a range of 500 μm or more and less than 1 mm were observed.
4: A large number (10 or more) of black aggregates having a size in a range of 500 μm or more and less than 1 mm was observed.
5: A large number (10 or more) of black aggregates having a size in a range of 1 mm or more was observed.

### [Evaluation of Thixotropic Property]

The evaluation on the thixotropic property was carried out in such a manner that both the viscosity at 30° C. and 6 rpm and the viscosity at 30° C. and 60 rpm were measured using a rheometer “MARS” (product name, a viscosity/viscoelasticity measuring apparatus, manufactured by Thermo Fisher Scientific Inc.) and a ratio of product of the rotation number and the viscosity (TI value, thixotropic index value) was calculated. The TI value of each dispersion for a thermoelectric conversion layer is presented by a relative value to the TI value of the thermoelectric conversion layer 101 and is shown in Table 1. As the TI value increases, the thixotropic property increases.

In the present invention, when the relative value is 0.1, the minimum printing property which is acceptable is achieved, and when the relative value is more than 0.1 but less than 1.1, the desirable printing property is achieved. When the relative value is 1.1 or more, it is determined that the printing property is particularly excellent.

Further, the film-forming property, the electrical conductivity, and the thermoelectric performance of each of the thermoelectric conversion layers 101 to 115 and the thermopower of each of the thermoelectric conversion elements 101 to 115 were evaluated as follows. Regarding Sample c101, only the film-forming property of the coating layer of the dispersion for a thermoelectric conversion layer was evaluated.

### [Film-Forming Properties]

The film-forming property was evaluated in such a manner that the spread degree of the coating layer due to the dripping of the dispersion for a thermoelectric conversion layer was focused on and visually observed based on the size of each thermoelectric conversion layer with respect to the opening section in the metal mask. The evaluation was carried out based on four grades of ranks 1, 2, 3, and 4 from the order of the excellent film-forming property. When the evaluation rank is 1 or 2, the degree of dripping of the dispersion is small and the formability is higher. Therefore, it is determined that the film has favorable quality and can be formed to be thick and the film-forming property is more excellent. When the evaluation rank is 3, the minimum film-forming property which is acceptable is achieved.
1: The size of the thermoelectric conversion layer is 1.5 times or less the opening section in the metal mask.
2: The size of the thermoelectric conversion layer is more than 1.5 times and 2.0 times or less the opening section in the metal mask.
3: The size of the thermoelectric conversion layer is more than 2.0 times and 2.5 times or less the opening section in the metal mask.
4: The size of the thermoelectric conversion layer is more than 2.5 times the opening section in the metal mask.

### [Measurement of Electrical Conductivity]

The electrical conductivity of each thermoelectric conversion layer was obtained by measuring the surface resistivity (unit: Ω/□) of each thermoelectric conversion layer using a low resistivity meter “LORESTA GP” (trade name, manufactured by Mitsubishi Chemical Analytech Co., Ltd.), measuring the film thickness (unit: cm) of each thermoelectric conversion layer using a stylus profilometer and surface shape measuring apparatus “XP-200” (trade name, manufactured by Ambios Technology Inc.), and computing the electrical conductivity (S/cm) using the following equation.

(Electrical conductivity)=1/((surface resistivity (Ω/□))×(film thickness (cm)) Equation:

### [Thermoelectric Performance: PF]

The Seebeck coefficient S (μV/k) and the electrical conductivity σ (S/cm) were measured at the temperature of 100° C. in the atmosphere using a thermoelectric conversion performance measurement machine MODEL RZ2001i (manufactured by Ozawa Science Co., Ltd.). From the obtained Seebeck coefficient S and electrical conductivity σ, a power factor (PF) as the thermoelectric performance was computed using the following equation. The PF of each thermoelectric conversion layer is represented by a relative value to the PF of the thermoelectric conversion layer 101, and is shown in Table 1.

PF (μW/(m·K))=(Seebeck coefficient S)²×(electrical conductivity σ) Equation:

### [Thermopower]

The thermopower of each thermoelectric conversion element was evaluated as follows. That is, the voltage difference caused between the first electrode 13 and the second electrode 15 when the glass substrate 12 in each thermoelectric conversion element was heated on the hot plate having a surface temperature of 80° C. was measured using a digital multi-meter R6581 (manufactured by Advantest Corporation). The thermopower of each thermoelectric conversion element is represented by a relative value to the thermopower of the thermoelectric conversion element 101, and is shown in Table 1.

### [Determination of Length of Single-Walled Carbon Nanotube]

The length of each of the single-walled carbon nanotubes “ASP-100F”, “HP”, and “MC” used in each Example was evaluated as follows. That is, a dilute dispersion liquid obtained by isolatedly dispersing each single-walled carbon nanotube using sodium cholate as a dispersant with an ultrasonic homogenizer was subjected to drop casting on a glass substrate, and then observation was performed by means of an atomic force microscope (AFM). The lengths of 50 single-walled carbon nanotubes were measured and then an average value thereof was obtained. The results are shown in Table 2.

### [Determination of Diameter of Single-Walled Carbon Nanotube]

The diameter of each of the single-walled carbon nanotubes used in each Example was evaluated as follows. That is, the Raman spectrum at excitation light with a wavelength of 532 nm of each single-walled carbon nanotube was measured (excitation wavelength: 532 nm), and the diameter was calculated by shift ω (RBM) (cm⁻¹) of radial breathing mode (RBM) using the following calculation formula. The results are shown in Table 2.

Diameter (nm)=248/ω(RBM) Calculation Formula:

### [Determination of G/D Ratio of Single-Walled Carbon Nanotube]

The Raman spectrum at excitation light with a wavelength of 532 nm was measured, and the ratio G/D of the G band intensity (near 1,590 cm⁻¹, in-plane vibration of graphene) and the D band intensity (near 1,350 cm⁻¹, derived from defects of sp² carbon network) of each single-walled carbon nanotube was calculated. As the intensity ratio G/D increases, defects of the carbon nanotube decrease. The results are shown in Table 2.

TABLE 1

| | | | Solid content | | Average particle | TI | |
|---|---|---|---|---|---|---|---|
| Sample | | Conjugated | concentration | Viscosity | diameter | value | |
| No. | CNT | polymer | (w/v %) | (mPa · s) | D (nm) | (*) | Dispersibility |
| 105 | A | P3OT | 0.1 | 4 | 428 | 0.2 | 3 |
| 106 | A | P3OT | 0.2 | 4 | 325 | 0.2 | 3 |
| 103 | A | P3OT | 0.5 | 11 | 254 | 0.9 | 3 |
| 101 | A | P3OT | 1.0 | 48 | 407 | 1.0 | 3 |
| 102 | A | P3OT | 2.0 | 67 | 325 | 1.4 | 2 |
| 107 | A | P3OT | 5.0 | 83 | 728 | 1.5 | 2 |
| 108 | A | P3OT | 10.0 | 106 | 821 | 2.3 | 2 |
| 104 | A | P3OT | 20.0 | 125 | 875 | 2.7 | 2 |
| 109 | B | P3OT | 1.0 | 101 | 42 | 1.8 | 3 |
| 110 | B | P3OT | 2.0 | 118 | 35 | 2.1 | 3 |
| 114 | C | P3OT | 1.0 | 55 | 163 | 1.1 | 3 |
| 115 | C | P3OT | 2.0 | 64 | 213 | 1.2 | 3 |
| 111 | A | 101 | 1.0 | 21 | 372 | 1.2 | 3 |
| 112 | A | 102 | 1.0 | 15 | 358 | 1.1 | 3 |
| 113 | A | 103 | 1.0 | 17 | 298 | 1.1 | 3 |
| c101 | A | P3OT | 20.0 | 372 | It was impossible | 3.2 | 5 |
| | | | | | to evaluate. | | |
| | | Electrical | | | | | |

| | | |
|---|---|---|
| Sample | Film-forming | conductivity |

| No. | properties | (S/cm) | PF (*) | Thermopower (*) | Remarks |
|---|---|---|---|---|---|
| 105 | 3 | 16 | 0.1 | 0.7 | This invention |
| 106 | 3 | 28 | 0.2 | 0.8 | This invention |
| 103 | 2 | 118 | 0.8 | 0.9 | This invention |
| 101 | 2 | 170 | 1.0 | 1.0 | This invention |
| 102 | 1 | 213 | 1.5 | 1.3 | This invention |
| 107 | 1 | 320 | 1.5 | 1.4 | This invention |
| 108 | 1 | 385 | 1.5 | 1.4 | This invention |
| 104 | 1 | 480 | 1.8 | 1.5 | This invention |
| 109 | 1 | 289 | 2.1 | 1.1 | This invention |
| 110 | 1 | 323 | 3.2 | 1.3 | This invention |
| 114 | 2 | 86 | 0.8 | 1.1 | This invention |
| 115 | 2 | 118 | 0.9 | 1.2 | This invention |
| 111 | 1 | 435 | 2.9 | 1.5 | This invention |
| 112 | 1 | 332 | 2.1 | 1.3 | This invention |
| 113 | 1 | 394 | 2.7 | 1.3 | This invention |
| c101 | 3 | It was impossible | It was impossible | It was impossible | Comparative |
| | | to evaluate. | to evaluate. | to evaluate. | example |

* The TI value is represented by a relative value to that of Sample No. 101.
* Kind of CNT A: ASP-100F, B: MC, C: HP
* The PF and Thermopower are represented by a relative values to those of Sample No. 101, respectively.

TABLE 2

| Item | “MC” | “HP” | “ASP-100F” |
|---|---|---|---|
| The number of layers | Single-walled | Single-walled | Single-walled |
| Length in longitudinal | >1 μm | >5 μm | >5 μm |
| direction | | | |
| Diameter | 1.7 to 2.0 nm | 1.3 nm | 1.3 to 1.5 nm |
| G/D ratio | 33 | 29 | 70 |

As shown in Table 1, the dispersions for a thermoelectric conversion layer of Sample Nos. 101 to 115 prepared by the high-speed rotating thin film dispersion method had a high viscosity and favorable dispersibility and were excellent in the thixotropic property without dividing of the CNT. Therefore, the film-forming property and the printing property were favorable. Accordingly, the thermoelectric conversion elements of Sample Nos. 101 to 115 were excellent in electrical conductivity and thermoelectric performance.

As the solid content concentration of the dispersion for a thermoelectric conversion layer increased, the viscosity and the thixotropic property gradually increased, and the film-forming property, preferably, the formability and the thermoelectric conversion performance were improved.

Specifically, since Sample Nos. 102, 104, 107, and 108 having a higher solid content concentration than that of Sample No. 101 were pastes having a high viscosity and favorable dispersibility, the film-forming property was more favorable. In particular, since Sample No. 104 having the highest solid content concentration had a higher thixotropic property and was excellent in formability during printing, the film-forming property was improved and the thermoelectric conversion performance was also excellent.

Further, according to Table 1 and Table 2, the film-forming properties of Sample Nos. 109 and 110 using a single-walled carbon nanotube “MC” having a length of more than 1 μm, a diameter of 1.7 to 2.0 nm, and the G/D ratio of 33 were equal to or higher than those of Sample Nos. 101 and 102 using a single-walled carbon nanotube “ASP-100F” and Sample Nos. 114 and 115 using a single-walled carbon nanotube “HP”. For this reason, the electrical conductivity and the PF were excellent and the thermopower was equal to or higher than those of Sample Nos. 101, 102, 114, and 115.

On the other hand, since Sample No. c101 having a high solid content concentration which was produced by an ultrasonic homogenizer could not be satisfactorily dispersed using the ultrasonic homogenizer, a layer could not formed and thus the evaluation on the thermoelectric conversion performance or the like could not performed.

### Example 2 and Comparative Example 2

### 1. Preparation of Dispersion for Thermoelectric Conversion Layer 201 and Thermoelectric Conversion Layer 201, and Production of Thermoelectric Conversion Element 201

A preliminary mixture 201 (the solid content concentration being 1.0 w/v % (the CNT content being 50% by mass)) and a dispersion for a thermoelectric conversion layer 201 (the solid content concentration being 1.0 w/v % (the CNT content being 50% by mass)) were prepared in the same manner as in the preparation of the dispersion for the dispersion for a thermoelectric conversion layer 101, except that a multi-walled carbon nanotube “VGCF-X” (product name, an average diameter of 150 nm, an average length of 10 to 20 μm, manufactured by SHOWA DENKO K. K.) was used as a nano conductive material instead of the single-walled carbon nanotube in the preparation of the dispersion for a thermoelectric conversion layer 101.

Further, a thermoelectric conversion layer 201 was prepared and a thermoelectric conversion element 201 was produced in the same manner as in the preparation of the thermoelectric conversion layer 101 and the production of the thermoelectric conversion element 101, using the dispersion for a thermoelectric conversion layer 201 instead of the dispersion for a thermoelectric conversion layer 101 in the preparation of the thermoelectric conversion layer 101 and the production of the thermoelectric conversion element 101.

### 2. Preparation of Dispersion for Thermoelectric Conversion Layer 202 and Thermoelectric Conversion Layer 202, and Production of Thermoelectric Conversion Element 202

A preliminary mixture 202 (the solid content concentration being 1.0 w/v % (the CNT content being 50% by mass)) and a dispersion for a thermoelectric conversion layer 202 (the solid content concentration being 1.0 w/v % (the CNT content being 50% by mass)) were prepared in the same manner as in the preparation of the dispersion for a thermoelectric conversion layer 101, except that carbon black “#3400B” (brand name, a diameter of 23 nm, manufactured by MITSUBISHI CHEMICAL CORPORATION) was used as a nano conductive material instead of the single-walled carbon nanotube in the preparation of the dispersion for a thermoelectric conversion layer 101.

Further, a thermoelectric conversion layer 202 was prepared and a thermoelectric conversion element 202 was produced in the same manner as in the preparation of the thermoelectric conversion layer 101 and the production of the thermoelectric conversion element 101, using the dispersion for a thermoelectric conversion layer 202 instead of the dispersion for a thermoelectric conversion layer 101 in the preparation of the thermoelectric conversion layer 101 and the production of the thermoelectric conversion element 101.

### 3 Preparation of Dispersion for Thermoelectric Conversion Layer c201 and Thermoelectric Conversion Layer c201, and Production of Thermoelectric Conversion Element c201

A preliminary mixture c201 (the solid content concentration being 1.0 w/v % (the CNT content being 50% by mass)) and a dispersion for a thermoelectric conversion layer c201 (the solid content concentration being 1.0 w/v % (the CNT content being 50% by mass)) were prepared in the same manner as in the preparation of the dispersion for the thermoelectric conversion layer c101, except that 100 mg of poly(3-octylthiophene-2,5-yl) was used and a 100 mg of multi-walled carbon nanotube “VGCF-X” (product name, manufactured by SHOWA DENKO K. K.) was used as a nano conductive material instead of the single-walled carbon nanotube in the preparation of the dispersion for a thermoelectric conversion layer c101.

Further, a thermoelectric conversion layer c201 was prepared and a thermoelectric conversion element c201 was produced in the same manner as in the preparation of the thermoelectric conversion layer 101 and the production of the thermoelectric conversion element 101, using the dispersion for a thermoelectric conversion layer c201 instead of the dispersion for a thermoelectric conversion layer 101 in the preparation of the thermoelectric conversion layer 101 and the production of the thermoelectric conversion element 101.

### 4. Preparation of Dispersion for Thermoelectric Conversion Layer c202 and Thermoelectric Conversion Layer c202, and Production of Thermoelectric Conversion Element c202

A preliminary mixture c202 (the solid content concentration being 1.0 w/v % (the CNT content being 50% by mass)) and a dispersion for a thermoelectric conversion layer c202 (the solid content concentration being 1.0 w/v % (the CNT content being 50% by mass)) were prepared in the same manner as in the preparation of the dispersion for a thermoelectric conversion layer c201, except that carbon black “#3400B” (brand name, a diameter of 23 nm, manufactured by MITSUBISHI CHEMICAL CORPORATION) was used as a nano conductive material instead of the multi-walled carbon nanotube in the preparation of the dispersion for a thermoelectric conversion layer c201.

Further, a thermoelectric conversion layer c202 was prepared and a thermoelectric conversion element c202 was produced in the same manner as in the preparation of the thermoelectric conversion layer c201 and the production of the thermoelectric conversion element c201, using the dispersion for a thermoelectric conversion layer c202 instead of the dispersion for a thermoelectric conversion layer c201 in the preparation of the thermoelectric conversion layer c201 and the production of the thermoelectric conversion element c201.

The viscosity, the dispersibility, and the thixotropic property of each of the dispersions for a thermoelectric conversion layer 201, 202, c201, and c202 prepared in this way were evaluated in the same manner as in Example 1.

Further, the film-forming properties, the electrical conductivity, and the thermoelectric performance of each of the thermoelectric conversion layers 201 and 202 and the thermopower of each of the thermoelectric conversion elements 201 and 202 were evaluated in the same manner as in Example 1.

The results are shown in Table 3.

TABLE 3

| | | Solid | | | | | | | | |
|---|---|---|---|---|---|---|---|---|---|---|
| | Nano | content | | TI | | Film- | Electrical | | | |
| Sample | conductive | concentration | Viscosity | value | | forming | conductivity | | Thermopower | |
| No. | material | (w/v %) | (mPa · s) | (*) | Dispersibility | properties | (S/cm) | PF (*) | (*) | Remarks |
| 201 | MWCNT | 1.0 | 32 | 1.2 | 2 | 2 | 32 | 0.05 | 0.5 | This |
| | | | | | | | | | | invention |
| 202 | CB | 1.0 | 27 | 1 | 2 | 2 | 19 | 0.02 | 0.4 | This |
| | | | | | | | | | | invention |
| c201 | MWCNT | 1.0 | 4 | 0.6 | 5 | 3 | It was | It was | It was | Comparative |
| | | | | | | | impossible | impossible | impossible | example |
| | | | | | | | to evaluate. | to evaluate. | to evaluate. | |
| c202 | CB | 1.0 | 5 | 0.5 | 5 | 3 | It was | It was | It was | Comparative |
| | | | | | | | impossible | impossible | impossible | example |
| | | | | | | | to evaluate. | to evaluate. | to evaluate. | |

* The TI value, PF and Thermopower are represented by a relative values to those of Sample No. 101, respectively.

As shown in Table 3, Sample Nos. 201 and 202 prepared by the high-speed rotating thin film dispersion method could form a film.

On the other hand, regarding Sample Nos. c201 and c202 respectively prepared by a mechanical homogenizer and an ultrasonic homogenizer, the dispersibility was poor as compared to Sample Nos. 201 and 202, the film-forming property was deteriorated, and a uniform film could be obtained. For this reason, the surface resistivity and the thermoelectric performance could not be measured and the electrical conductivity, the PF, and the thermopower could not be evaluated.

### Example 3

### 1. Preparation of Dispersion for Thermoelectric Conversion Layer 301 and Thermoelectric Conversion Layer 301, and Production of Thermoelectric Conversion Element 301

A dispersion for a thermoelectric conversion layer 301 and a thermoelectric conversion layer 301 were prepared and a thermoelectric conversion element 301 was produced in the same manner as in Sample No. 101, except that 100 mg of 1-butyl-3-methylimidazolium hexafluorophosphate was used as a dispersant instead of poly(3-octylthiophene-2,5-yl).

The dispersibility of the dispersion for a thermoelectric conversion layer 301 prepared in this way was evaluated in the same manner as in Example 1.

Further, the film-forming property, the intensity ratio [Id/Ig], the electrical conductivity, and the thermoelectric performance of thermoelectric conversion layer 301, and the thermopower of thermoelectric conversion element 301 were evaluated in the same manner as in Example 1 or by the following method.

The PF of the thermoelectric conversion layer 301 and the thermopower of the thermoelectric conversion element 301 were obtained as relative values to the PF of the thermoelectric conversion layer 101 and the thermopower of the thermoelectric conversion element 101.

The results are shown in Table 4.

### [Intensity Ratio [Id/Ig]]

As the intensity ratio [Id/Ig] of the dispersion for a thermoelectric conversion layer, the Raman spectrum was measured in the same manner as in the calculation of the G/D ratio described above, the intensity ratio [Id/Ig] of the G band and the D band of the single-walled carbon nanotube in the thermoelectric conversion layer was calculated. A case where this intensity ratio [Id/Ig] is small means that the carbon nanotube has less cracks and damage is small during dispersing.

TABLE 4

| | | | Intensity | | | | |
|---|---|---|---|---|---|---|---|
| | | Film- | ratio | Electrical | | | |
| Sample | | forming | [Id/Ig] | conductivity | PF | Thermopower | |
| No. | Dispersibility | properties | (*) | (S/cm) | (*) | (*) | Remarks |
| 301 | 1 | 2 | 0.036 | 1080 | 1.9 | 0.6 | This |
| | | | | | | | invention |

* The PF and Thermopower are represented by a relative values to those of Sample No. 101, respectively.

As shown in Table 4, Sample No. 301 prepared by the high-speed rotating thin film dispersion method had favorable dispersibility and thus the film-forming property was favorable. Further, the intensity ratio [Id/Ig] was small and the damage to the dispersion was small. Therefore, the electrical conductivity was large and the thermoelectric performance was favorable.

### Example 4

### 1. Preparation of Dispersions for Thermoelectric Conversion Layer 401 to 406

Dispersions for a thermoelectric conversion layer 401 to 406 were prepared in the same manner as in the dispersion for a thermoelectric conversion layer 101, except that the mass ratio of poly(3-octylthiophene-2,5-yl) and a single-walled carbon nanotube “ASP-100F” (product name, produced by Hanwha Chemical Co., Ltd.) was changed to the mass ratio as shown in Table 5 in the preparation of the dispersion for a thermoelectric conversion layer 101.

### 2. Preparation of Thermoelectric Conversion Layers 401 to 406, and Production of Thermoelectric Conversion Elements 401 to 406

A thermoelectric conversion layers 401 to 406 were prepared and a thermoelectric conversion element 401 to 406 were produced in the same manner as in the preparation of the thermoelectric conversion layer 101 and the production of the thermoelectric conversion element 101, using each of the dispersions for a thermoelectric conversion layer 401 to 406 instead of the dispersion for a thermoelectric conversion layer 101 in the preparation of the thermoelectric conversion layer 101 and the production of the thermoelectric conversion element 101.

Herein, the sample No. 403 is the same as the sample No. 101.

The viscosity, the average particle diameter D, the dispersibility, and the thixotropic property of each of the dispersions for a thermoelectric conversion layer 401 to 406 prepared were evaluated as in the same manner as in Example 1.

Further, the film-forming property, the electrical conductivity, and the thermoelectric performance of each of the thermoelectric conversion layers 401 to 406, and the thermopower of each of the thermoelectric conversion elements 401 to 406 were evaluated in the same manner as in Example 1. The thixotropic property, the thermoelectric performance and the thermopower of each sample were obtained as relative values to those of Sample No. 101.

The results are shown in Table 5.

TABLE 5

| | | | Average | | | | | | | |
|---|---|---|---|---|---|---|---|---|---|---|
| | | | particle | TI | | Film- | Electrical | | | |
| Sample | CNT:Diapersant | Viscosity | diameter | value | | forming | conductivity | PF | Thermopower | |
| No. | (mass ratio) | (mPa · s) | D (nm) | (*) | Dispersibility | properties | (S/cm) | (*) | (*) | Remarks |
| 401 | 10:90 | 15 | 382 | 0.7 | 2 | 3 | 25 | 0.4 | 0.4 | This |
| | | | | | | | | | | invention |
| 402 | 30:70 | 21 | 252 | 0.9 | 2 | 3 | 87 | 0.7 | 0.5 | This |
| | | | | | | | | | | invention |
| 403 | 50:50 | 48 | 407 | 1.0 | 3 | 2 | 170 | 1.0 | 1.0 | This |
| | | | | | | | | | | invention |
| 404 | 70:30 | 58 | 532 | 1.1 | 1 | 1 | 201 | 1.3 | 1.3 | This |
| | | | | | | | | | | invention |
| 405 | 90:10 | 62 | 427 | 1.3 | 2 | 1 | 248 | 1.5 | 1.6 | This |
| | | | | | | | | | | invention |
| 406 | 5:95 | 7 | 285 | 0.7 | 2 | 3 | 21 | 0.2 | 0.2 | This |
| | | | | | | | | | | invention |

* The TI value, PF and Thermopower are represented by a relative values to those of Sample No. 101, respectively.

As shown in Table 5, regarding all Sample Nos. 401 to 406, the CNT was less likely to be divided, and the dispersibility and the film-forming property were excellent. Since Sample Nos. 401 to 405 having a mass ratio of 10 or more (a content of 10% by mass or more) of the CNT in the solid contents of the dispersion for a thermoelectric conversion layer, particularly, Sample Nos. 403 to 405 having a mass ratio of 50 or more (a content of 50% by mass or more) had a high viscosity and were excellent in the film-forming property, the electrical conductivity and the thermoelectric performance were also excellent.

### Example 5

### 1. Preparation of Dispersion for Thermoelectric Conversion Layer 501

90 mg of poly(3-octylthiophene-2,5-yl), 20 mg of polystyrene (represented as “PPS” in Table 6, polymerization degree of 2000, manufactured by Wako Pure Chemical Industries, Ltd.) as the non-conjugated polymer, and 20 mL of o-dichlorobenzene were added and then completely dissolved by using an ultrasonic cleaner “US-2” (product name, manufactured by IUCHI SEIEIDO CO., LTD., an output of 120 W, indirect radiation). Subsequently, 90 mg of a single-walled carbon nanotube “ASP-100F” (product name, produced by Hanwha Chemical Co., Ltd.) was added and then a preliminary mixture 501 was obtained by performing the preliminary mixing using a mechanical homogenizer “T10basic” (manufactured by IKA). The solid content concentration of this preliminary mixture 501 was 1.0 w/v % (the CNT content was 45% by mass).

Subsequently, this preliminary mixture 501 was subjected to the dispersion treatment by the high-speed rotating thin film dispersion method at a circumferential velocity of 40 m/sec for 5 minutes in constant-temperature reservoir at 10° C., using a thin-film spin system high-speed mixer “FILMIX 40-40 type” (manufactured by PRIMIX Corporation), thereby preparing a dispersion for a thermoelectric conversion layer 501.

### 2. Preparation of Dispersion for Thermoelectric Conversion Layer 502

A dispersion for a thermoelectric conversion layer 502 (the CNT content being 25% by mass) was prepared in the same manner as in the dispersion for a thermoelectric conversion layer 501, except that the mass ratio of poly(3-octylthiophene-2,5-yl), the single-walled carbon nanotube “HP”, and the polystyrene was changed to be the mass ratio as shown in Table 6 in the preparation of the dispersion for a thermoelectric conversion layer 501.

### 3. Preparation of Thermoelectric Conversion Layers 501 and 502, and Production of Thermoelectric Conversion Elements 501 and 502

A thermoelectric conversion layers 501 and 502 were prepared and a thermoelectric conversion element 501 and 502 were produced in the same manner as in the preparation of the thermoelectric conversion layer 101 and the production of the thermoelectric conversion element 101, using each of the dispersions for a thermoelectric conversion layer 501 and 502 instead of the dispersion for a thermoelectric conversion layer 101 in the preparation of the thermoelectric conversion layer 101 and the production of the thermoelectric conversion element 101.

The viscosity, the average particle diameter D, the dispersibility, and the thixotropic property of each of the dispersions for a thermoelectric conversion layer 501 and 502 prepared were evaluated as in the same manner as in Example 1.

Further, the film-forming property, the electrical conductivity, and the thermoelectric performance of each of the thermoelectric conversion layers 501 and 502, and the thermopower of each of the thermoelectric conversion elements 501 and 502 were evaluated in the same manner as in Example 1. The thixotropic property, the thermoelectric performance and the thermopower of each sample were obtained as relative values to those of Sample No. 101.

The results are shown in Table 6.

TABLE 6

| | | | Average | | | | | | | |
|---|---|---|---|---|---|---|---|---|---|---|
| | | | particle | TI | | Film- | Electrical | | | |
| Sample | CNT:Diapersant:PPS | Viscosity | diameter | value | | forming | conductivity | PF | Thermopower | |
| No. | (mass ratio) | (mPa · s) | D (nm) | (*) | Dispersibility | properties | (S/cm) | (*) | (*) | Remarks |
| 101 | 100:100:0 | 48 | 407 | 1.0 | 3 | 2 | 170 | 1.0 | 1.0 | This |
| | | | | | | | | | | invention |
| 501 | 90:90:20 | 32 | 683 | 1.1 | 2 | 1 | 165 | 1.0 | 1.1 | This |
| | | | | | | | | | | invention |
| 502 | 50:50:100 | 18 | 797 | 0.9 | 2 | 1 | 105 | 0.8 | 0.7 | This |
| | | | | | | | | | | invention |

* The TI value, PF and Thermopower are represented by a relative values to those of Sample No. 101, respectively.

As shown in Table 6, regarding all Sample Nos. 501 and 502 using a non-conjugated polymer, the CNT was less likely to be divided, and the dispersibility and the film-forming property were excellent. In particular, Sample No. 501 having a mass ratio of 10 (a content of 10% by mass) of the non-conjugated polymer in the solid contents of the dispersion for a thermoelectric conversion layer also had favorable electrical conductivity and also was excellent in the thermoelectric performance.

### Example 6

### 1. Preparation of Dispersion for Thermoelectric Conversion Layer 601

100 mg of poly(3-octylthiophene-2,5-yl), 100 mg of a single-walled carbon nanotube “ASP-100F” (product name, produced by Hanwha Chemical Co., Ltd.), and 20 mL of o-dichlorobenzene were added and then a preliminary mixture 601 was obtained by performing the preliminary mixing using a mechanical homogenizer “T10basic” (manufactured by IKA). The solid content concentration of this preliminary mixture 601 was 1.0 w/v % (the CNT content was 50% by mass). Subsequently, this preliminary mixture 601 was subjected to the dispersion treatment by the high-speed rotating thin film dispersion method at a circumferential velocity of 25 m/sec for 5 minutes in constant-temperature reservoir at 10° C., using a thin-film spin system high-speed mixer “FILMIX 40-40 type” (manufactured by PRIMIX Corporation), thereby preparing a dispersion for a thermoelectric conversion layer 601.

### 2. Preparation of Dispersion for Thermoelectric Conversion Layer 602

A dispersion for a thermoelectric conversion layer 602 was prepared in the same manner as in the preparation of the dispersion for a thermoelectric conversion layer 601, except that the circumferential velocity of the thin-film spin system high-speed mixer “FILMIX 40-40 type” was changed to 10 m/sec in the preparation of the dispersion for a thermoelectric conversion layer 601.

### 3. Preparation of Thermoelectric Conversion Layers 601 and 602, and Production of Thermoelectric Conversion Elements 601 and 602

A thermoelectric conversion layers 601 and 602 were prepared and a thermoelectric conversion element 601 and 602 were produced in the same manner as in the preparation of the thermoelectric conversion layer 101 and the production of the thermoelectric conversion element 101, using each of the dispersions for a thermoelectric conversion layer 601 and 602 instead of the dispersion for a thermoelectric conversion layer 101 in the preparation of the thermoelectric conversion layer 101 and the production of the thermoelectric conversion element 101.

The viscosity, the average particle diameter D, the dispersibility, and the thixotropic property of each of the dispersions for a thermoelectric conversion layer 601 and 602 prepared were evaluated as in the same manner as in Example 1.

Further, the film-forming property, the electrical conductivity, and the thermoelectric performance of each of the thermoelectric conversion layers 601 and 602, and the thermopower of each of the thermoelectric conversion elements 601 and 602 were evaluated in the same manner as in Example 1. The thixotropic property, the thermoelectric performance and the thermopower of each sample were obtained as relative values to those of Sample No. 101. The results are shown in Table 7.

TABLE 7

| | | | Average | | | | | | | |
|---|---|---|---|---|---|---|---|---|---|---|
| | circumferential | | particle | TI | | Film- | Electrical | | | |
| Sample | velocity | Viscosity | diameter | value | | forming | conductivity | PF | Thermopower | |
| No. | (m/s) | (mPa · s) | D (nm) | (*) | Dispersibility | properties | (S/cm) | (*) | (*) | Remarks |
| 101 | 40 | 48 | 407 | 1.0 | 3 | 2 | 170 | 1.0 | 1.0 | This |
| | | | | | | | | | | invention |
| 601 | 25 | 21 | 631 | 0.7 | 3 | 2 | 168 | 0.9 | 0.8 | This |
| | | | | | | | | | | invention |
| 602 | 10 | 8 | 732 | 0.4 | 3 | 3 | 153 | 0.9 | 0.7 | This |
| | | | | | | | | | | invention |

* The TI value, PF and Thermopower are represented by as a relative values to those of Sample No. 101, respectively.

As shown in Table 7, regarding all Sample Nos. 101, 601 and 602 using a non-conjugated polymer, the CNT was less likely to be divided, and the dispersibility and the film-forming property were excellent. In particular, Sample No. 101 and Sample No. 601 prepared by the high-speed rotating thin film dispersion method at a high circumferential velocity were excellent in film-forming property. As a result, electrical conductivity and thermoelectric performance were also high.

### Example 7

### 1. Preparation of Dispersion for Thermoelectric Conversion Layer 701

10 mg of a single-walled carbon nanotube “MC” (product name, manufactured by Meijo Nano Carbon Co., Ltd.), 4 mg of TCNQ (manufactured by Tokyo Chemical Industry Co., Ltd.), and 20 mL of o-dichlorobenzene were added, preliminary mixing was performed at 20° C. for 15 minutes using a mechanical homogenizer “T10basic” (manufactured by IKA), and the resultant mixture was filtered through a 1 μm membrane filter, thereby obtaining a carbon nanotube-TCNQ mixture. This operation was repeated 5 times and the resultant mixtures were collected, thereby obtaining about 50 mg of a composition 701.

Subsequently, 20 mL of o-dichlorobenzene was added to 50 mg of the composition 701 and 50 mg of poly(3-octylthiophene-2,5-yl), and the preliminary mixing was further performed at 20° C. for 15 minutes using a mechanical homogenizer “T10basic” (manufactured by IKA), thereby obtaining a preliminary mixture 701. The solid content concentration of this preliminary mixture 701 was 0.5 w/v %.

Subsequently, this preliminary mixture 701 was subjected to the dispersion treatment by the high-speed rotating thin film dispersion method at a circumferential velocity of 40 m/sec for 5 minutes in constant-temperature reservoir at 10° C., using a thin-film spin system high-speed mixer “FILMIX 40-40 type” (manufactured by PRIMIX Corporation), thereby preparing a dispersion for a thermoelectric conversion layer 701. The solid content concentration of this dispersion for a thermoelectric conversion layer 701 was 0.5 w/v %.

### 2. Preparation of Dispersion for Thermoelectric Conversion Layer 702

10 mg of a single-walled carbon nanotube “MC” (product name, manufactured by Meijo Nano Carbon Co., Ltd.), 50 mg of Triphenylphospine (manufactured by Wako Pure Chemical Industries, Ltd., hereinafter, referred to as “TPP”), and 20 mL of cyclohexanone were added, preliminary mixing was performed at 20° C. for 15 minutes using a mechanical homogenizer “T10basic” (manufactured by IKA), and the resultant mixture was filtered through a 1 μm membrane filter, thereby obtaining a carbon nanotube-TPP mixture. This operation was repeated 5 times and the resultant mixtures were collected, thereby obtaining about 50 mg of a composition 702.

Subsequently, 20 mL of cyclohexanone was added to 50 mg of the composition 702 and 50 mg of polystyrene, and the preliminary mixing was further performed at 20° C. for 15 minutes using a mechanical homogenizer “T10basic” (manufactured by IKA), thereby obtaining a preliminary mixture 702. The solid content concentration of this preliminary mixture 702 was 0.5 w/v %.

Subsequently, this preliminary mixture 702 was subjected to the dispersion treatment by the high-speed rotating thin film dispersion method at a circumferential velocity of 40 m/sec for 5 minutes in constant-temperature reservoir at 10° C., using a thin-film spin system high-speed mixer “FILMIX 40-40 type” (manufactured by PRIMIX Corporation), thereby preparing a dispersion for a thermoelectric conversion layer 702. The solid content concentration of this dispersion for a thermoelectric conversion layer 702 was 0.5 w/v %.

### 3. Preparation of Thermoelectric Conversion Layers 701 and 702, and Production of Thermoelectric Conversion Elements 701 and 702

A thermoelectric conversion layers 701 and 702 were prepared and a thermoelectric conversion element 701 and 702 were produced in the same manner as in the preparation of the thermoelectric conversion layer 101 and the production of the thermoelectric conversion element 101, using each of the dispersions for a thermoelectric conversion layer 701 and 702 instead of the dispersion for a thermoelectric conversion layer 101 in the preparation of the thermoelectric conversion layer 101 and the production of the thermoelectric conversion element 101.

The dispersibility of the prepared dispersions for a thermoelectric conversion layer 701 and 702 was evaluated in the same manner in Example 1 and the polarity thereof was identified.

Further, the film-forming property, electrical conductivity, and thermoelectric performance of each of the thermoelectric conversion layers 701 and 702 and the thermopower of each of the thermoelectric conversion elements 701 and 702 were evaluated in the same manner in Example 1. The thermoelectric performance and thermopower of each sample were obtained as relative values to those of the sample 109.

The results are shown in Table 8.

TABLE 8

| | | | | | | Electrical | | | |
|---|---|---|---|---|---|---|---|---|---|
| Sample | | | | Film-forming | | conductivity | PF | Thermopower | |
| No. | Polymer | Dopant | Dispersibility | properties | Polarity | (S/cm) | (*) | (*) | Remarks |
| 109 | P3OT | None | 3 | 1 | p | 289 | 1.0 | 1.0 | This |
| | | | | | | | | | invention |
| 701 | P3OT | TCNQ | 3 | 1 | p | 462 | 2.1 | 1.2 | This |
| | | | | | | | | | invention |
| 702 | PS | PPT | 3 | 1 | n | 260 | 0.6 | 0.8 | This |
| | | | | | | | | | invention |

* The PF and Thermopower are represented by a relative values to those of Sample No. 109, respectively.

As is clearly understood from Table 8, in Sample Nos. 701 and 702 prepared by the high-speed rotating thin film dispersion method and using a dopant, CNT was less likely, for example, to be divided and was excellent in dispersibility, film-forming property, and electrical conductivity. Further, in Sample No. 702 using a non-conjugated polymer and an n-type dopant, the p-type polarity was converted into the n-type polarity as compared to the case of not using a non-conjugated polymer and an n-type dopant.

### Example 8

### 1. Preparation of Dispersion for Thermoelectric Conversion Layer 801 and Thermoelectric Conversion Layer 801, and Production of Thermoelectric Conversion Element 801

A preliminary mixture 801 (the solid content concentration being 1.0 w/v % (the CNT content being 50% by mass)) and a dispersion for an thermoelectric conversion layer 801 (the solid content concentration being 1.0 w/v % (the CNT content being 50% by mass)) were prepared in the same manner as in the preparation of the dispersion for the thermoelectric conversion layer 101, except that 100 mg of polystyrene (polymerization degree of 2000, manufactured by Wako Pure Chemical Industries, Ltd.) was used instead of poly(3-octylthiophene-2,5-yl) and 100 mg of “HP” was used instead of the single-walled carbon nanotube “ASP-100F” (product name, produced by Hanwha Chemical Co., Ltd.) in the preparation of the dispersion for a thermoelectric conversion layer 101.

Further, a thermoelectric conversion layer 801 was prepared and a thermoelectric conversion element 801 was produced in the same manner as in the preparation of the thermoelectric conversion layer 101 and the production of the thermoelectric conversion element 101, using the dispersion for a thermoelectric conversion layer 801 instead of the dispersion for a thermoelectric conversion layer 101 in the preparation of the thermoelectric conversion layer 101 and the production of the thermoelectric conversion element 101.

### 2. Preparation of Dispersion for Thermoelectric Conversion Layer 802 and Thermoelectric Conversion Layer 802, and Production of Thermoelectric Conversion Element 802

A preliminary mixture 802 (the solid content concentration being 1.0 w/v % (the CNT content being 50% by mass)) and a dispersion for an thermoelectric conversion layer 802 (the solid content concentration being 1.0 w/v % (the CNT content being 50% by mass)) were prepared in the same manner as in the preparation of the dispersion for the thermoelectric conversion layer 801, except that 100 mg of 2-vinylnaphthalene (molecular weight: 175,000, manufactured by Aldrich Co.) was used instead of polystyrene (polymerization degree of 2000, manufactured by Wako Pure Chemical Industries, Ltd.) in the preparation of the dispersion for a thermoelectric conversion layer 801.

Further, a thermoelectric conversion layer 802 was prepared and a thermoelectric conversion element 802 was produced in the same manner as in the preparation of the thermoelectric conversion layer 101 and the production of the thermoelectric conversion element 101, using the dispersion for a thermoelectric conversion layer 802 instead of the dispersion for a thermoelectric conversion layer 101 in the preparation of the thermoelectric conversion layer 101 and the production of the thermoelectric conversion element 101.

### 3. Preparation of Dispersion for Thermoelectric Conversion Layer 803 and Thermoelectric Conversion Layer 803, and Production of Thermoelectric Conversion Element 803

A preliminary mixture 803 (the solid content concentration being 1.0 w/v % (the CNT content being 50% by mass)) and a dispersion for an thermoelectric conversion layer 803 (the solid content concentration being 1.0 w/v % (the CNT content being 50% by mass)) were prepared in the same manner as in the preparation of the dispersion for the thermoelectric conversion layer 801, except that 100 mg of PC—Z type polycarbonate (Panlite TS-2020, manufactured by TEIJIN LIMITED) was used instead of polystyrene (polymerization degree of 2000, manufactured by Wako Pure Chemical Industries, Ltd.) in the preparation of the dispersion for a thermoelectric conversion layer 801.

Further, a thermoelectric conversion layer 803 was prepared and a thermoelectric conversion element 803 was produced in the same manner as in the preparation of the thermoelectric conversion layer 101 and the production of the thermoelectric conversion element 101, using the dispersion for a thermoelectric conversion layer 803 instead of the dispersion for a thermoelectric conversion layer 101 in the preparation of the thermoelectric conversion layer 101 and the production of the thermoelectric conversion element 101.

The viscosity, the average particle diameter D, the dispersibility, and the thixotropic property of each of the dispersions for a thermoelectric conversion layer 801 to 803 prepared were evaluated as in the same manner as in Example 1.

Further, the film-forming property, the electrical conductivity, and the thermoelectric performance of each of the thermoelectric conversion layers 801 to 803, and the thermopower of each of the thermoelectric conversion elements 801 to 803 were evaluated in the same manner as in Example 1. The thixotropic property, the thermoelectric performance and the thermopower of each sample were obtained as relative values to those of Sample No. 114. The results are shown in Table 9.

TABLE 9

| | | | Average | | | | | | | |
|---|---|---|---|---|---|---|---|---|---|---|
| | | | particle | TI | | Film- | Electrical | | | |
| Sample | | Viscosity | diameter | value | | forming | conductivity | PF | Thermopower | |
| No. | Polymer | (mPa · s) | D (nm) | (*) | Dispersibility | properties | (S/cm) | (*) | (*) | Remarks |
| 801 | A | 68 | 230 | 1.0 | 2 | 1 | 38 | 0.9 | 1.0 | This |
| | | | | | | | | | | invention |
| 802 | B | 62 | 162 | 1.1 | 1 | 1 | 54 | 2.0 | 1.3 | This |
| | | | | | | | | | | invention |
| 803 | C | 58 | 204 | 1.0 | 1 | 1 | 52 | 1.5 | 1.1 | This |
| | | | | | | | | | | invention |

* The TI value, PF and Thermopower are represented by a relative values to those of Sample No. 114, respectively.
* Kind of Polymer A: polystyrene B: 2-vinylnaphthalene C: polycarbonate

As is clearly understood from Table 9, in all of Sample Nos. 801, 802, and 803 prepared by the high-speed rotating thin film dispersion method, the CNT was less likely, for example, to be divided and was excellent in dispersibility and film-forming property, and thus electrical conductivity and thermoelectric performance were also high.

Having described our invention as related to the present embodiments, it is our intention that the invention not be limited by any of the details of the description, unless otherwise specified, but rather be construed broadly within its spirit and scope as set out in the accompanying claims.

### REFERENCE SIGNS LIST

1, 2 Thermoelectric conversion element
11, 17 Metal plate
12, 22 First substrate
13, 23 First electrode
14, 24 Thermoelectric conversion layer
15, 25 Second electrode
16, 26 Second substrate
31 Substrate
32 Region in which the thermoelectric conversion layer is to be formed
33 Bank

1. A method of producing a thermoelectric conversion element which has, on a substrate, a first electrode, a thermoelectric conversion layer, and a second electrode, which method comprises steps of:
preparing a dispersion for the thermoelectric conversion layer containing a nano conductive material by subjecting at least the nano conductive material and a dispersion medium to a high-speed rotating thin film dispersion method; and
applying the prepared dispersion for a thermoelectric conversion layer on or above the substrate and then drying the dispersion for a thermoelectric conversion layer.

2. The method of producing a thermoelectric conversion element according to claim 1, wherein solid content concentration of the dispersion for a thermoelectric conversion layer is 0.5 to 20 w/v %.

3. The method of producing a thermoelectric conversion element according to claim 1, wherein content of the nano conductive material in the solid contents of the dispersion for a thermoelectric conversion layer is 10% by mass or more.

4. The method of producing a thermoelectric conversion element according to claim 1, wherein a viscosity of the dispersion for a thermoelectric conversion layer is 10 mPa·s or more.

5. The method of producing a thermoelectric conversion element according to claim 1, wherein the high-speed rotating thin film dispersion method is performed at a circumferential velocity of 10 to 40 m/sec.

6. The method of producing a thermoelectric conversion element according to claim 1, wherein a dispersant is further subjected to the high-speed rotating thin film dispersion method.

7. The method of producing a thermoelectric conversion element according to claim 6, wherein the dispersant is a conjugated polymer.

8. The method of producing a thermoelectric conversion element according to claim 1, wherein a non-conjugated polymer is further subjected to the high-speed rotating thin film dispersion method.

9. The method of producing a thermoelectric conversion element according to claim 1, wherein the nano conductive material is at least one kind of material selected from the group consisting of a carbon nanotube, a carbon nanofiber, fullerene, graphite, graphene, carbon nanoparticles and a metal nanowire.

10. The method of producing a thermoelectric conversion element according to claim 1, wherein the nano conductive material is a carbon nanotube.

11. The method of producing a thermoelectric conversion element according to claim 1, wherein the nano conductive material is a single-walled carbon nanotube, the diameter of the single-walled carbon nanotube is 1.5 nm to 2.0 nm, the length of the single-walled carbon nanotube is 1 μm or more, and the G/D ratio of the single-walled carbon nanotube is 30 or more.

12. The method of producing a thermoelectric conversion element according to claim 1, wherein the dispersion for a thermoelectric conversion layer is applied on or above the substrate by a printing method.

13. The method of producing a thermoelectric conversion element according to claim 1, wherein an average particle diameter D of the nano conductive material, which is measured by a dynamic light scattering method, in the dispersion for a thermoelectric conversion layer is 1,000 nm or less.

14. The method of producing a thermoelectric conversion element according to claim 1, wherein a ratio [dD/D] between a half-value width dD in the particle size distribution and an average particle diameter D, of the nano conductive material, which is measured by a dynamic light scattering method, in the dispersion for a thermoelectric conversion layer is 5 or less.

15. A method of preparing a dispersion for a thermoelectric conversion layer, the dispersion being used for forming a thermoelectric conversion layer of a thermoelectric conversion element, which method comprises:
dispersing a nano conductive material into a dispersion medium by subjecting at least the nano conductive material and the dispersion medium to a high-speed rotating thin film dispersion method.
